(19) United States
(12) Patent Application Publication
(10) Pub. No.: US 2024/0029539 A1
(43) Pub. Date: Jan. 25, 2024

(54) METHODS, SYSTEMS, APPARATUS, AND ARTICLES OF MANUFACTURE TO MONITOR HEAT EXCHANGERS AND ASSOCIATED RESERVOIRS

(71) Applicant: Intel Corporation, Santa Clara, CA (US)

(72) Inventors: Prabhakar Subrahmanyam, San Jose, CA (US); Viktor Polyanko, San Jose, CA (US); Vishnu Prasadh Sugumar, Santa Clara, CA (US); Ying-Feng Pang, San Jose, CA (US); Mark Lawrence Bianco, Mountain View, CA (US); Sandeep Ahuja, Portland, OR (US); Tejas Shah, Austin, TX (US)

(21) Appl. No.: 18/476,069

(22) Filed: Sep. 27, 2023

(51) Int. Cl. G08B 21/18; H05K 7/20

(52) U.S. Cl. CPC G08B 21/182; H05K 7/20263; H05K 7/20763; H05K 7/20236

(57) ABSTRACT

Methods, systems, apparatus, and articles of manufacture to monitor heat exchangers and associated reservoirs are disclosed. An example apparatus includes programmable circuitry to detect, based on outputs of a sensor associated with a first reservoir, a coolant level of the first reservoir, the first reservoir removably coupled to a second reservoir, the first reservoir to supply coolant to the second reservoir, predict, based on the coolant level, a characteristic associated with operation of a cooling device fluidly coupled to the second reservoir, and cause an output to be presented at a user device based on the predicted characteristic.

### FIELD OF THE DISCLOSURE

This disclosure relates generally to liquid cooling systems for electronic components and, more particularly, to methods, systems, apparatus, and articles of manufacture to monitor heat exchangers and associated reservoirs.

### BACKGROUND

The use of liquids to cool electronic components is being explored for its benefits over more traditional air cooling systems, as there is an increasing need to address thermal management risks resulting from increased thermal design power in high performance systems (e.g., CPU and/or GPU servers in data centers, cloud computing, edge computing, etc.). More particularly, relative to air, liquid has inherent advantages of higher specific heat (when no boiling is involved) and higher latent heat of vaporization (when boiling is involved).

### BRIEF DESCRIPTION OF THE DRAWINGS

FIG. 1 illustrates one or more example environments in which teachings of this disclosure may be implemented.

FIG. 2 illustrates at least one example of a data center for executing workloads with disaggregated resources.

FIG. 3 illustrates at least one example of a pod that may be included in the data center of FIG. 2.

FIG. 4 is a perspective view of at least one example of a rack that may be included in the pod of FIG. 3.

FIG. 5 is a side elevation view of the rack of FIG. 4.

FIG. 6 is a perspective view of the rack of FIG. 4 having a sled mounted therein.

FIG. 7 is a is a block diagram of at least one example of a top side of the sled of FIG. 6.

FIG. 8 is a block diagram of at least one example of a bottom side of the sled of FIG. 7.

FIG. 9 is a block diagram of at least one example of a compute sled usable in the data center of FIG. 2.

FIG. 10 is a top perspective view of at least one example of the compute sled of FIG. 9.

FIG. 11 is a block diagram of at least one example of an accelerator sled usable in the data center of FIG. 2.

FIG. 12 is a top perspective view of at least one example of the accelerator sled of FIG. 11.

FIG. 13 is a block diagram of at least one example of a storage sled usable in the data center of FIG. 2.

FIG. 14 is a top perspective view of at least one example of the storage sled of FIG. 13.

FIG. 15 is a block diagram of at least one example of a memory sled usable in the data center of FIG. 2.

FIG. 16 is a block diagram of a system that may be established within the data center of FIG. 2 to execute workloads with managed nodes of disaggregated resources.

FIG. 17 illustrates an example environment including example reservoir monitoring circuitry and example system monitoring circuitry to monitor an example heat exchanger and associated example reservoirs in accordance with teachings of this disclosure.

FIG. 18A illustrates a detailed view of one of the example reservoirs of FIG. 17.

FIG. 18B is a front view of an example coolant monitoring device of FIG. 18A.

FIG. 19 illustrates example reservoirs that can be implemented with the example heat exchanger of FIG. 17.

FIG. 20 illustrates the example heat exchanger and the example reservoirs of FIG. 19 implemented on an example chassis.

FIG. 21 is a block diagram of an example implementation of the example reservoir monitoring circuitry of FIG. 17.

FIG. 22 is a block diagram of an example implementation of the example system monitoring circuitry of FIG. 17.

FIG. 23 illustrates a first example graph that can be generated and/or output by the example system monitoring circuitry of FIG. 22.

FIG. 24 illustrates a second example graph that can be generated and/or output by the example system monitoring circuitry of FIG. 22.

FIG. 25 illustrates a first example table that can be generated and/or output by the example system monitoring circuitry of FIG. 22.

FIG. 26 illustrates a second example table that can be generated and/or output by the example system monitoring circuitry of FIG. 22.

FIG. 27A is a schematic illustration of a first example liquid cooling system of an example data center environment in which examples disclosed herein can be implemented.

FIG. 27B illustrates a second example liquid cooling system of an example data center environment in which examples disclosed herein can be implemented.

FIG. 28A illustrates an example immersion tank in which examples disclosed herein can be implemented.

FIG. 28B illustrates another example of the immersion tank of FIG. 28A.

FIG. 29 is a flowchart representative of example machine readable instructions and/or example operations that may be executed, instantiated, and/or performed by example programmable circuitry to implement the reservoir monitoring circuitry of FIG. 21.

FIG. 30 is a flowchart representative of example machine readable instructions and/or example operations that may be executed, instantiated, and/or performed by example programmable circuitry to implement the system monitoring circuitry of FIG. 22.

FIG. 31 is a flowchart representative of example machine readable instructions and/or example operations that may be executed, instantiated, and/or performed by programmable circuitry to train and/or re-train one or more example machine learning models to be utilized by the system monitoring circuitry of FIG. 22.

FIG. 32 is a block diagram of an example processing platform including programmable circuitry structured to execute, instantiate, and/or perform the example machine readable instructions and/or perform the example operations of FIG. 29 to implement the reservoir monitoring circuitry of FIG. 21.

FIG. 33 is a block diagram of an example processing platform including programmable circuitry structured to execute, instantiate, and/or perform the example machine readable instructions and/or perform the example operations of FIGS. 30 and/or 31 to implement the system monitoring circuitry of FIG. 22.

FIG. 34 is a block diagram of an example implementation of the programmable circuitry of FIGS. 32 and/or 33.

FIG. 35 is a block diagram of another example implementation of the programmable circuitry of FIGS. 32 and/or 33.

FIG. 36 is a block diagram of an example software/firmware/instructions distribution platform (e.g., one or more servers) to distribute software, instructions, and/or firmware (e.g., corresponding to the example machine readable instructions of FIGS. 29, 30, and/or 31) to client devices associated with end users and/or consumers (e.g., for license, sale, and/or use), retailers (e.g., for sale, re-sale, license, and/or sub-license), and/or original equipment manufacturers (OEMs) (e.g., for inclusion in products to be distributed to, for example, retailers and/or to other end users such as direct buy customers).

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

### DETAILED DESCRIPTION

As noted above, the use of liquids to cool electronic components is being explored for its benefits over more traditional air cooling systems, as there are increasing needs to address thermal management risks resulting from increased thermal design power in high performance systems (e.g., CPU and/or GPU servers in data centers, accelerators, artificial intelligence computing, machine learning computing, cloud computing, edge computing, and the like). More particularly, relative to air, liquid has inherent advantages of higher specific heat (when no boiling is involved) and higher latent heat of vaporization (when boiling is involved). In some instances, liquid can be used to indirectly cool electronic components by cooling a cold plate that is thermally coupled to the electronic component(s). An alternative approach is to directly immerse electronic components in the cooling liquid. In direct immersion cooling, the liquid can be in direct contact with the electronic components to directly draw away heat from the electronic components. To enable the cooling liquid to be in direct contact with electronic components, the cooling liquid is electrically insulative (e.g., a dielectric liquid).

A liquid cooling system can involve at least one of single-phase cooling or two-phase cooling. As used herein, single-phase cooling (e.g., single-phase immersion cooling) means the cooling fluid (sometimes also referred to herein as cooling liquid or coolant) used to cool electronic components draws heat away from heat sources (e.g., electronic components) without changing phase (e.g., without boiling and becoming vapor). Such cooling fluids are referred to herein as single-phase cooling fluids, liquids, or coolants. By contrast, as used herein, two-phase cooling (e.g., two-phase immersion cooling) means the cooling fluid (in this case, a cooling liquid) vaporizes or boils from the heat generated by the electronic components to be cooled, thereby changing from the liquid phase to the vapor phase. The gaseous vapor may subsequently be condensed back into a liquid (e.g., via a condenser) to again be used in the cooling process. Such cooling fluids are referred to herein as two-phase cooling fluids, liquids, or coolants. Notably, gases (e.g., air) can also be used to cool components and, therefore, may also be referred to as a cooling fluid and/or a coolant. However, indirect cooling and immersion cooling typically involves at least one cooling liquid (which may or may not change to the vapor phase when in use). Example systems, apparatus, and associated methods to improve cooling systems and/or associated cooling processes are disclosed herein.

In some environments (e.g., data centers), liquid assisted air cooling (LAAC) heat exchangers are used to dissipate heat from one or more electronic devices. In some cases, a reservoir (e.g., a coolant reservoir) is fluidly and/or operatively coupled to a corresponding one of the heat exchangers to provide coolant thereto. In some such cases, due to relatively large heat loads and/or relatively long cycle times of the heat exchangers, evaporation of the coolant in the reservoir may occur. Additionally, loss of coolant may occur when devices (e.g., cold plates) are connected to and/or disconnected from the heat exchangers (e.g., via quick disconnect fittings). Such evaporation and/or loss of coolant can result in pump failures and/or other anomalies associated with the heat exchangers, contributing to downtime in the operation of the heat exchangers to allow for repair and/or maintenance.

Typically, additional coolant is provided to the reservoir to reduce the risk of damage to and/or failure of the heat exchangers resulting from low coolant levels. For instance, the additional coolant can be provided periodically by an operator and/or based on visual inspection of the coolant levels by the operator. However, given the variability of heat loads and resulting evaporation rates, it may be difficult for an operator to predict when coolant levels are likely to drop below a threshold. As a result, low coolant levels are often not detected until after a pump failure and/or other hardware anomaly have occurred, resulting in reactive maintenance to repair and/or replace one or more components of the heat exchanger.

Examples disclosed herein monitor and/or predict performance of example heat exchangers and associated example reservoirs. In examples disclosed herein, a first example reservoir (e.g., a primary reservoir) is fluidly coupled to a heat exchanger (e.g., a liquid cooling system, an LAAC heat exchanger, etc.), and a second example reservoir (e.g., a secondary reservoir) is fluidly and removably coupled to the primary reservoir. In some examples, the first reservoir supplies coolant (e.g., fluid, cooling fluid) to the heat exchanger for use in cooling one or more devices (e.g., cold plates, server racks, etc.), and the second reservoir supplies coolant to the first reservoir over time based on monitoring and without operator intervention (e.g., periodically delivers fluid without user input to initiate each delivery). As such, examples disclosed herein maintain sufficient levels of coolant at the heat exchanger to reduce a risk of pump failure and/or other hardware anomalies. Further, examples disclosed herein enable refill and/or replacement of the second reservoir without halting operation of the heat exchanger, thus reducing interruptions and/or downtime in the operation of the heat exchanger.

Additionally, examples disclosed herein implement an example monitoring system to monitor and/or display the coolant level (e.g., fluid level) of the second reservoirs. For example, one or more sensors are operatively coupled to the second reservoir to detect the coolant level. In some examples, based on a comparison of the detected coolant level to one or more coolant thresholds (e.g., fluid thresholds), examples disclosed herein determine a status (e.g., a condition) corresponding to the second reservoir. For example, the status can indicate whether the second reservoir is full, whether additional coolant should be provided in the second reservoir, etc. In some examples, the sensors can indicate coolant levels from which capacity can be derived (e.g., 75% of reservoir capacity, 50% of reservoir capacity, 25% of reservoir capacity, etc.), and the coolant thresholds can be selected based on size of the reservoir and/or properties of the one or more sensors. Some examples disclosed herein activate one or more indicators (e.g., light sources) based on the status. For example, a first light source can be activated when the second reservoir is full, and a second light source (e.g., different from the first light source) can be activated when additional coolant should be provided in the second reservoir. In some examples, a color of the activated light source(s) can indicate the status of the second reservoir (e.g., whether the coolant is to be replenished). In some examples, an alert is generated and/or presented (e.g., via email, an SMS, a dashboard) to the user when the coolant level is low (e.g., below one or more threshold(s)). In some such examples, the alert can include a location and/or an identifier corresponding to the secondary reservoir and/or the heat exchanger. Advantageously, by alerting an operator when coolant levels are low, examples disclosed herein reduce risk of damage resulting from insufficient coolant at the heat exchanger.

Further examples disclosed herein detect and/or predict, based on execution of one or more example machine learning models, one or more example anomalies associated with the heat exchangers and/or the coolant. For example, example programmable circuitry disclosed herein executes the machine learning model(s) based on data (e.g., sensor data and/or user input information) associated with the heat exchanger(s) and/or the coolant. In some examples, as a result of the execution, the programmable circuitry outputs one or more example coolant anomalies (e.g., evaporation and/or overheating of the coolant, leakage of the coolant, reduced efficiency of the coolant, pressure drop of the coolant, etc.), one or more example hardware anomalies (e.g., pump failures, fan failures, blocked air flow, fin damage, operating temperatures exceeding a threshold, etc.), and/or a useful life (e.g., a remaining useful life (RUL), a remaining operational life) detected and/or predicted for the corresponding heat exchanger(s). In some examples, the output of the machine learning model(s) can be used to adjust one or more control parameters of the heat exchangers (e.g., fan speed, pump speed, coolant flow rate, etc.) to adjust a cooling performance thereof.

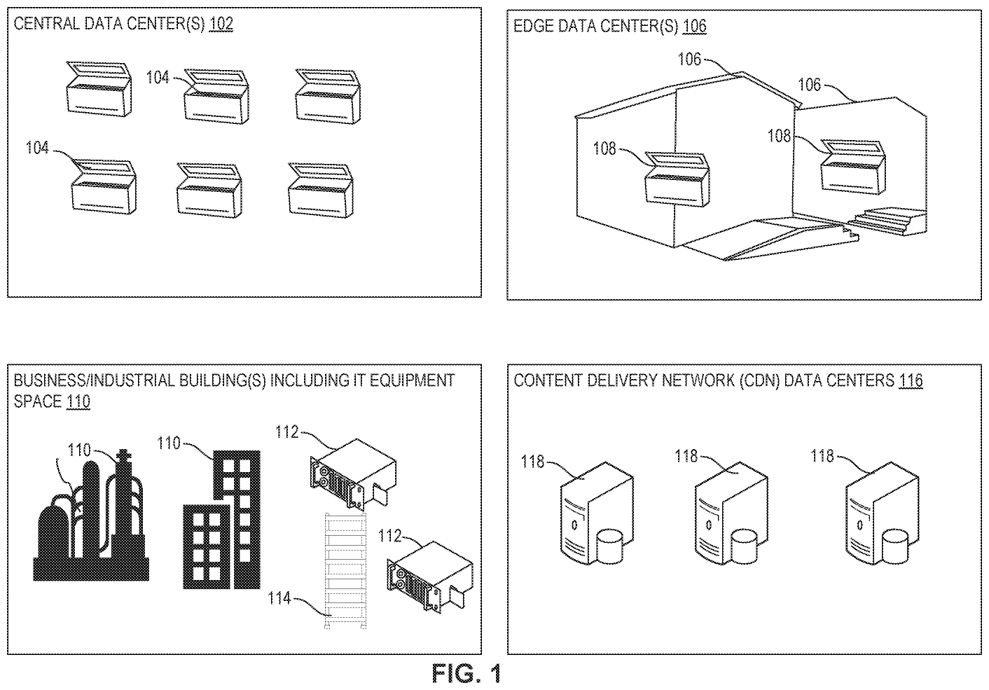

FIG. 1 illustrates one or more example environments in which teachings of this disclosure may be implemented. The example environment(s) of FIG. 1 can include one or more central data centers 102. The central data center(s) 102 can store a large number of servers used by, for instance, one or more organizations for data processing, storage, etc. As illustrated in FIG. 1, the central data center(s) 102 include a plurality of immersion tank(s) 104 to facilitate cooling of the servers and/or other electronic components stored at the central data center(s) 102. The immersion tank(s) 104 can provide for single-phase cooling or two-phase cooling.

The example environments of FIG. 1 can be part of an edge computing system. For instance, the example environments of FIG. 1 can include edge data centers or micro-data centers 106. The edge data center(s) 106 can include, for example, data centers located at a base of a cell tower. In some examples, the edge data center(s) 106 are located at or near a top of a cell tower and/or other utility pole. The edge data center(s) 106 include respective housings that store server(s), where the server(s) can be in communication with, for instance, the server(s) stored at the central data center(s) 102, client devices, and/or other computing devices in the edge network. Example housings of the edge data center(s) 106 may include materials that form one or more exterior surfaces that partially or fully protect contents therein, in which protection may include weather protection, hazardous environment protection (e.g., EMI, vibration, extreme temperatures), and/or enable submergibility. Example housings may include power circuitry to provide power for stationary and/or portable implementations, such as AC power inputs, DC power inputs, AC/DC or DC/AC converter(s), power regulators, transformers, charging circuitry, batteries, wired inputs and/or wireless power inputs. As illustrated in FIG. 1, the edge data center(s) 106 can include immersion tank(s) 108 to store server(s) and/or other electronic component(s) located at the edge data center(s) 106.

The example environment(s) of FIG. 1 can include buildings 110 for purposes of business and/or industry that store information technology (IT) equipment in, for example, one or more rooms of the building(s) 110. For example, as represented in FIG. 1, server(s) 112 can be stored with server rack(s) 114 that support the server(s) 112 (e.g., in an opening of slot of the rack 114). In some examples, the server(s) 112 located at the buildings 110 include on-premise server(s) of an edge computing network, where the on-premise server(s) are in communication with remote server(s) (e.g., the server(s) at the edge data center(s) 106) and/or other computing device(s) within an edge network.

The example environment(s) of FIG. 1 include content delivery network (CDN) data center(s) 116. The CDN data center(s) 116 of this example include server(s) 118 that cache content such as images, webpages, videos, etc. accessed via user devices. The server(s) 118 of the CDN data centers 116 can be disposed in immersion cooling tank(s) such as the immersion tanks 104, 108 shown in connection with the data centers 102, 106.

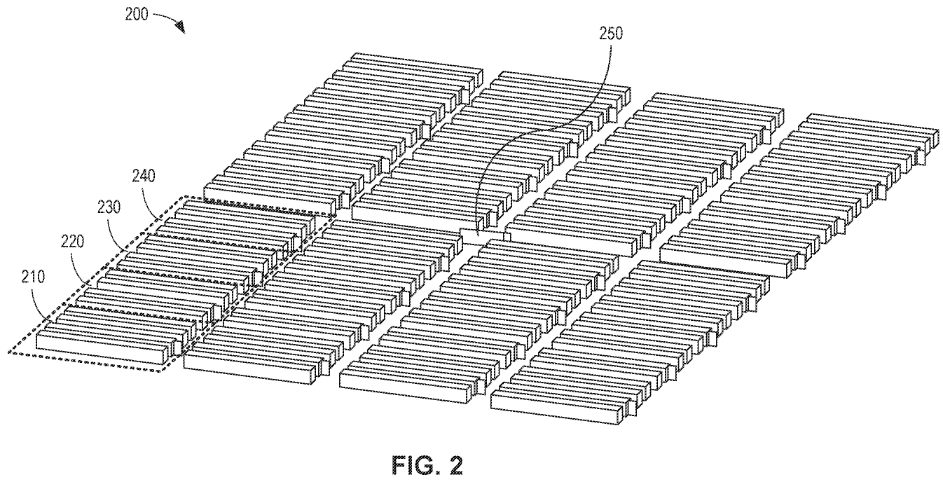

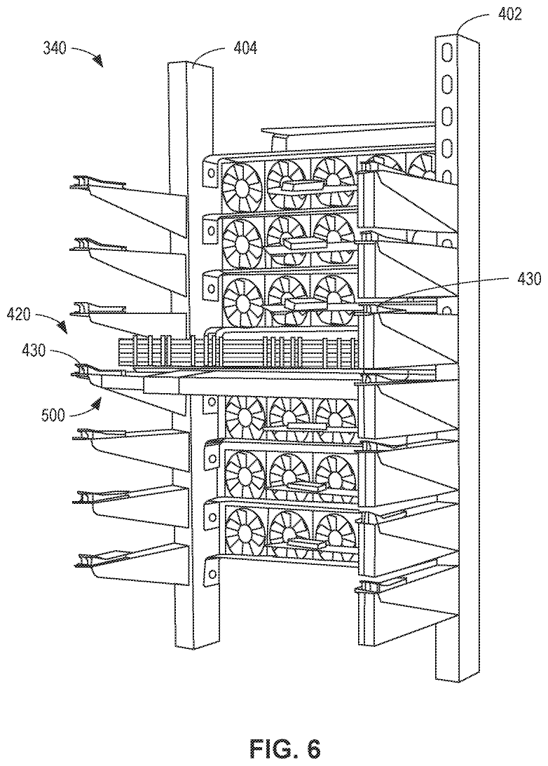

In some instances, the example data centers 102, 106, 116 and/or building(s) 110 of FIG. 1 include servers and/or other electronic components that are cooled independent of immersion tanks (e.g., the immersion tanks 104, 108) and/or an associated immersion cooling system. That is, in some examples, some or all of the servers and/or other electronic components in the data centers 102, 106, 116 and/or building(s) 110 can be cooled by air and/or liquid coolants without immersing the servers and/or other electronic components therein. Thus, in some examples, the immersion tanks 104, 108 of FIG. 1 may be omitted. Further, the example data centers 102, 106, 116 and/or building(s) 110 of FIG. 1 can correspond to, be implemented by, and/or be adaptations of the example data center 200 described in further detail below in connection with FIGS. 2-16.

Although a certain number of cooling tank(s) and other component(s) are shown in the figures, any number of such components may be present. Also, the example cooling data centers and/or other structures or environments disclosed herein are not limited to arrangements of the size that are depicted in FIG. 1. For instance, the structures containing example cooling systems and/or components thereof disclosed herein can be of a size that includes an opening to accommodate service personnel, such as the example data center(s) 106 of FIG. 1, but can also be smaller (e.g., a “doghouse” enclosure). For instance, the structures containing example cooling systems and/or components thereof disclosed herein can be sized such that access (e.g., the only access) to an interior of the structure is a port for service personnel to reach into the structure. In some examples, the structures containing example cooling systems and/or components thereof disclosed herein are be sized such that only a tool can reach into the enclosure because the structure may be supported by, for a utility pole or radio tower, or a larger structure.

In addition to or as an alternative to the immersion tanks 104, 108, any of the example environments of FIG. 1 can utilize one or more liquid cooling systems having a cold plate to control the temperature of the electronic devices/components in the example environments. An example liquid cooling system and example cold plates are disclosed in further detail in connection with FIGS. X-X.

FIG. 2 illustrates an example data center 200 in which disaggregated resources may cooperatively execute one or more workloads (e.g., applications on behalf of customers). The illustrated data center 200 includes multiple platforms 210, 220, 230, 240 (referred to herein as pods), each of which includes one or more rows of racks. Although the data center 200 is shown with multiple pods, in some examples, the data center 200 may be implemented as a single pod. As described in more detail herein, a rack may house multiple sleds. A sled may be primarily equipped with a particular type of resource (e.g., memory devices, data storage devices, accelerator devices, general purpose programmable circuitry), i.e., resources that can be logically coupled to form a composed node. Some such nodes may act as, for example, a server. In the illustrative example, the sleds in the pods 210, 220, 230, 240 are connected to multiple pod switches (e.g., switches that route data communications to and from sleds within the pod). The pod switches, in turn, connect with spine switches 250 that switch communications among pods (e.g., the pods 210, 220, 230, 240) in the data center 200. In some examples, the sleds may be connected with a fabric using Intel Omni-Path™ technology. In other examples, the sleds may be connected with other fabrics, such as InfiniB and or Ethernet. As described in more detail herein, resources within the sleds in the data center 200 may be allocated to a group (referred to herein as a “managed node”) containing resources from one or more sleds to be collectively utilized in the execution of a workload. The workload can execute as if the resources belonging to the managed node were located on the same sled. The resources in a managed node may belong to sleds belonging to different racks, and even to different pods 210, 220, 230, 240. As such, some resources of a single sled may be allocated to one managed node while other resources of the same sled are allocated to a different managed node (e.g., first programmable circuitry assigned to one managed node and second programmable circuitry of the same sled assigned to a different managed node).

A data center including disaggregated resources, such as the data center 200, can be used in a wide variety of contexts, such as enterprise, government, cloud service provider, and communications service provider (e.g., Telco's), as well in a wide variety of sizes, from cloud service provider mega-data centers that consume over 200,000 sq. ft. to single- or multi-rack installations for use in base stations.

In some examples, the disaggregation of resources is accomplished by using individual sleds that include predominantly a single type of resource (e.g., compute sleds including primarily compute resources, memory sleds including primarily memory resources). The disaggregation of resources in this manner, and the selective allocation and deallocation of the disaggregated resources to form a managed node assigned to execute a workload, improves the operation and resource usage of the data center 200 relative to typical data centers. Such typical data centers include hyperconverged servers containing compute, memory, storage and perhaps additional resources in a single chassis. For example, because a given sled will contain mostly resources of a same particular type, resources of that type can be upgraded independently of other resources. Additionally, because different resource types (programmable circuitry, storage, accelerators, etc.) typically have different refresh rates, greater resource utilization and reduced total cost of ownership may be achieved. For example, a data center operator can upgrade the programmable circuitry throughout a facility by only swapping out the compute sleds. In such a case, accelerator and storage resources may not be contemporaneously upgraded and, rather, may be allowed to continue operating until those resources are scheduled for their own refresh. Resource utilization may also increase. For example, if managed nodes are composed based on requirements of the workloads that will be running on them, resources within a node are more likely to be fully utilized. Such utilization may allow for more managed nodes to run in a data center with a given set of resources, or for a data center expected to run a given set of workloads, to be built using fewer resources.

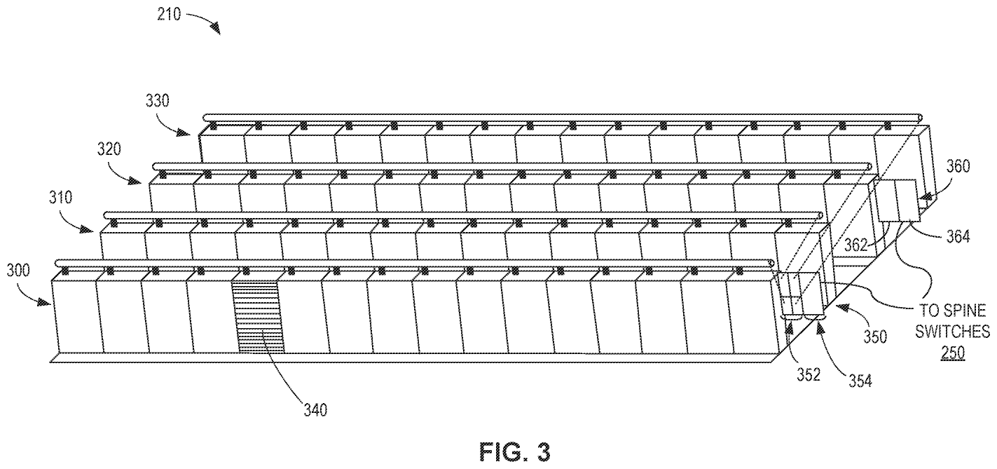

Referring now to FIG. 3, the pod 210, in the illustrative example, includes a set of rows 300, 310, 320, 330 of racks 340. Individual ones of the racks 340 may house multiple sleds (e.g., sixteen sleds) and provide power and data connections to the housed sleds, as described in more detail herein. In the illustrative example, the racks are connected to multiple pod switches 350, 360. The pod switch 350 includes a set of ports 352 to which the sleds of the racks of the pod 210 are connected and another set of ports 354 that connect the pod 210 to the spine switches 250 to provide connectivity to other pods in the data center 200. Similarly, the pod switch 360 includes a set of ports 362 to which the sleds of the racks of the pod 210 are connected and a set of ports 364 that connect the pod 210 to the spine switches 250. As such, the use of the pair of switches 350, 360 provides an amount of redundancy to the pod 210. For example, if either of the switches 350, 360 fails, the sleds in the pod 210 may still maintain data communication with the remainder of the data center 200 (e.g., sleds of other pods) through the other switch 350, 360. Furthermore, in the illustrative example, the switches 250, 350, 360 may be implemented as dual-mode optical switches, capable of routing both Ethernet protocol communications carrying Internet Protocol (IP) packets and communications according to a second, high-performance link-layer protocol (e.g., PCI Express) via optical signaling media of an optical fabric.

It should be appreciated that any one of the other pods 220, 230, 240 (as well as any additional pods of the data center 200) may be similarly structured as, and have components similar to, the pod 210 shown in and disclosed in regard to FIG. 3 (e.g., a given pod may have rows of racks housing multiple sleds as described above). Additionally, while two pod switches 350, 360 are shown, it should be understood that in other examples, a different number of pod switches may be present, providing even more failover capacity. In other examples, pods may be arranged differently than the rows-of-racks configuration shown in FIGS. 2 and 3. For example, a pod may include multiple sets of racks arranged radially, i.e., the racks are equidistant from a center switch.

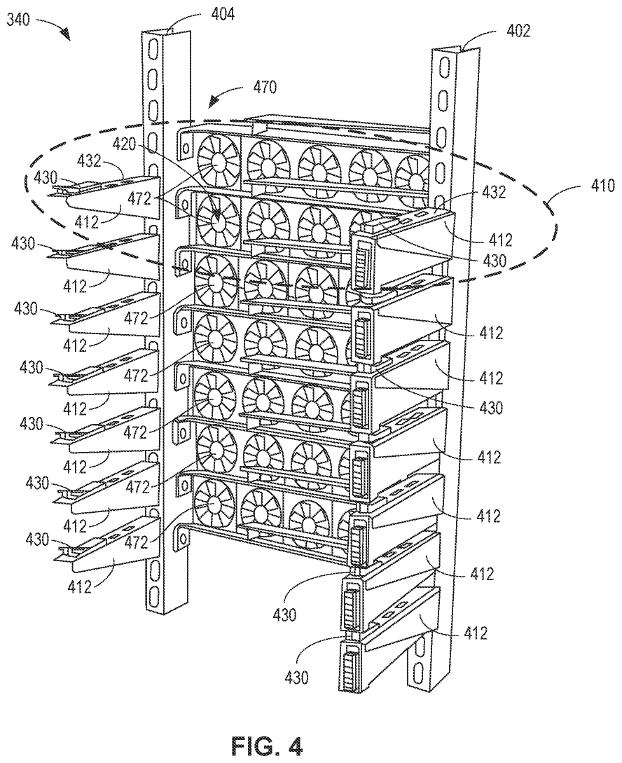

FIGS. 4-6 illustrate an example rack 340 of the data center 200. As shown in the illustrated example, the rack 340 includes two elongated support posts 402, 404, which are arranged vertically. For example, the elongated support posts 402, 404 may extend upwardly from a floor of the data center 200 when deployed. The rack 340 also includes one or more horizontal pairs 410 of elongated support arms 412 (identified in FIG. 4 via a dashed ellipse) configured to support a sled of the data center 200 as discussed below. One elongated support arm 412 of the pair of elongated support arms 412 extends outwardly from the elongated support post 402 and the other elongated support arm 412 extends outwardly from the elongated support post 404.

In the illustrative examples, at least some of the sleds of the data center 200 are chassis-less sleds. That is, such sleds have a chassis-less circuit board substrate on which physical resources (e.g., programmable circuitry, memory, accelerators, storage, etc.) are mounted as discussed in more detail below. As such, the rack 340 is configured to receive the chassis-less sleds. For example, a given pair 410 of the elongated support arms 412 defines a sled slot 420 of the rack 340, which is configured to receive a corresponding chassis-less sled. To do so, the elongated support arms 412 include corresponding circuit board guides 430 configured to receive the chassis-less circuit board substrate of the sled. The circuit board guides 430 are secured to, or otherwise mounted to, a top side 432 of the corresponding elongated support arms 412. For example, in the illustrative example, the circuit board guides 430 are mounted at a distal end of the corresponding elongated support arm 412 relative to the corresponding elongated support post 402, 404. For clarity of FIGS. 4-6, not every circuit board guide 430 may be referenced in each figure. In some examples, at least some of the sleds include a chassis and the racks 340 are suitably adapted to receive the chassis.

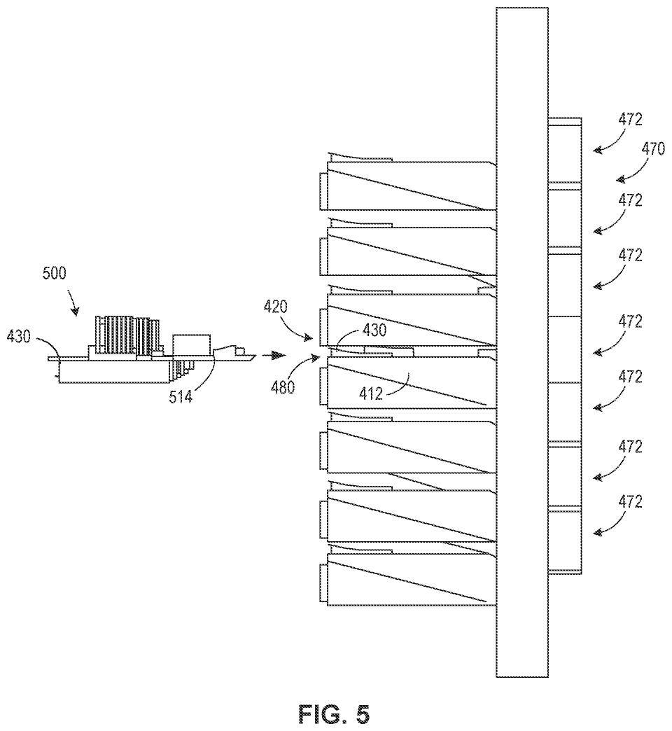

The circuit board guides 430 include an inner wall that defines a circuit board slot 480 configured to receive the chassis-less circuit board substrate of a sled 500 when the sled 500 is received in the corresponding sled slot 420 of the rack 340. To do so, as shown in FIG. 5, a user (or robot) aligns the chassis-less circuit board substrate of an illustrative chassis-less sled 500 to a sled slot 420. The user, or robot, may then slide the chassis-less circuit board substrate forward into the sled slot 420 such that each side edge 514 of the chassis-less circuit board substrate is received in a corresponding circuit board slot 480 of the circuit board guides 430 of the pair 410 of elongated support arms 412 that define the corresponding sled slot 420 as shown in FIG. 5. By having robotically accessible and robotically manipulable sleds including disaggregated resources, the different types of resource can be upgraded independently of one other and at their own optimized refresh rate. Furthermore, the sleds are configured to blindly mate with power and data communication cables in the rack 340, enhancing their ability to be quickly removed, upgraded, reinstalled, and/or replaced. As such, in some examples, the data center 200 may operate (e.g., execute workloads, undergo maintenance and/or upgrades, etc.) without human involvement on the data center floor. In other examples, a human may facilitate one or more maintenance or upgrade operations in the data center 200.

It should be appreciated that the circuit board guides 430 are dual sided. That is, a circuit board guide 430 includes an inner wall that defines a circuit board slot 480 on each side of the circuit board guide 430. In this way, the circuit board guide 430 can support a chassis-less circuit board substrate on either side. As such, a single additional elongated support post may be added to the rack 340 to turn the rack 340 into a two-rack solution that can hold twice as many sled slots 420 as shown in FIG. 4. The illustrative rack 340 includes seven pairs 410 of elongated support arms 412 that define seven corresponding sled slots 420. The sled slots 420 are configured to receive and support a corresponding sled 500 as discussed above. In other examples, the rack 340 may include additional or fewer pairs 410 of elongated support arms 412 (i.e., additional or fewer sled slots 420). It should be appreciated that because the sled 500 is chassis-less, the sled 500 may have an overall height that is different than typical servers. As such, in some examples, the height of a given sled slot 420 may be shorter than the height of a typical server (e.g., shorter than a single rank unit, referred to as “1U”). That is, the vertical distance between pairs 410 of elongated support arms 412 may be less than a standard rack unit “1U.” Additionally, due to the relative decrease in height of the sled slots 420, the overall height of the rack 340 in some examples may be shorter than the height of traditional rack enclosures. For example, in some examples, the elongated support posts 402, 404 may have a length of six feet or less. Again, in other examples, the rack 340 may have different dimensions. For example, in some examples, the vertical distance between pairs 410 of elongated support arms 412 may be greater than a standard rack unit “1U”. In such examples, the increased vertical distance between the sleds allows for larger heatsinks to be attached to the physical resources and for larger fans to be used (e.g., in the fan array 470 described below) for cooling the sleds, which in turn can allow the physical resources to operate at increased power levels. Further, it should be appreciated that the rack 340 does not include any walls, enclosures, or the like. Rather, the rack 340 is an enclosure-less rack that is opened to the local environment. In some cases, an end plate may be attached to one of the elongated support posts 402, 404 in those situations in which the rack 340 forms an end-of-row rack in the data center 200.

In some examples, various interconnects may be routed upwardly or downwardly through the elongated support posts 402, 404. To facilitate such routing, the elongated support posts 402, 404 include an inner wall that defines an inner chamber in which interconnects may be located. The interconnects routed through the elongated support posts 402, 404 may be implemented as any type of interconnects including, but not limited to, data or communication interconnects to provide communication connections to the sled slots 420, power interconnects to provide power to the sled slots 420, and/or other types of interconnects.

The rack 340, in the illustrative example, includes a support platform on which a corresponding optical data connector (not shown) is mounted. Such optical data connectors are associated with corresponding sled slots 420 and are configured to mate with optical data connectors of corresponding sleds 500 when the sleds 500 are received in the corresponding sled slots 420. In some examples, optical connections between components (e.g., sleds, racks, and switches) in the data center 200 are made with a blind mate optical connection. For example, a door on a given cable may prevent dust from contaminating the fiber inside the cable. In the process of connecting to a blind mate optical connector mechanism, the door is pushed open when the end of the cable approaches or enters the connector mechanism. Subsequently, the optical fiber inside the cable may enter a gel within the connector mechanism and the optical fiber of one cable comes into contact with the optical fiber of another cable within the gel inside the connector mechanism.

The illustrative rack 340 also includes a fan array 470 coupled to the cross-support arms of the rack 340. The fan array 470 includes one or more rows of cooling fans 472, which are aligned in a horizontal line between the elongated support posts 402, 404. In the illustrative example, the fan array 470 includes a row of cooling fans 472 for the different sled slots 420 of the rack 340. As discussed above, the sleds 500 do not include any on-board cooling system in the illustrative example and, as such, the fan array 470 provides cooling for such sleds 500 received in the rack 340. In other examples, some or all of the sleds 500 can include on-board cooling systems. Further, in some examples, the sleds 500 and/or the racks 340 may include and/or incorporate a liquid and/or immersion cooling system to facilitate cooling of electronic component(s) on the sleds 500. The rack 340, in the illustrative example, also includes different power supplies associated with different ones of the sled slots 420. A given power supply is secured to one of the elongated support arms 412 of the pair 410 of elongated support arms 412 that define the corresponding sled slot 420. For example, the rack 340 may include a power supply coupled or secured to individual ones of the elongated support arms 412 extending from the elongated support post 402. A given power supply includes a power connector configured to mate with a power connector of a sled 500 when the sled 500 is received in the corresponding sled slot 420. In the illustrative example, the sled 500 does not include any on-board power supply and, as such, the power supplies provided in the rack 340 supply power to corresponding sleds 500 when mounted to the rack 340. A given power supply is configured to satisfy the power requirements for its associated sled, which can differ from sled to sled. Additionally, the power supplies provided in the rack 340 can operate independent of each other. That is, within a single rack, a first power supply providing power to a compute sled can provide power levels that are different than power levels supplied by a second power supply providing power to an accelerator sled. The power supplies may be controllable at the sled level or rack level, and may be controlled locally by components on the associated sled or remotely, such as by another sled or an orchestrator.

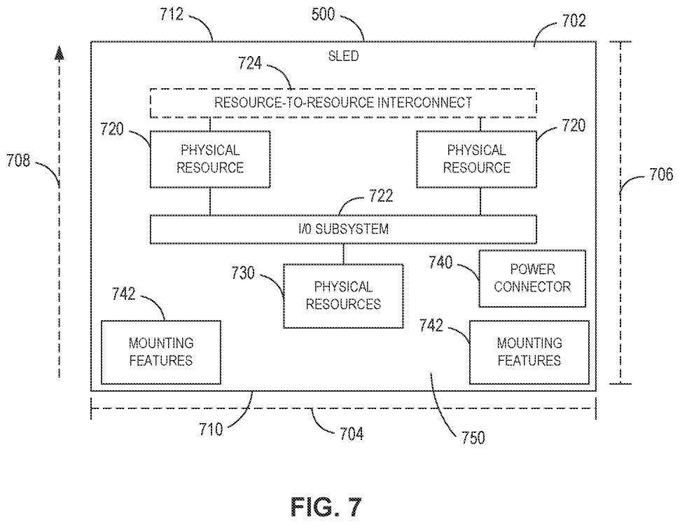

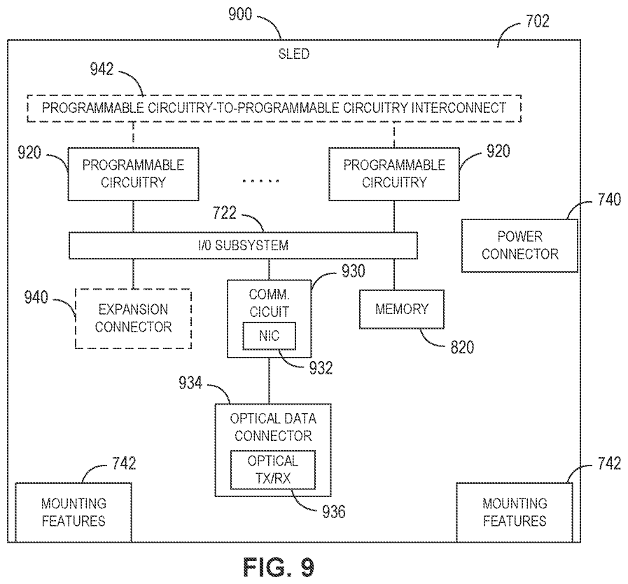

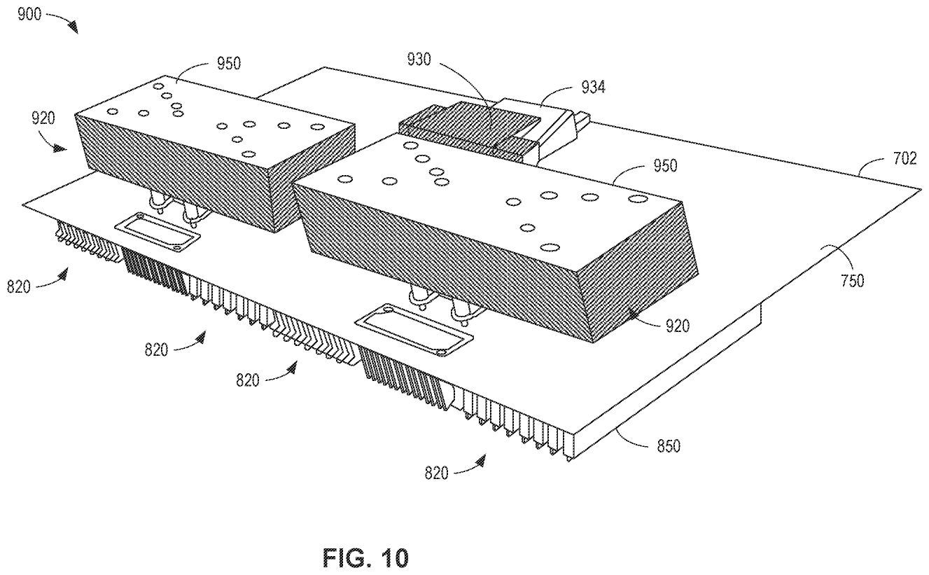

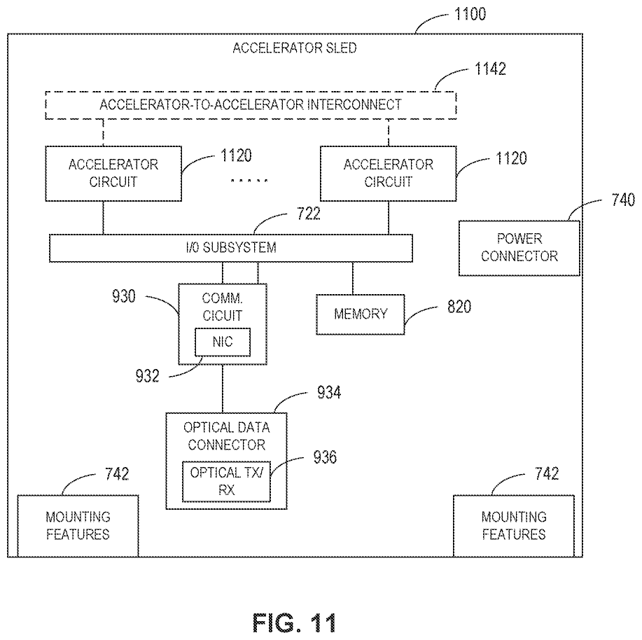

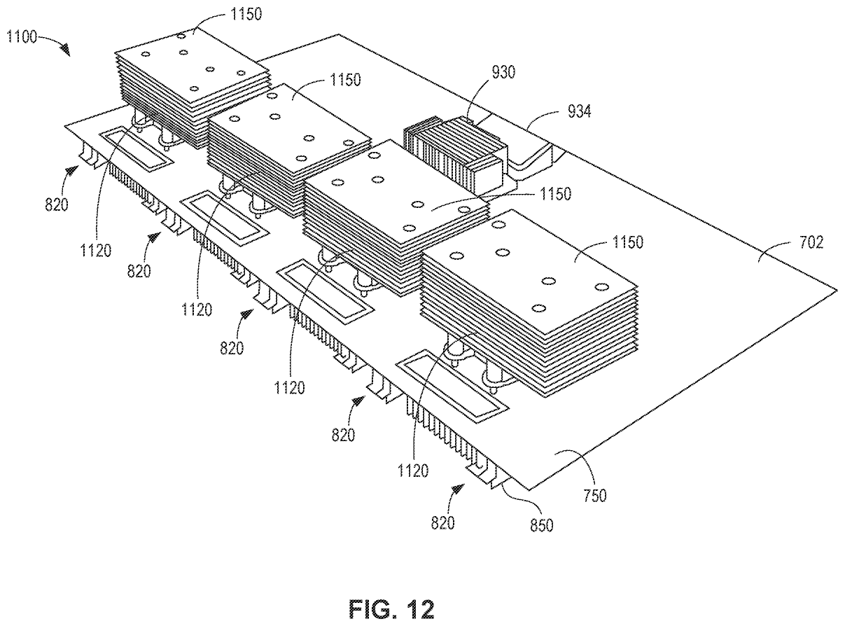

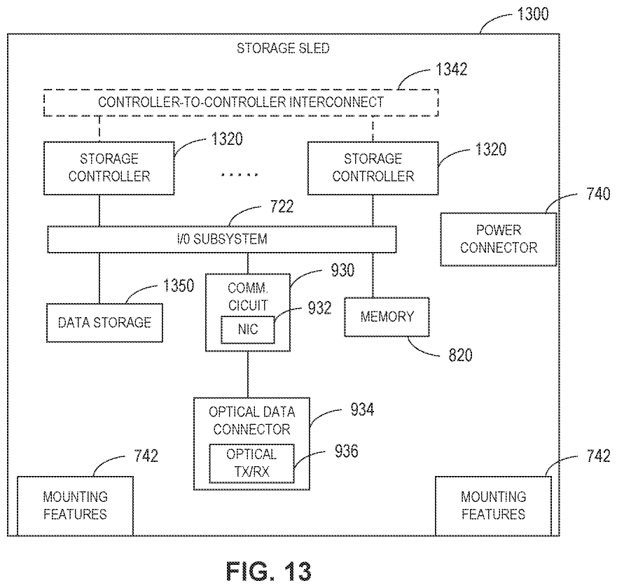

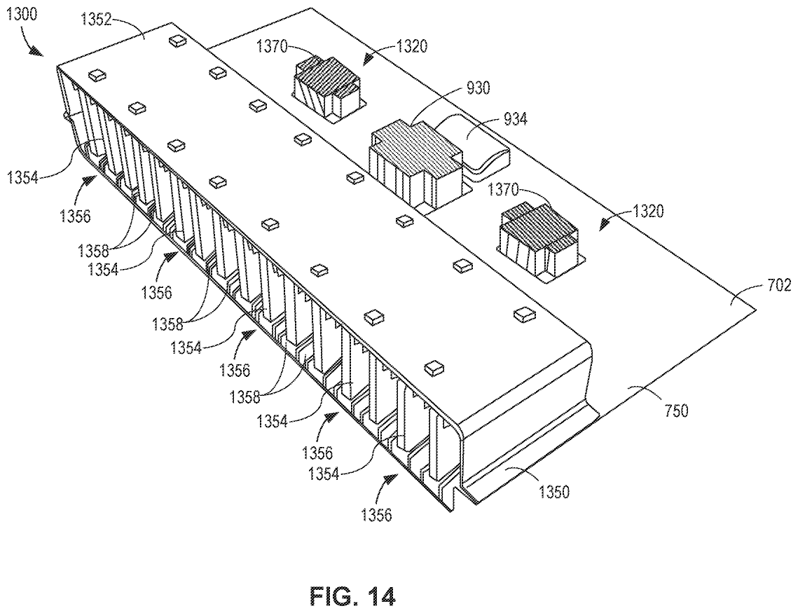

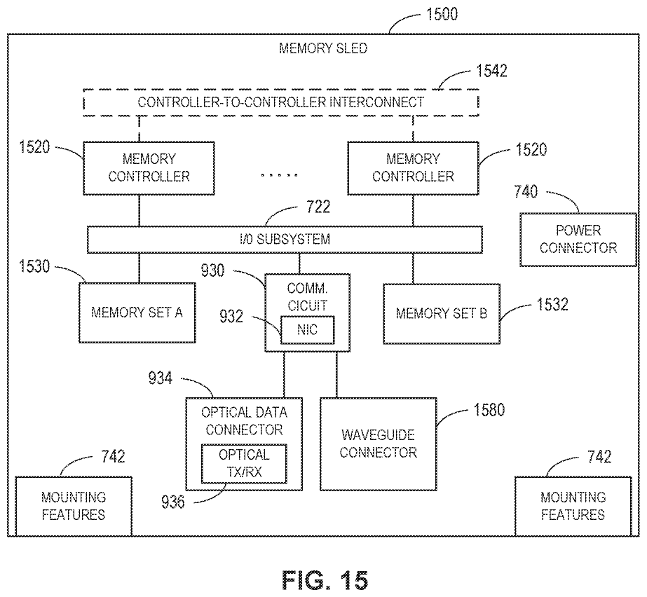

Referring now to FIG. 7, the sled 500, in the illustrative example, is configured to be mounted in a corresponding rack 340 of the data center 200 as discussed above. In some examples, a given sled 500 may be optimized or otherwise configured for performing particular tasks, such as compute tasks, acceleration tasks, data storage tasks, etc. For example, the sled 500 may be implemented as a compute sled 900 as discussed below in regard to FIGS. 9 and 10, an accelerator sled 1100 as discussed below in regard to FIGS. 11 and 12, a storage sled 1300 as discussed below in regard to FIGS. 13 and 14, or as a sled optimized or otherwise configured to perform other specialized tasks, such as a memory sled 1500, discussed below in regard to FIG. 15.

As discussed above, the illustrative sled 500 includes a chassis-less circuit board substrate 702, which supports various physical resources (e.g., electrical components) mounted thereon. It should be appreciated that the circuit board substrate 702 is “chassis-less” in that the sled 500 does not include a housing or enclosure. Rather, the chassis-less circuit board substrate 702 is open to the local environment. The chassis-less circuit board substrate 702 may be formed from any material capable of supporting the various electrical components mounted thereon. For example, in an illustrative example, the chassis-less circuit board substrate 702 is formed from an FR-4 glass-reinforced epoxy laminate material. Other materials may be used to form the chassis-less circuit board substrate 702 in other examples.

As discussed in more detail below, the chassis-less circuit board substrate 702 includes multiple features that improve the thermal cooling characteristics of the various electrical components mounted on the chassis-less circuit board substrate 702. As discussed, the chassis-less circuit board substrate 702 does not include a housing or enclosure, which may improve the airflow over the electrical components of the sled 500 by reducing those structures that may inhibit air flow. For example, because the chassis-less circuit board substrate 702 is not positioned in an individual housing or enclosure, there is no vertically-arranged backplane (e.g., a back plate of the chassis) attached to the chassis-less circuit board substrate 702, which could inhibit air flow across the electrical components. Additionally, the chassis-less circuit board substrate 702 has a geometric shape configured to reduce the length of the airflow path across the electrical components mounted to the chassis-less circuit board substrate 702. For example, the illustrative chassis-less circuit board substrate 702 has a width 704 that is greater than a depth 706 of the chassis-less circuit board substrate 702. In one particular example, the chassis-less circuit board substrate 702 has a width of about 21 inches and a depth of about 9 inches, compared to a typical server that has a width of about 17 inches and a depth of about 39 inches. As such, an airflow path 708 that extends from a front edge 710 of the chassis-less circuit board substrate 702 toward a rear edge 712 has a shorter distance relative to typical servers, which may improve the thermal cooling characteristics of the sled 500. Furthermore, although not illustrated in FIG. 7, the various physical resources mounted to the chassis-less circuit board substrate 702 in this example are mounted in corresponding locations such that no two substantively heat-producing electrical components shadow each other as discussed in more detail below. That is, no two electrical components, which produce appreciable heat during operation (i.e., greater than a nominal heat sufficient enough to adversely impact the cooling of another electrical component), are mounted to the chassis-less circuit board substrate 702 linearly in-line with each other along the direction of the airflow path 708 (i.e., along a direction extending from the front edge 710 toward the rear edge 712 of the chassis-less circuit board substrate 702). The placement and/or structure of the features may be suitable adapted when the electrical component(s) are being cooled via liquid (e.g., one phase or two phase cooling).

As discussed above, the illustrative sled 500 includes one or more physical resources 720 mounted to a top side 750 of the chassis-less circuit board substrate 702. Although two physical resources 720 are shown in FIG. 7, it should be appreciated that the sled 500 may include one, two, or more physical resources 720 in other examples. The physical resources 720 may be implemented as any type of programmable circuitry, controller, or other compute circuit capable of performing various tasks such as compute functions and/or controlling the functions of the sled 500 depending on, for example, the type or intended functionality of the sled 500. For example, as discussed in more detail below, the physical resources 720 may be implemented as high-performance processor circuitry in examples in which the sled 500 is implemented as a compute sled, as accelerator co-processor circuitry or circuits in examples in which the sled 500 is implemented as an accelerator sled, storage controllers in examples in which the sled 500 is implemented as a storage sled, or a set of memory devices in examples in which the sled 500 is implemented as a memory sled.

The sled 500 also includes one or more additional physical resources 730 mounted to the top side 750 of the chassis-less circuit board substrate 702. In the illustrative example, the additional physical resources include a network interface controller (NIC) as discussed in more detail below. Depending on the type and functionality of the sled 500, the physical resources 730 may include additional or other electrical components, circuits, and/or devices in other examples.

The physical resources 720 are communicatively coupled to the physical resources 730 via an input/output (I/O) subsystem 722. The I/O subsystem 722 may be implemented as circuitry and/or components to facilitate input/output operations with the physical resources 720, the physical resources 730, and/or other components of the sled 500. For example, the I/O subsystem 722 may be implemented as, or otherwise include, memory controller hubs, input/output control hubs, integrated sensor hubs, firmware devices, communication links (e.g., point-to-point links, bus links, wires, cables, waveguides, light guides, printed circuit board traces, etc.), and/or other components and subsystems to facilitate the input/output operations. In the illustrative example, the I/O subsystem 722 is implemented as, or otherwise includes, a double data rate 4 (DDR4) data bus or a DDR5 data bus.

In some examples, the sled 500 may also include a resource-to-resource interconnect 724. The resource-to-resource interconnect 724 may be implemented as any type of communication interconnect capable of facilitating resource-to-resource communications. In the illustrative example, the resource-to-resource interconnect 724 is implemented as a high-speed point-to-point interconnect (e.g., faster than the I/O subsystem 722). For example, the resource-to-resource interconnect 724 may be implemented as a QuickPath Interconnect (QPI), an UltraPath Interconnect (UPI), or other high-speed point-to-point interconnect dedicated to resource-to-resource communications.

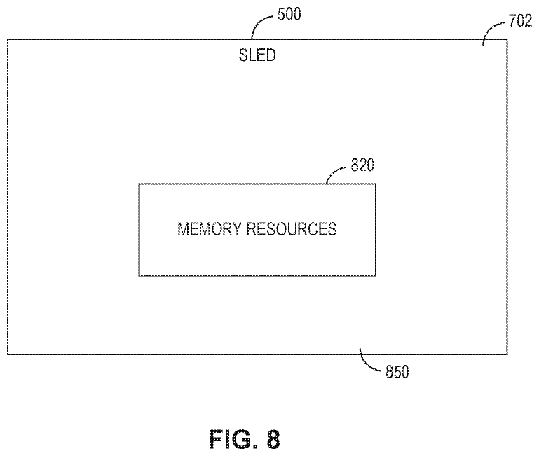

The sled 500 also includes a power connector 740 configured to mate with a corresponding power connector of the rack 340 when the sled 500 is mounted in the corresponding rack 340. The sled 500 receives power from a power supply of the rack 340 via the power connector 740 to supply power to the various electrical components of the sled 500. That is, the sled 500 does not include any local power supply (i.e., an on-board power supply) to provide power to the electrical components of the sled 500. The exclusion of a local or on-board power supply facilitates the reduction in the overall footprint of the chassis-less circuit board substrate 702, which may increase the thermal cooling characteristics of the various electrical components mounted on the chassis-less circuit board substrate 702 as discussed above. In some examples, voltage regulators are placed on a bottom side 850 (see FIG. 8) of the chassis-less circuit board substrate 702 directly opposite of programmable circuitry 920 (see FIG. 9), and power is routed from the voltage regulators to the programmable circuitry 920 by vias extending through the circuit board substrate 702. Such a configuration provides an increased thermal budget, additional current and/or voltage, and better voltage control relative to typical printed circuit boards in which processor power is delivered from a voltage regulator, in part, by printed circuit traces.

In some examples, the sled 500 may also include mounting features 742 configured to mate with a mounting arm, or other structure, of a robot to facilitate the placement of the sled 500 in a rack 340 by the robot. The mounting features 742 may be implemented as any type of physical structures that allow the robot to grasp the sled 500 without damaging the chassis-less circuit board substrate 702 or the electrical components mounted thereto. For example, in some examples, the mounting features 742 may be implemented as non-conductive pads attached to the chassis-less circuit board substrate 702. In other examples, the mounting features may be implemented as brackets, braces, or other similar structures attached to the chassis-less circuit board substrate 702. The particular number, shape, size, and/or make-up of the mounting feature 742 may depend on the design of the robot configured to manage the sled 500.

Referring now to FIG. 8, in addition to the physical resources 730 mounted on the top side 750 of the chassis-less circuit board substrate 702, the sled 500 also includes one or more memory devices 820 mounted to a bottom side 850 of the chassis-less circuit board substrate 702. That is, the chassis-less circuit board substrate 702 is implemented as a double-sided circuit board. The physical resources 720 are communicatively coupled to the memory devices 820 via the I/O subsystem 722. For example, the physical resources 720 and the memory devices 820 may be communicatively coupled by one or more vias extending through the chassis-less circuit board substrate 702. Different ones of the physical resources 720 may be communicatively coupled to different sets of one or more memory devices 820 in some examples. Alternatively, in other examples, different ones of the physical resources 720 may be communicatively coupled to the same ones of the memory devices 820.

The memory devices 820 may be implemented as any type of memory device capable of storing data for the physical resources 720 during operation of the sled 500, such as any type of volatile (e.g., dynamic random access memory (DRAM), etc.) or non-volatile memory. Volatile memory may be a storage medium that requires power to maintain the state of data stored by the medium. Non-limiting examples of volatile memory may include various types of random access memory (RAM), such as dynamic random access memory (DRAM) or static random access memory (SRAM). One particular type of DRAM that may be used in a memory module is synchronous dynamic random access memory (SDRAM). In particular examples, DRAM of a memory component may comply with a standard promulgated by JEDEC, such as JESD79F for DDR SDRAM, JESD79-2F for DDR2 SDRAM, JESD79-3F for DDR3 SDRAM, JESD79-4A for DDR4 SDRAM, JESD209 for Low Power DDR (LPDDR), JESD209-2 for LPDDR2, JESD209-3 for LPDDR3, and JESD209-4 for LPDDR4. Such standards (and similar standards) may be referred to as DDR-based standards and communication interfaces of the storage devices that implement such standards may be referred to as DDR-based interfaces.

In one example, the memory device is a block addressable memory device, such as those based on NAND or NOR technologies. A memory device may also include next-generation nonvolatile devices, such as Intel 3D XPoint™ memory or other byte addressable write-in-place nonvolatile memory devices. In one example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory. The memory device may refer to the die itself and/or to a packaged memory product. In some examples, the memory device may include a transistor-less stackable cross point architecture in which memory cells sit at the intersection of word lines and bit lines and are individually addressable and in which bit storage is based on a change in bulk resistance.

Referring now to FIG. 9, in some examples, the sled 500 may be implemented as a compute sled 900. The compute sled 900 is optimized, or otherwise configured, to perform compute tasks. As discussed above, the compute sled 900 may rely on other sleds, such as acceleration sleds and/or storage sleds, to perform such compute tasks. The compute sled 900 includes various physical resources (e.g., electrical components) similar to the physical resources of the sled 500, which have been identified in FIG. 9 using the same reference numbers. The description of such components provided above in regard to FIGS. 7 and 8 applies to the corresponding components of the compute sled 900 and is not repeated herein for clarity of the description of the compute sled 900.

In the illustrative compute sled 900, the physical resources 720 include programmable circuitry 920. Although only two blocks of programmable circuitry 920 are shown in FIG. 9, it should be appreciated that the compute sled 900 may include additional programmable circuits 920 in other examples. Illustratively, the programmable circuitry 920 corresponds to high-performance processor circuitry 920 and may be configured to operate at a relatively high power rating. Although the high-performance programmable circuitry 920 generates additional heat operating at power ratings greater than typical processor circuitry (which operate at around 155-230 W), the enhanced thermal cooling characteristics of the chassis-less circuit board substrate 702 discussed above facilitate the higher power operation. For example, in the illustrative example, the programmable circuitry 920 is configured to operate at a power rating of at least 250 W. In some examples, the programmable circuitry 920 may be configured to operate at a power rating of at least 350 W.

In some examples, the compute sled 900 may also include a programmable circuitry-to-programmable circuitry interconnect 942. Similar to the resource-to-resource interconnect 724 of the sled 500 discussed above, the programmable circuitry-to-programmable circuitry interconnect 942 may be implemented as any type of communication interconnect capable of facilitating programmable circuitry-to-programmable circuitry interconnect 942 communications. In the illustrative example, the programmable circuitry-to-programmable circuitry interconnect 942 is implemented as a high-speed point-to-point interconnect (e.g., faster than the I/O subsystem 722). For example, the programmable circuitry-to-programmable circuitry interconnect 942 may be implemented as a QuickPath Interconnect (QPI), an UltraPath Interconnect (UPI), or other high-speed point-to-point interconnect dedicated to programmable circuitry-to-programmable circuitry communications.

The compute sled 900 also includes a communication circuit 930. The illustrative communication circuit 930 includes a network interface controller (NIC) 932, which may also be referred to as a host fabric interface (HFI). The NIC 932 may be implemented as, or otherwise include, any type of integrated circuit, discrete circuits, controller chips, chipsets, add-in-boards, daughtercards, network interface cards, or other devices that may be used by the compute sled 900 to connect with another compute device (e.g., with other sleds 500). In some examples, the NIC 932 may be implemented as part of a system-on-a-chip (SoC) that includes one or more processor circuits, or included on a multichip package that also contains one or more processor circuits. In some examples, the NIC 932 may include a local processor circuit (not shown) and/or a local memory (not shown) that are both local to the NIC 932. In such examples, the local processor circuit of the NIC 932 may be capable of performing one or more of the functions of the programmable circuitry 920. Additionally or alternatively, in such examples, the local memory of the NIC 932 may be integrated into one or more components of the compute sled at the board level, socket level, chip level, and/or other levels.

The communication circuit 930 is communicatively coupled to an optical data connector 934. The optical data connector 934 is configured to mate with a corresponding optical data connector of the rack 340 when the compute sled 900 is mounted in the rack 340. Illustratively, the optical data connector 934 includes a plurality of optical fibers which lead from a mating surface of the optical data connector 934 to an optical transceiver 936. The optical transceiver 936 is configured to convert incoming optical signals from the rack-side optical data connector to electrical signals and to convert electrical signals to outgoing optical signals to the rack-side optical data connector. Although shown as forming part of the optical data connector 934 in the illustrative example, the optical transceiver 936 may form a portion of the communication circuit 930 in other examples.

In some examples, the compute sled 900 may also include an expansion connector 940. In such examples, the expansion connector 940 is configured to mate with a corresponding connector of an expansion chassis-less circuit board substrate to provide additional physical resources to the compute sled 900. The additional physical resources may be used, for example, by the programmable circuitry 920 during operation of the compute sled 900. The expansion chassis-less circuit board substrate may be substantially similar to the chassis-less circuit board substrate 702 discussed above and may include various electrical components mounted thereto. The particular electrical components mounted to the expansion chassis-less circuit board substrate may depend on the intended functionality of the expansion chassis-less circuit board substrate. For example, the expansion chassis-less circuit board substrate may provide additional compute resources, memory resources, and/or storage resources. As such, the additional physical resources of the expansion chassis-less circuit board substrate may include, but is not limited to, processor circuitry, memory devices, storage devices, and/or accelerator circuits including, for example, field programmable gate arrays (FPGA), application-specific integrated circuits (ASICs), security co-processor circuits, graphics processing units (GPUs), machine learning circuits, or other specialized processor circuits, controllers, devices, and/or circuits.

Referring now to FIG. 10, an illustrative example of the compute sled 900 is shown. As shown, the programmable circuitry 920, communication circuit 930, and optical data connector 934 are mounted to the top side 750 of the chassis-less circuit board substrate 702. Any suitable attachment or mounting technology may be used to mount the physical resources of the compute sled 900 to the chassis-less circuit board substrate 702. For example, the various physical resources may be mounted in corresponding sockets (e.g., a processor circuit socket), holders, or brackets. In some cases, some of the electrical components may be directly mounted to the chassis-less circuit board substrate 702 via soldering or similar techniques.

As discussed above, the separate programmable circuitry 920 and the communication circuit 930 are mounted to the top side 750 of the chassis-less circuit board substrate 702 such that no two heat-producing, electrical components shadow each other. In the illustrative example, the programmable circuitry 920 and the communication circuit 930 are mounted in corresponding locations on the top side 750 of the chassis-less circuit board substrate 702 such that no two of those physical resources are linearly in-line with others along the direction of the airflow path 708. It should be appreciated that, although the optical data connector 934 is in-line with the communication circuit 930, the optical data connector 934 produces no or nominal heat during operation.

The memory devices 820 of the compute sled 900 are mounted to the bottom side 850 of the of the chassis-less circuit board substrate 702 as discussed above in regard to the sled 500. Although mounted to the bottom side 850, the memory devices 820 are communicatively coupled to the programmable circuitry 920 located on the top side 750 via the I/O subsystem 722. Because the chassis-less circuit board substrate 702 is implemented as a double-sided circuit board, the memory devices 820 and the programmable circuitry 920 may be communicatively coupled by one or more vias, connectors, or other mechanisms extending through the chassis-less circuit board substrate 702. Different programmable circuitry 920 (e.g., different processor circuitry) may be communicatively coupled to a different set of one or more memory devices 820 in some examples. Alternatively, in other examples, different programmable circuitry 920 (e.g., different processor circuitry) may be communicatively coupled to the same ones of the memory devices 820. In some examples, the memory devices 820 may be mounted to one or more memory mezzanines on the bottom side of the chassis-less circuit board substrate 702 and may interconnect with a corresponding programmable circuitry 920 through a ball-grid array.

Different programmable circuitry 920 (e.g., different processor circuitry) include and/or is associated with corresponding heatsinks 950 secured thereto. Due to the mounting of the memory devices 820 to the bottom side 850 of the chassis-less circuit board substrate 702 (as well as the vertical spacing of the sleds 500 in the corresponding rack 340), the top side 750 of the chassis-less circuit board substrate 702 includes additional “free” area or space that facilitates the use of heatsinks 950 having a larger size relative to traditional heatsinks used in typical servers. Additionally, due to the improved thermal cooling characteristics of the chassis-less circuit board substrate 702, none of the programmable circuitry heatsinks 950 include cooling fans attached thereto. That is, the heatsinks 950 may be fan-less heatsinks. In some examples, the heatsinks 950 mounted atop the programmable circuitry 920 may overlap with the heatsink attached to the communication circuit 930 in the direction of the airflow path 708 due to their increased size, as illustratively suggested by FIG. 10.

Referring now to FIG. 11, in some examples, the sled 500 may be implemented as an accelerator sled 1100. The accelerator sled 1100 is configured, to perform specialized compute tasks, such as machine learning, encryption, hashing, or other computational-intensive task. In some examples, for example, a compute sled 900 may offload tasks to the accelerator sled 1100 during operation. The accelerator sled 1100 includes various components similar to components of the sled 500 and/or the compute sled 900, which have been identified in FIG. 11 using the same reference numbers. The description of such components provided above in regard to FIGS. 7, 8, and 9 apply to the corresponding components of the accelerator sled 1100 and is not repeated herein for clarity of the description of the accelerator sled 1100.

In the illustrative accelerator sled 1100, the physical resources 720 include accelerator circuits 1120. Although only two accelerator circuits 1120 are shown in FIG. 11, it should be appreciated that the accelerator sled 1100 may include additional accelerator circuits 1120 in other examples. For example, as shown in FIG. 12, the accelerator sled 1100 may include four accelerator circuits 1120. The accelerator circuits 1120 may be implemented as any type of processor circuitry, co-processor circuitry, compute circuit, or other device capable of performing compute or processing operations. For example, the accelerator circuits 1120 may be implemented as, for example, field programmable gate arrays (FPGA), application-specific integrated circuits (ASICs), security co-processor circuitry, graphics processing units (GPUs), neuromorphic processor units, quantum computers, machine learning circuits, or other specialized processor circuitry, controllers, devices, and/or circuits.

In some examples, the accelerator sled 1100 may also include an accelerator-to-accelerator interconnect 1142. Similar to the resource-to-resource interconnect 724 of the sled 500 discussed above, the accelerator-to-accelerator interconnect 1142 may be implemented as any type of communication interconnect capable of facilitating accelerator-to-accelerator communications. In the illustrative example, the accelerator-to-accelerator interconnect 1142 is implemented as a high-speed point-to-point interconnect (e.g., faster than the I/O subsystem 722). For example, the accelerator-to-accelerator interconnect 1142 may be implemented as a QuickPath Interconnect (QPI), an UltraPath Interconnect (UPI), or other high-speed point-to-point interconnect dedicated to programmable circuitry-to-programmable circuitry communications. In some examples, the accelerator circuits 1120 may be daisy-chained with a primary accelerator circuit 1120 connected to the NIC 932 and memory 820 through the I/O subsystem 722 and a secondary accelerator circuit 1120 connected to the NIC 932 and memory 820 through a primary accelerator circuit 1120.

Referring now to FIG. 12, an illustrative example of the accelerator sled 1100 is shown. As discussed above, the accelerator circuits 1120, the communication circuit 930, and the optical data connector 934 are mounted to the top side 750 of the chassis-less circuit board substrate 702. Again, the individual accelerator circuits 1120 and communication circuit 930 are mounted to the top side 750 of the chassis-less circuit board substrate 702 such that no two heat-producing, electrical components shadow each other as discussed above. The memory devices 820 of the accelerator sled 1100 are mounted to the bottom side 850 of the of the chassis-less circuit board substrate 702 as discussed above in regard to the sled 500. Although mounted to the bottom side 850, the memory devices 820 are communicatively coupled to the accelerator circuits 1120 located on the top side 750 via the I/O subsystem 722 (e.g., through vias). Further, the accelerator circuits 1120 may include and/or be associated with a heatsink 1150 that is larger than a traditional heatsink used in a server. As discussed above with reference to the heatsinks 950 of FIG. 9, the heatsinks 1150 may be larger than traditional heatsinks because of the “free” area provided by the memory resources 820 being located on the bottom side 850 of the chassis-less circuit board substrate 702 rather than on the top side 750.

Referring now to FIG. 13, in some examples, the sled 500 may be implemented as a storage sled 1300. The storage sled 1300 is configured, to store data in a data storage 1350 local to the storage sled 1300. For example, during operation, a compute sled 900 or an accelerator sled 1100 may store and retrieve data from the data storage 1350 of the storage sled 1300. The storage sled 1300 includes various components similar to components of the sled 500 and/or the compute sled 900, which have been identified in FIG. 13 using the same reference numbers. The description of such components provided above in regard to FIGS. 7, 8, and 9 apply to the corresponding components of the storage sled 1300 and is not repeated herein for clarity of the description of the storage sled 1300.

In the illustrative storage sled 1300, the physical resources 720 includes storage controllers 1320. Although only two storage controllers 1320 are shown in FIG. 13, it should be appreciated that the storage sled 1300 may include additional storage controllers 1320 in other examples. The storage controllers 1320 may be implemented as any type of programmable circuitry, controller, or control circuit capable of controlling the storage and retrieval of data into the data storage 1350 based on requests received via the communication circuit 930. In the illustrative example, the storage controllers 1320 are implemented as relatively low-power programmable circuitry or controllers. For example, in some examples, the storage controllers 1320 may be configured to operate at a power rating of about 75 watts.

In some examples, the storage sled 1300 may also include a controller-to-controller interconnect 1342. Similar to the resource-to-resource interconnect 724 of the sled 500 discussed above, the controller-to-controller interconnect 1342 may be implemented as any type of communication interconnect capable of facilitating controller-to-controller communications. In the illustrative example, the controller-to-controller interconnect 1342 is implemented as a high-speed point-to-point interconnect (e.g., faster than the I/O subsystem 722). For example, the controller-to-controller interconnect 1342 may be implemented as a QuickPath Interconnect (QPI), an UltraPath Interconnect (UPI), or other high-speed point-to-point interconnect dedicated to programmable circuitry-to-programmable circuitry communications.

Referring now to FIG. 14, an illustrative example of the storage sled 1300 is shown. In the illustrative example, the data storage 1350 is implemented as, or otherwise includes, a storage cage 1352 configured to house one or more solid state drives (SSDs) 1354. To do so, the storage cage 1352 includes a number of mounting slots 1356, which are configured to receive corresponding solid state drives 1354. The mounting slots 1356 include a number of drive guides 1358 that cooperate to define an access opening of the corresponding mounting slot 1356. The storage cage 1352 is secured to the chassis-less circuit board substrate 702 such that the access openings face away from (i.e., toward the front of) the chassis-less circuit board substrate 702. As such, solid state drives 1354 are accessible while the storage sled 1300 is mounted in a corresponding rack 340. For example, a solid state drive 1354 may be swapped out of a rack 340 (e.g., via a robot) while the storage sled 1300 remains mounted in the corresponding rack 340.

The storage cage 1352 illustratively includes sixteen mounting slots 1356 and is capable of mounting and storing sixteen solid state drives 1354. The storage cage 1352 may be configured to store additional or fewer solid state drives 1354 in other examples. Additionally, in the illustrative example, the solid state drives are mounted vertically in the storage cage 1352, but may be mounted in the storage cage 1352 in a different orientation in other examples. A given solid state drive 1354 may be implemented as any type of data storage device capable of storing long term data. To do so, the solid state drives 1354 may include volatile and non-volatile memory devices discussed above.

As shown in FIG. 14, the storage controllers 1320, the communication circuit 930, and the optical data connector 934 are illustratively mounted to the top side 750 of the chassis-less circuit board substrate 702. Again, as discussed above, any suitable attachment or mounting technology may be used to mount the electrical components of the storage sled 1300 to the chassis-less circuit board substrate 702 including, for example, sockets (e.g., a processor circuit socket), holders, brackets, soldered connections, and/or other mounting or securing techniques.

As discussed above, the individual storage controllers 1320 and the communication circuit 930 are mounted to the top side 750 of the chassis-less circuit board substrate 702 such that no two heat-producing, electrical components shadow each other. For example, the storage controllers 1320 and the communication circuit 930 are mounted in corresponding locations on the top side 750 of the chassis-less circuit board substrate 702 such that no two of those electrical components are linearly in-line with each other along the direction of the airflow path 708.

The memory devices 820 (not shown in FIG. 14) of the storage sled 1300 are mounted to the bottom side 850 (not shown in FIG. 14) of the chassis-less circuit board substrate 702 as discussed above in regard to the sled 500. Although mounted to the bottom side 850, the memory devices 820 are communicatively coupled to the storage controllers 1320 located on the top side 750 via the I/O subsystem 722. Again, because the chassis-less circuit board substrate 702 is implemented as a double-sided circuit board, the memory devices 820 and the storage controllers 1320 may be communicatively coupled by one or more vias, connectors, or other mechanisms extending through the chassis-less circuit board substrate 702. The storage controllers 1320 include and/or are associated with a heatsink 1370 secured thereto. As discussed above, due to the improved thermal cooling characteristics of the chassis-less circuit board substrate 702 of the storage sled 1300, none of the heatsinks 1370 include cooling fans attached thereto. That is, the heatsinks 1370 may be fan-less heatsinks.

Referring now to FIG. 15, in some examples, the sled 500 may be implemented as a memory sled 1500. The storage sled 1500 is optimized, or otherwise configured, to provide other sleds 500 (e.g., compute sleds 900, accelerator sleds 1100, etc.) with access to a pool of memory (e.g., in two or more sets 1530, 1532 of memory devices 820) local to the memory sled 1300. For example, during operation, a compute sled 900 or an accelerator sled 1100 may remotely write to and/or read from one or more of the memory sets 1530, 1532 of the memory sled 1300 using a logical address space that maps to physical addresses in the memory sets 1530, 1532. The memory sled 1500 includes various components similar to components of the sled 500 and/or the compute sled 900, which have been identified in FIG. 15 using the same reference numbers. The description of such components provided above in regard to FIGS. 7, 8, and 9 apply to the corresponding components of the memory sled 1500 and is not repeated herein for clarity of the description of the memory sled 1500.

In the illustrative memory sled 1500, the physical resources 720 include memory controllers 1520. Although only two memory controllers 1520 are shown in FIG. 15, it should be appreciated that the memory sled 1500 may include additional memory controllers 1520 in other examples. The memory controllers 1520 may be implemented as any type of programmable circuitry, controller, or control circuit capable of controlling the writing and reading of data into the memory sets 1530, 1532 based on requests received via the communication circuit 930. In the illustrative example, the memory controllers 1520 are connected to corresponding memory sets 1530, 1532 to write to and read from memory devices 820 (not shown) within the corresponding memory set 1530, 1532 and enforce any permissions (e.g., read, write, etc.) associated with sled 500 that has sent a request to the memory sled 1500 to perform a memory access operation (e.g., read or write).

In some examples, the memory sled 1500 may also include a controller-to-controller interconnect 1542. Similar to the resource-to-resource interconnect 724 of the sled 500 discussed above, the controller-to-controller interconnect 1542 may be implemented as any type of communication interconnect capable of facilitating controller-to-controller communications. In the illustrative example, the controller-to-controller interconnect 1542 is implemented as a high-speed point-to-point interconnect (e.g., faster than the I/O subsystem 722). For example, the controller-to-controller interconnect 1542 may be implemented as a QuickPath Interconnect (QPI), an UltraPath Interconnect (UPI), or other high-speed point-to-point interconnect dedicated to programmable circuitry-to-programmable circuitry communications. As such, in some examples, a memory controller 1520 may access, through the controller-to-controller interconnect 1542, memory that is within the memory set 1532 associated with another memory controller 1520. In some examples, a scalable memory controller is made of multiple smaller memory controllers, referred to herein as “chiplets”, on a memory sled (e.g., the memory sled 1500). The chiplets may be interconnected (e.g., using EMIB (Embedded Multi-Die Interconnect Bridge) technology). The combined chiplet memory controller may scale up to a relatively large number of memory controllers and I/O ports, (e.g., up to 16 memory channels). In some examples, the memory controllers 1520 may implement a memory interleave (e.g., one memory address is mapped to the memory set 1530, the next memory address is mapped to the memory set 1532, and the third address is mapped to the memory set 1530, etc.). The interleaving may be managed within the memory controllers 1520, or from CPU sockets (e.g., of the compute sled 900) across network links to the memory sets 1530, 1532, and may improve the latency associated with performing memory access operations as compared to accessing contiguous memory addresses from the same memory device.

Further, in some examples, the memory sled 1500 may be connected to one or more other sleds 500 (e.g., in the same rack 340 or an adjacent rack 340) through a waveguide, using the waveguide connector 1580. In the illustrative example, the waveguides are 74 millimeter waveguides that provide 16 Rx (i.e., receive) lanes and 16 Tx (i.e., transmit) lanes. Different ones of the lanes, in the illustrative example, are either 16 GHz or 32 GHz. In other examples, the frequencies may be different. Using a waveguide may provide high throughput access to the memory pool (e.g., the memory sets 1530, 1532) to another sled (e.g., a sled 500 in the same rack 340 or an adjacent rack 340 as the memory sled 1500) without adding to the load on the optical data connector 934.

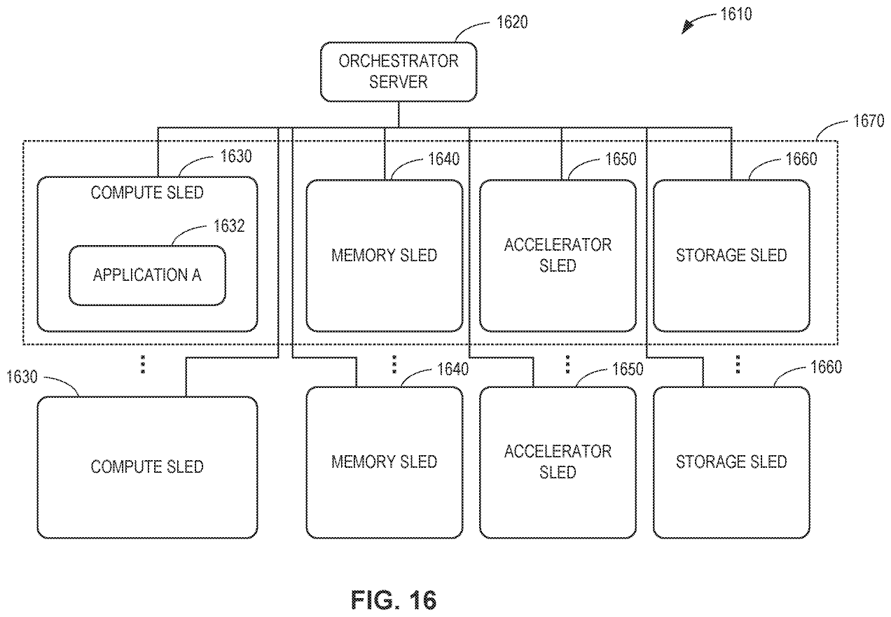

Referring now to FIG. 16, a system for executing one or more workloads (e.g., applications) may be implemented in accordance with the data center 200. In the illustrative example, the system 1610 includes an orchestrator server 1620, which may be implemented as a managed node including a compute device (e.g., programmable circuitry 920 on a compute sled 900) executing management software (e.g., a cloud operating environment, such as OpenStack) that is communicatively coupled to multiple sleds 500 including a large number of compute sleds 1630 (e.g., similar to the compute sled 900), memory sleds 1640 (e.g., similar to the memory sled 1500), accelerator sleds 1650 (e.g., similar to the memory sled 1500), and storage sleds 1660 (e.g., similar to the storage sled 1300). One or more of the sleds 1630, 1640, 1650, 1660 may be grouped into a managed node 1670, such as by the orchestrator server 1620, to collectively perform a workload (e.g., an application 1632 executed in a virtual machine or in a container). The managed node 1670 may be implemented as an assembly of physical resources 720, such as programmable circuitry 920, memory resources 820, accelerator circuits 1120, or data storage 1350, from the same or different sleds 500. Further, the managed node may be established, defined, or “spun up” by the orchestrator server 1620 at the time a workload is to be assigned to the managed node or at any other time, and may exist regardless of whether any workloads are presently assigned to the managed node. In the illustrative example, the orchestrator server 1620 may selectively allocate and/or deallocate physical resources 720 from the sleds 500 and/or add or remove one or more sleds 500 from the managed node 1670 as a function of quality of service (QoS) targets (e.g., a target throughput, a target latency, a target number of instructions per second, etc.) associated with a service level agreement for the workload (e.g., the application 1632). In doing so, the orchestrator server 1620 may receive telemetry data indicative of performance conditions (e.g., throughput, latency, instructions per second, etc.) in different ones of the sleds 500 of the managed node 1670 and compare the telemetry data to the quality of service targets to determine whether the quality of service targets are being satisfied. The orchestrator server 1620 may additionally determine whether one or more physical resources may be deallocated from the managed node 1670 while still satisfying the QoS targets, thereby freeing up those physical resources for use in another managed node (e.g., to execute a different workload). Alternatively, if the QoS targets are not presently satisfied, the orchestrator server 1620 may determine to dynamically allocate additional physical resources to assist in the execution of the workload (e.g., the application 1632) while the workload is executing. Similarly, the orchestrator server 1620 may determine to dynamically deallocate physical resources from a managed node if the orchestrator server 1620 determines that deallocating the physical resource would result in QoS targets still being met.

Additionally, in some examples, the orchestrator server 1620 may identify trends in the resource utilization of the workload (e.g., the application 1632), such as by identifying phases of execution (e.g., time periods in which different operations, having different resource utilizations characteristics, are performed) of the workload (e.g., the application 1632) and pre-emptively identifying available resources in the data center 200 and allocating them to the managed node 1670 (e.g., within a predefined time period of the associated phase beginning). In some examples, the orchestrator server 1620 may model performance based on various latencies and a distribution scheme to place workloads among compute sleds and other resources (e.g., accelerator sleds, memory sleds, storage sleds) in the data center 200. For example, the orchestrator server 1620 may utilize a model that accounts for the performance of resources on the sleds 500 (e.g., FPGA performance, memory access latency, etc.) and the performance (e.g., congestion, latency, bandwidth) of the path through the network to the resource (e.g., FPGA). As such, the orchestrator server 1620 may determine which resource(s) should be used with which workloads based on the total latency associated with different potential resource(s) available in the data center 200 (e.g., the latency associated with the performance of the resource itself in addition to the latency associated with the path through the network between the compute sled executing the workload and the sled 500 on which the resource is located).

In some examples, the orchestrator server 1620 may generate a map of heat generation in the data center 200 using telemetry data (e.g., temperatures, fan speeds, etc.) reported from the sleds 500 and allocate resources to managed nodes as a function of the map of heat generation and predicted heat generation associated with different workloads, to maintain a target temperature and heat distribution in the data center 200. Additionally or alternatively, in some examples, the orchestrator server 1620 may organize received telemetry data into a hierarchical model that is indicative of a relationship between the managed nodes (e.g., a spatial relationship such as the physical locations of the resources of the managed nodes within the data center 200 and/or a functional relationship, such as groupings of the managed nodes by the customers the managed nodes provide services for, the types of functions typically performed by the managed nodes, managed nodes that typically share or exchange workloads among each other, etc.). Based on differences in the physical locations and resources in the managed nodes, a given workload may exhibit different resource utilizations (e.g., cause a different internal temperature, use a different percentage of programmable circuitry or memory capacity) across the resources of different managed nodes. The orchestrator server 1620 may determine the differences based on the telemetry data stored in the hierarchical model and factor the differences into a prediction of future resource utilization of a workload if the workload is reassigned from one managed node to another managed node, to accurately balance resource utilization in the data center 200. In some examples, the orchestrator server 1620 may identify patterns in resource utilization phases of the workloads and use the patterns to predict future resource utilization of the workloads.

To reduce the computational load on the orchestrator server 1620 and the data transfer load on the network, in some examples, the orchestrator server 1620 may send self-test information to the sleds 500 to enable a given sled 500 to locally (e.g., on the sled 500) determine whether telemetry data generated by the sled 500 satisfies one or more conditions (e.g., an available capacity that satisfies a predefined threshold, a temperature that satisfies a predefined threshold, etc.). The given sled 500 may then report back a simplified result (e.g., yes or no) to the orchestrator server 1620, which the orchestrator server 1620 may utilize in determining the allocation of resources to managed nodes.

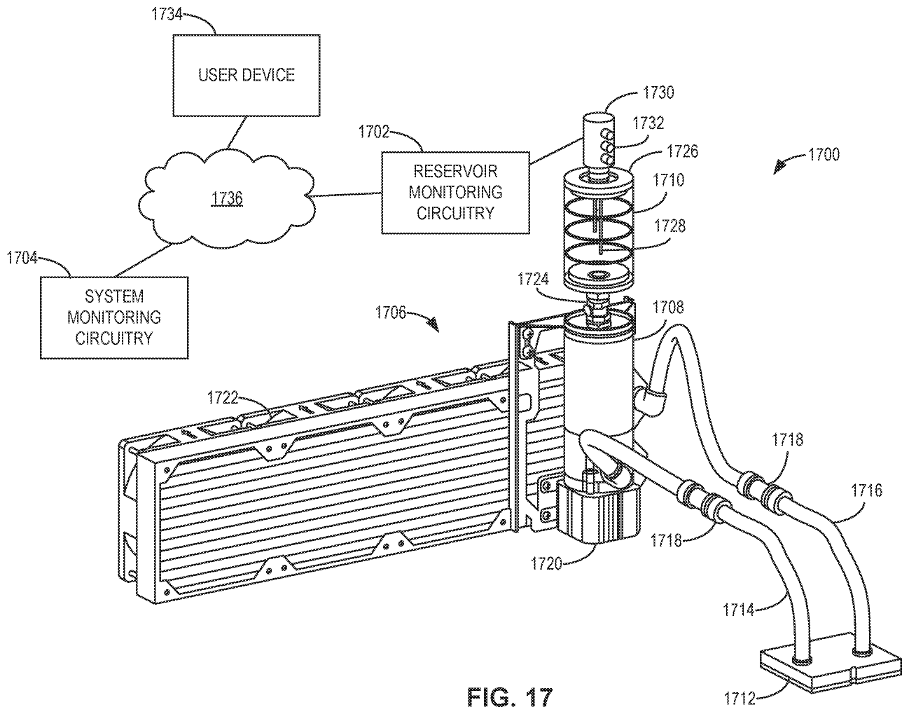

FIG. 17 illustrates an example environment 1700 including example reservoir monitoring circuitry 1702 and example system monitoring circuitry 1704 to monitor an example heat exchanger 1706 and associated example reservoirs 1708, 1710 in accordance with teachings of this disclosure. In the illustrated example of FIG. 17, the heat exchanger 1706 is a liquid air assisted cooling (LAAC) system which utilizes coolant from the first reservoir 1708 and/or the second reservoir 1710 to cool one or more electronic components (e.g., heat dissipating devices). In this example, the heat exchanger 1706 is fluidly coupled to an example cold plate 1712 via a first tube (e.g., a supply tube) 1714 and a second tube (e.g., a return tube) 1716. In this example, fittings (e.g., quick disconnect fittings) 1718 are implemented along the first and second tubes 1714, 1716 to facilitate coupling and/or decoupling of devices (e.g., cold plates) to and/or from the heat exchanger 1706.

In the example of FIG. 17, a pump 1720 is fluidly and/or operatively coupled to the first reservoir 1708. In operation, the pump 1720 causes circulation of coolant from the first reservoir 1708 to the cold plate 1712 via the first tube 1714, and from the cold plate 1712 to the heat exchanger 1706 via the second tube 1716. In this example, as the coolant passes through and/or across the cold plate 1712, the coolant draws heat from one or more electronic components operatively coupled to the cold plate 1712. The heated coolant returns to the heat exchanger 1706 via the second tube 1716, where the heated coolant can be air-cooled by operation of one or more fans 1722 of the heat exchanger 1706 before returning to the first reservoir 1708.

In some examples, loss of coolant can occur during operation of the heat exchanger 1706. For example, a relatively high heat load from the one or more electronic components coupled to the cold plate 1712 can result in evaporation of the coolant over time. In some examples, loss of coolant can occur when devices (e.g., the cold plate 1712) are connected to and/or disconnected from the heat exchanger 1706 at the fittings 1718. For example, some coolant may remain in the portions of the tubes 1714, 1716 that are disconnected from the heat exchanger 1706 at the fittings 1718, thus reducing an amount of coolant available to the heat exchanger 1706. Additionally or alternatively, leakage of coolant can occur along the tubes 1714, 1716 and/or between components of the heat exchanger 1706. In some examples, such loss of coolant can result in a coolant level in the first reservoir 1708 being less than a threshold. As a result, failure of and/or damage to the pump 1720 and/or one or more components of the heat exchanger 1706 can occur.

In the illustrated example of FIG. 17, the example second reservoir 1710 is fluidly coupled to the first reservoir 1708 to provide and/or supply additional coolant to the first reservoir 1708 when loss of coolant occurs. The second reservoir 1710 can deliver additional coolant to the first reservoir without user involvement. For example, the second reservoir 1710 is coupled (e.g., fluidly coupled) to a top portion of the first reservoir 1708 via an example fitting (e.g., a quick disconnect fitting) 1724, where gravity causes coolant from the second reservoir 1710 to flow to the first reservoir 1708 via the fitting 1724. In some examples, automatic flow of the coolant from the second reservoir 1710 to the first reservoir 1708 ensures the first reservoir 1708 remains filled with coolant (e.g., the amount of coolant in the first reservoir 1708 satisfies a threshold capacity of the first reservoir 1708) during operation of the heat exchanger 1706, thereby reducing risk of damage to the heat exchanger 1706 resulting from insufficient coolant levels in the first reservoir 1708.

In some examples, a coolant level of the coolant in the second reservoir 1710 can vary over time as the coolant from the second reservoir 1710 is provided to the first reservoir 1708. In some examples, loss of coolant in the second reservoir 1710 warrants provision of additional coolant to the second reservoir 1710. For example, an example cap 1726 removably coupled to the second reservoir 1710, and the cap 1726 can be removed to enable refilling of the second reservoir 1710 with coolant. Additionally or alternatively, the second reservoir 1710 can be decoupled (e.g., removed) from the first reservoir 1708 at the fitting 1724, and can be refilled at a second location before recoupling to the first reservoir 1708. In some examples, because the second reservoir 1710 is separate (e.g., fluidly decoupled) from an example closed loop flow path (e.g., including the first reservoir 1708, the tubing 1714, 1716, the cold plate 1712, and the heat exchanger 1706) of the coolant, the second reservoir 1710 can be refilling during operation of the heat exchanger 1706 (e.g., without halting operation of the heat exchanger 1706). Accordingly, examples disclosed herein can reduce downtime in the operation of the heat exchanger 1706.

In the example of FIG. 17, one or more sensors 1728 are operatively coupled to the second reservoir 1710 to detect a coolant level (e.g., a volume, a height, etc.) of the coolant in the second reservoir 1710. The sensor(s) 1728 can include, for example, liquid level sensors such as float switches, ultrasonic level sensors, radar level sensors, pressure sensors, capacitance or contact sensors, etc. In some examples, the sensors 1728 are communicatively coupled to the reservoir monitoring circuitry 1702 and/or the system monitoring circuitry 1704 to provide outputs thereto, where the outputs correspond to sensor data representative of the detected coolant level in the second reservoir 1710. Further, an example indicator 1730 is coupled to the second reservoir 1710 to indicate the coolant level and/or a status of the second reservoir 1710 to an operator. For example, the indicator 1730 can indicate whether the coolant level in the second reservoir 1710 is satisfactory (e.g., greater than or equal to a first example threshold level), low (e.g., less than the first threshold level and greater than or equal to a second example threshold level, and/or less than the second threshold level and greater than or equal to a third example threshold level), or critically low (e.g., less than the third threshold level). In this example, the indicator 1730 includes one or more example light sources 1732 to emit light based on the status and/or the coolant level. In some examples, a different type of indicator (e.g., an audio indicator, a display presenting text, etc.) can additionally or alternatively be used instead.

In the illustrated example of FIG. 17, the reservoir monitoring circuitry 1702 monitors the status and/or the coolant level of the second reservoir 1710. For example, the reservoir monitoring circuitry 1702 obtains the sensor data corresponding to outputs from the sensors 1728, and determines the coolant level in the second reservoir 1710 based on the sensor data. In some examples, based on an evaluation of the coolant level with respect to one or more thresholds (e.g., the first threshold level, the second threshold level, and/or the third threshold level), the reservoir monitoring circuitry 1702 determines the status of the second reservoir 1710 (e.g., whether the coolant level in the second reservoir 1710 is satisfactory, low, and/or critically low). In some examples, the reservoir monitoring circuitry 1702 is communicatively and/or operatively coupled to the indicator 1730, and the reservoir monitoring circuitry 1702 controls and/or adjusts the indicator 1730 based on the detected coolant level and/or status of the second reservoir 1710. For example, the reservoir monitoring circuitry 1702 can activate and/or deactivate one(s) of the light sources 1732 to indicate the coolant level and/or the status to an operator.

In some examples, the reservoir monitoring circuitry 1702 generates and/or causes alert(s) to be presented to an operator. The alert(s) can include visual alert(s), audio alert(s), etc. For example, the reservoir monitoring circuitry 1702 can generate the alert in response to determining that the coolant level in the second reservoir 1710 is low and/or critically low. In some example, the reservoir monitoring circuitry 1702 can generate the alert periodically (e.g., at a frequency selected by an operator). In some examples, the alert can include the status, the coolant level, a location (e.g., a grid location, a geographic location) of the second reservoir 1710, and/or an identifier associated with the second reservoir 1710. In some examples, the alert indicates an amount of coolant missing in the second reservoir 1710, and/or includes instructions for locating and/or accessing the second reservoir 1710. In some examples, the reservoir monitoring circuitry 1702 outputs the alert for presentation (e.g., display) at an example user device (e.g., a computer, a mobile device, etc.) 1734 of the operator, where the user device 1734 is communicatively coupled to the reservoir monitoring circuitry 1702 via an example network 1736. In some examples, by alerting the operator when refilling of the second reservoir 1710 is warranted, the reservoir monitoring circuitry 1702 can reduce a frequency of manual refilling and/or inspection of the second reservoir 1710 by an operator.

In the example of FIG. 17, the reservoir monitoring circuitry 1702 is communicatively coupled to the example system monitoring circuitry 1704 via the network 1736. In some examples, the reservoir monitoring circuitry 1702 provides example reservoir information to the system monitoring circuitry 1704 via the network 1736, where the reservoir information includes the coolant level, the status, the location, and/or the identifier associated with the second reservoir 1710. In some examples, the reservoir monitoring circuitry 1702 can be coupled to one or more additional devices (e.g., other user devices, cloud based devices) via the network 1736. In some such examples, the reservoir monitoring circuitry 1702 can provide the alerts and/or the reservoir information to the additional device(s) for presentation and/or storage thereon.

While one heat exchanger 1706 and one second reservoir 1710 are shown in the example environment 1700 of FIG. 17, some environments (e.g., data centers) implement an example system including multiple ones of the heat exchanger 1706 and/or multiple ones of the second reservoir 1710. In some such examples, the reservoir monitoring circuitry 1702 obtains sensor data for each of the heat exchangers 1706 in the system to monitor coolant levels thereof. Additionally or alternatively, multiple instances of the reservoir monitoring circuitry 1702 can be used to monitor coolant levels for one or more corresponding heat exchangers 1706.

For some systems implementing a relatively large number (e.g., hundreds, thousands, etc.) of heat exchangers, it may be difficult and/or impractical for an operator to manually inspect and/or monitor performance of individual one(s) of the heat exchangers. Accordingly, in the illustrated example of FIG. 17, the system monitoring circuitry 1704 can monitor and/or predict performance of an example system including multiple ones of the heat exchanger 1706 and/or the second reservoir 1710 of FIG. 17. For example, based on the reservoir information from one or more instances of the reservoir monitoring circuitry 1702 and/or based on user input(s) provided to the user device 1734, the system monitoring circuitry 1704 can detect and/or predict example anomalies associated with the coolant and/or the heat exchangers 1706, and/or can predict a remaining useful life (RUL) of the heat exchangers 1706. For example, the coolant anomalies can include evaporation and/or overheating of the coolant, leakage of the coolant, reduced efficiency of the coolant, pressure drop of the coolant, corrosion of equipment associated with the coolant, etc. In some examples, the hardware anomalies can include pump failures, fan failures, blocked air flow, fin damage, operating temperatures exceeding a threshold, etc. In some examples, the RUL represents a duration for which one(s) of heat exchangers 1706 can operate until maintenance and/or replacement of the one(s) of the heat exchangers 1706 is expected.

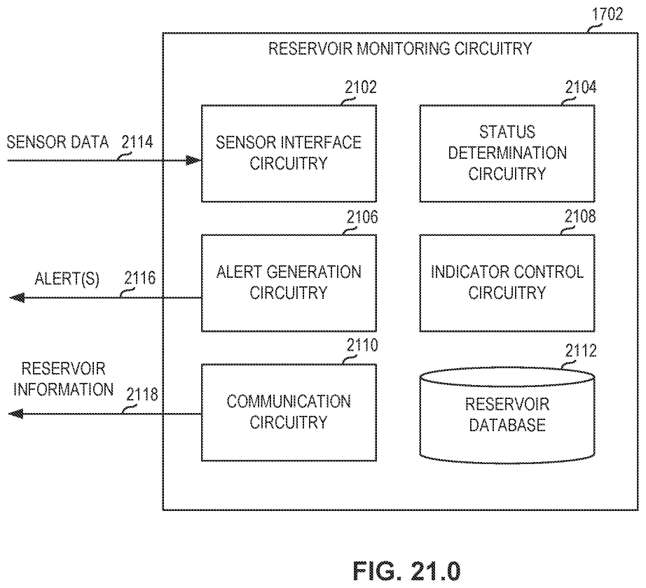

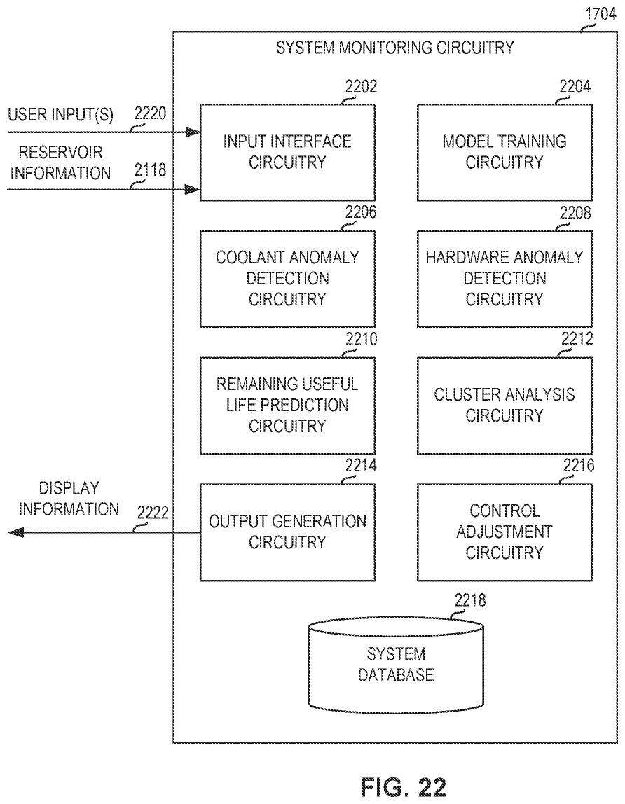

In some examples, the system monitoring circuitry 1704 predicts the anomalies and/or the RUL based on execution of one or more example models (e.g., machine learning models) trained based on historical data (e.g., past user input(s) and/or past reservoir information). In some examples, the system monitoring circuitry 1704 outputs the predicted anomalies and/or RUL for presentation to an operator to facilitate servicing of the heat exchangers 1706. Additionally or alternatively, the system monitoring circuitry 1704 can cause, based on the predicted anomalies and/or RUL, one or more control parameters (e.g., fan speed, pump rate, coolant flow rate, etc.) associated with the heat exchangers 1706 to be adjusted (e.g., in an effort to extend the RUL or mitigate effects of an expiring RUL). Operation of the reservoir monitoring circuitry 1702 and the system monitoring circuitry 1704 is described further in detail below in connection with FIGS. 21 and 22, respectively.

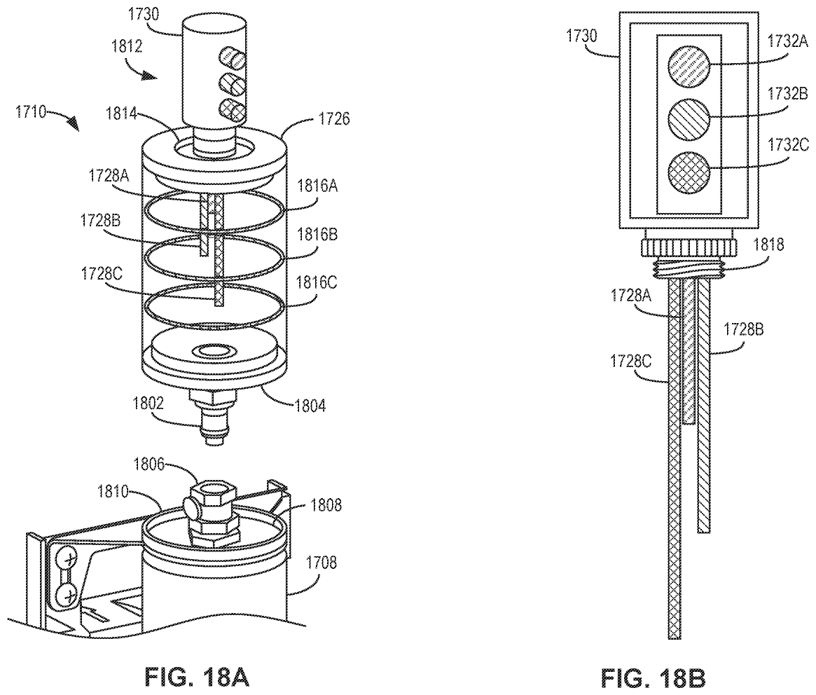

FIG. 18A illustrates the second example reservoir 1710 of FIG. 17. In the illustrated example of FIG. 18A, the second reservoir 1710 is detached and/or disconnected from the first reservoir 1708 at the fitting 1724. In some examples, the second reservoir 1710 is detachable from the first reservoir 1708 to enable refilling the second reservoir 1710 at a second location and/or to enable swapping of the second reservoir 1710 with a different reservoir (e.g., a full reservoir). In this example, the fitting 1724 includes a plug 1802 positioned at a surface 1804 of the second reservoir 1710 proximate to the first reservoir 1708 when the second reservoir 1710 is coupled to the first reservoir 1708. The fitting 1724 includes a socket 1806 positioned at a surface 1808 of the first reservoir 1708, where the plug 1802 is mated to the socket 1806. In the illustrated example, a wall 1810 is coupled to and/or integrally formed on surface 1808 of the first reservoir 1708 opposite the surface 1804 of the second reservoir 1710 to catch and/or contain excess fluid that may escape from the second reservoir 1710 (e.g., during coupling and/or decoupling of the first and second reservoirs 1708, 1710).

In the example of FIG. 18A, the example indicator 1730 and the example sensors 1728 (e.g., including a first example sensor 1728A, a second example sensor 1728B, and a third example sensor 1728C) define a coolant monitoring device 1812 implemented at the second reservoir 1710. In this example, the coolant monitoring device 1812 is positioned in an opening 1814 of the cap 1726 of the second reservoir 1710, such that the sensors 1728 extend into the second reservoir 1710. In some examples, the coolant monitoring device 1812 can be removed from the cap 1726 to enable refilling of the second reservoir 1710 via the opening 1814.

In the illustrated example of FIG. 18A, the sensors 1728 detect whether the coolant level in the second reservoir 1710 satisfies corresponding threshold levels. The threshold levels can be represented by an amount of extension of the sensors 1728 in the second reservoir 1710. For example, the first sensor 1728A corresponds to a first threshold level, the second sensor 1728B corresponds to a second threshold level (e.g., less than the first threshold level), and the third sensor 1728C corresponds to a third threshold level (e.g., less than the first threshold level and the second threshold level). In this example, the first threshold level corresponds to 75% of a capacity of the second reservoir 1710, the second threshold level corresponds to 50% of the capacity of the second reservoir 1710, and the third threshold level corresponds to 25% of the capacity of the second reservoir 1710. In some examples, at least one of the threshold levels can be different (e.g., 90%, 80%, 10%, etc.). In some examples, the threshold levels are selected based on at least one of an expected heat dissipation rate of the heat exchanger 1706 of FIG. 17, an expected evaporation rate of the coolant, a number of heat exchangers and/or cold plates associated with the second reservoir 1710, or an expected lifetime of the heat exchanger 1706.

In this example, the second reservoir 1710 includes markers 1816 to visually indicate respective ones of the threshold levels to an operator. For example, a first example marker 1816A indicates the first threshold level, a second example marker 1816B indicates the second threshold level, and a third example marker 1816C indicates the third threshold level. In this example, the markers 1816 include different colored rings positioned at the respective threshold levels. In some examples, the markers 1816 can be different (e.g., text and/or other labels indicating the respective threshold levels).

In operation, the sensors 1728 output one or more signals to the reservoir monitoring circuitry 1702 of FIG. 17 to indicate the detected coolant levels in the second reservoir 1710. For example, when the coolant level is at or above the first threshold level, the coolant is in contact with the first sensor 1728A, thus triggering the first sensor 1728A to send a first example signal to the reservoir monitoring circuitry 1702. In some examples, when the coolant level drops below the first threshold level, the coolant does not contact the first sensor 1728A, such that the first sensor 1728A does not send the first signal (e.g., and/or sends an alternate signal) to the reservoir monitoring circuitry 1702. Similarly, in some examples, the second sensor 1728B sends a second example signal to the reservoir monitoring circuitry 1702 when the coolant is at or above the second threshold level (e.g., is in contact with the second sensor 1728B), and does not send the second signal (e.g., and/or sends an alternate signal) when the coolant is below the second threshold level (e.g., is not in contact with the second sensor 1728B). Further, the third sensor 1728C sends a third example signal to the reservoir monitoring circuitry 1702 when the coolant is at or above the third threshold level (e.g., is in contact with the third sensor 1728C), and does not send the third signal (e.g., and/or sends an alternate signal) when the coolant is below the third threshold level (e.g., is not in contact with the third sensor 1728C).

While three of the sensors 1728 are used in this example, a different number of sensors and/or corresponding thresholds can be used instead. In some examples, a different type of sensor can be used to detect the coolant level in the second reservoir 1710 by, for example, measuring a distance between the sensor and the coolant. In some such examples, the sensor can provide a signal indicative of a measured value of the coolant level (e.g., instead of providing a binary response indicative of whether the coolant does or does not reach a particular threshold level).

FIG. 18B illustrates a front view of the example coolant monitoring device 1812 of FIG. 18A. In the illustrated example of FIG. 18B, the coolant monitoring device 1812 includes a threaded portion 1818 for removably coupling the coolant monitoring device 1812 to the cap 1726 of FIG. 18A. In the illustrated example, the indicator 1730 includes a first example light source 1732A, a second example light source 1732B, and a third example light source 1732B to indicate a status of the coolant in the second reservoir 1710 of FIGS. 17 and/or 18B. For example, different colors of the light sources 1732 can be associated with different statuses of the coolant. In some examples, the first light source 1732A has a first color (e.g., green) representing a first status (e.g., a satisfactory coolant level), the second light source 1732B has a second color (e.g., yellow) representing a second status (e.g., a low coolant level), and the third light source 1732C has a third color (e.g., red) representing a third status (e.g., a critically low coolant level). In some examples, one or more different colors (e.g., instead of green, yellow, and/or red) can be used for the light sources 1732 instead, and/or one or more of the light sources 1732 can be omitted. In some examples, in addition to or instead of one or more of the light sources 1732, the indicator 1730 can include a display to present information (e.g., the coolant level, the status, etc.) to an operator. Additionally or alternatively, the indicator 1730 can include a speaker to emit audio representative of the information.

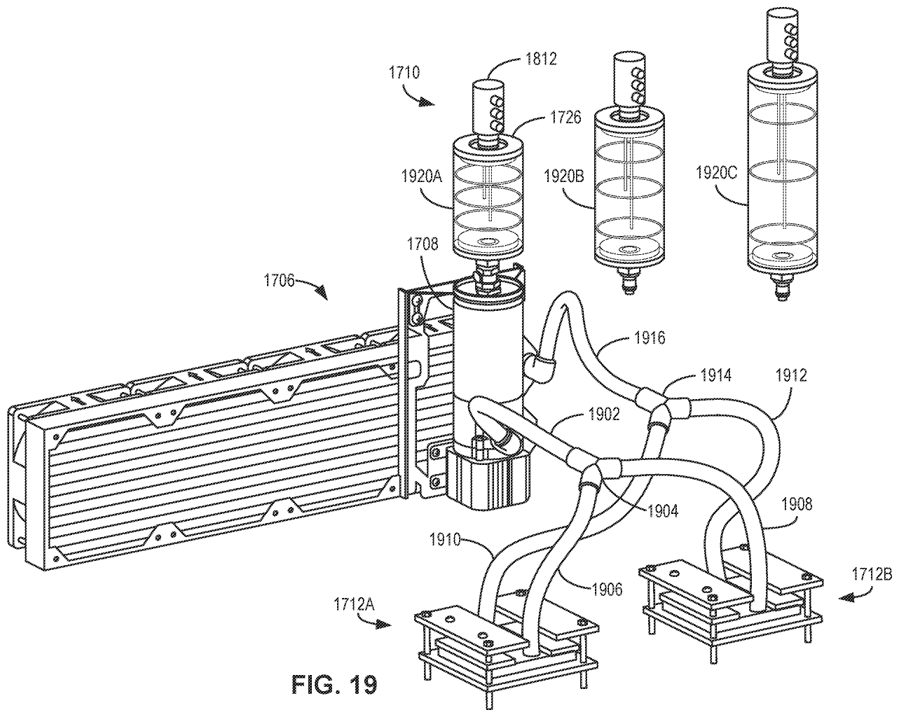

FIG. 19 illustrates different example sizes of the second reservoir 1710 that can be implemented with the first example reservoir 1708 of the example heat exchanger 1706 of FIG. 17. Unlike the heat exchanger 1706 shown in FIG. 17, the heat exchanger 1706 in the illustrated example of FIG. 19 is fluidly and/or operatively coupled to multiple example cold plates 1712A, 1712B to circulate coolant therethrough. In this example, supply tubing 1902 directs coolant from the first reservoir 1708 to the cold plates 1712A, 1712B. In some examples, the supply tubing 1902 includes a first example tee connection 1904 at which the coolant from the supply tubing 1902 separates into a first supply path 1906 to the first cold plate 1712A and a second supply path 1908 to the second cold plate 1712B. Conversely, the coolant flows from the cold plates 1712A, 1712B along respective first and second return paths 1910, 1912 to a second example tee connection 1914 implemented on example return tubing 1916. In some examples, the coolant from the return tubing 1916 flows through the heat exchanger 1706 and is cooled prior to being recirculated through the cold plates 1712A, 1712B. While two of the cold plates 1712A, 1712B are used in this example, the heat exchanger 1706 can be fluidly and/or operatively coupled to any number (e.g., one, two, three or more, etc.) of cold plates to provide cooling thereof.

In the illustrated example of FIG. 19, the second reservoir 1710 can be implemented using one of a first example reservoir body 1920A having a first volume, a second example reservoir body 1920B having a second volume (e.g., greater than the first volume), or a third example reservoir body 1920C having a third volume (e.g., greater than the first volume and the second volume). In some examples, the example coolant monitoring device 1812 and/or the cap 1726 can be transferred between the reservoir bodies 1920. In some examples, the volume of the second reservoir 1710 can be selected based on an expected heat load of the heat exchanger 1706, a number of the cold plates 1712 fluidly and/or operatively coupled to the heat exchanger 1706, an expected evaporation rate of the coolant, etc.

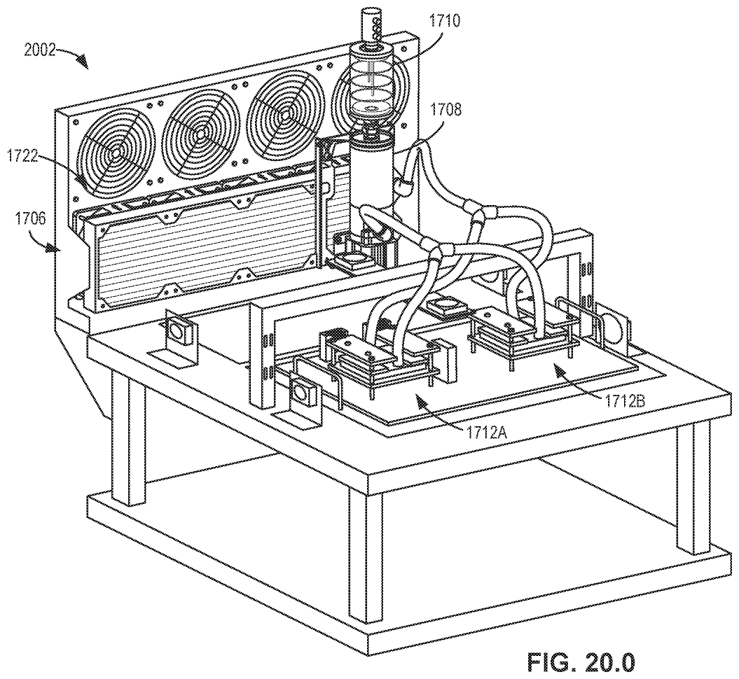

FIG. 20 illustrates the example heat exchanger 1706 and the example reservoirs 1708, 1710 of FIG. 19 implemented on an example chassis 2002. In the illustrated example of FIG. 20, the chassis 2002 includes the first and second example cold plates 1712A, 1712B coupled thereto, and the heat exchanger 1706 is fluidly and/or operatively coupled to the cold plates 1712A, 1712B to facilitate cooling thereof. In some examples, a cooling capacity of the heat exchanger 1706 is based on a number of the fans 1722 implemented by the heat exchanger 1706. For example, when the heat exchanger 1706 includes four of the fans 1722 as shown in FIG. 20, the heat exchanger 1706 can cool a threshold amount (e.g., up to 1.3 kilowatts) of package power. In some examples, a number of the cold plates 1712 to be cooled by the heat exchanger 1706 is selected based on the cooling capacity thereof.

FIG. 21 is a block diagram of an example implementation of the example reservoir monitoring circuitry 1702 of FIG. 17 to monitor coolant levels of the second example reservoir 1710 of FIG. 17. The reservoir monitoring circuitry 1702 of FIG. 21 may be instantiated (e.g., creating an instance of, bring into being for any length of time, materialize, implement, etc.) by programmable circuitry such as a Central Processor Unit (CPU) executing first instructions. Additionally or alternatively, the reservoir monitoring circuitry 1702 of FIG. 21 may be instantiated (e.g., creating an instance of, bring into being for any length of time, materialize, implement, etc.) by (i) an Application Specific Integrated Circuit (ASIC) and/or (ii) a Field Programmable Gate Array (FPGA) structured and/or configured in response to execution of second instructions to perform operations corresponding to the first instructions. It should be understood that some or all of the circuitry of FIG. 21 may, thus, be instantiated at the same or different times. Some or all of the circuitry of FIG. 21 may be instantiated, for example, in one or more threads executing concurrently on hardware and/or in series on hardware. Moreover, in some examples, some or all of the circuitry of FIG. 21 may be implemented by microprocessor circuitry executing instructions and/or FPGA circuitry performing operations to implement one or more virtual machines and/or containers.

In the illustrated example of FIG. 21, the reservoir monitoring circuitry 1702 includes example sensor interface circuitry 2102, example status determination circuitry 2104, example alert generation circuitry 2106, example indicator control circuitry 2108, example communication circuitry 2110, and an example reservoir database 2112.

The example reservoir database 2112 stores data utilized and/or obtained by the reservoir monitoring circuitry 1702. The example reservoir database 2112 of FIG. 21 is implemented by any memory, storage device and/or storage disc for storing data such as, for example, flash memory, magnetic media, optical media, solid state memory, hard drive(s), thumb drive(s), etc. Furthermore, the data stored in the example reservoir database 2112 may be in any data format such as, for example, binary data, comma delimited data, tab delimited data, structured query language (SQL) structures, etc. Although in the illustrated example, the example reservoir database 2112 is illustrated as a single device, the example reservoir database 2112 and/or any other data storage devices described herein may be implemented by any number and/or type(s) of memories.

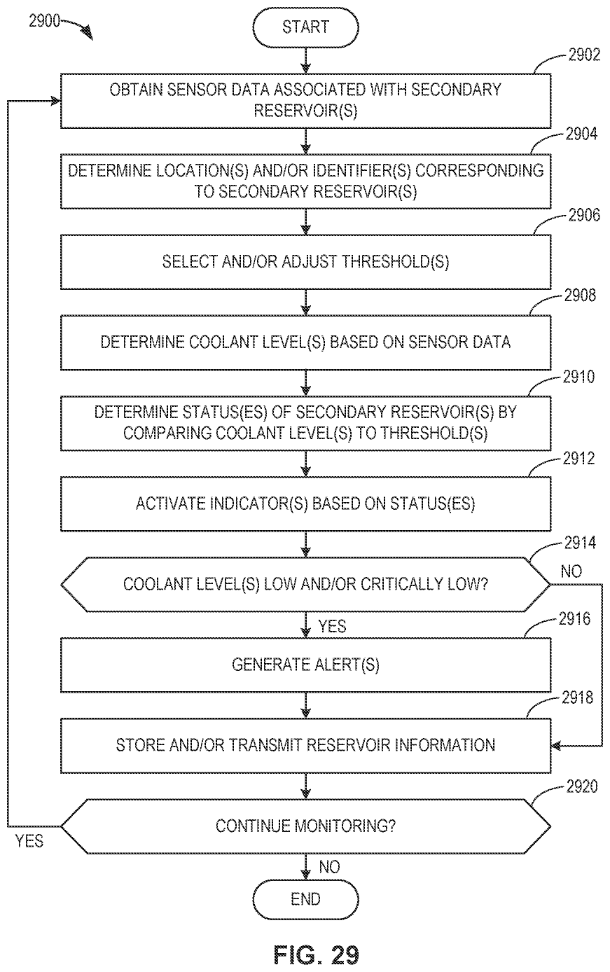

The sensor interface circuitry 2102 of FIG. 21 obtains and/or accesses example sensor data 2114 corresponding to outputs of one or more of the example sensors 1728 of FIGS. 17, 18A, and/or 18B. For example, the sensor data 2114 can include a first example signal from the first sensor 1728A, a second example signal from the second sensor 1728B, and/or a third example signal from the third sensor 1728C. In some examples, the first signal is indicative of the coolant level in the second reservoir 1710 being at or above the first example threshold, the second signal is indicative of the coolant level being at or above the second example threshold, and the third signal is indicative of the coolant level being at or above the third example threshold. In some examples, the sensor data 2114 includes a measurement value from one or more additional sensors operatively coupled to the second reservoir 1710, where the measurement value indicates a detected coolant level in the second reservoir 1710 (e.g., without reference to one(s) of the thresholds). In some examples, the sensor interface circuitry 2102 provides the sensor data 2114 to the example reservoir database 2112 for storage therein. In some examples, the sensor interface circuitry 2102 is instantiated by programmable circuitry executing sensor interface circuitry instructions and/or configured to perform operations such as those represented by the flowchart(s) of FIG. 29.

The status determination circuitry 2104 of FIG. 21 determines an example status associated with the second reservoir 1710 and/or the coolant therein. For example, based on the sensor data 2114, the status determination circuitry 2104 determines whether the coolant level in the second reservoir 1710 is satisfactory, low, or critically low. In some examples, the status determination circuitry 2104 determines that the coolant level is satisfactory (e.g., is at or above the first threshold level) in response to the sensor interface circuitry 2102 receiving at least the first signal from the first sensor 1728A. In some examples, the status determination circuitry 2104 determines that the coolant level is low (e.g., is below the first threshold level and is at or above at least one of the second threshold level or the third threshold level) in response to the sensor interface circuitry 2102 not receiving the first signal from the first sensor 1728A, and receiving at least the third signal from the third sensor 1728C. Additionally, the status determination circuitry 2104 determines that the coolant level is at or above the second threshold in response to the sensor interface circuitry 2102 receiving the second signal from the second sensor 1728B, and determines the coolant level is below the second threshold in response to the sensor interface circuitry 2102 not receiving the second signal. In some examples, the status determination circuitry 2104 determines that the coolant level is critically low (e.g., is below the third threshold level) in response to the sensor interface circuitry 2102 not receiving the third signal from the third sensor 1728C (and not receiving signals from the other sensors 1728A, 1728B).

In some examples, when the sensor data 2114 is a measurement value representative of the detected coolant level (e.g., without reference to one(s) of the threshold levels), the threshold levels are preprogrammed in the status determination circuitry 2104, and the status determination circuitry 2104 determines the status by comparing the measurement value to the threshold levels. For example, the status determination circuitry 2104 determines that the coolant level is satisfactory in response to determining that the measurement value satisfies (e.g., is greater than or equal to) the first threshold level. In some examples, the status determination circuitry 2104 determines that the coolant level is low in response to determining that the measurement value satisfies the third threshold level, but does not satisfy the first threshold level. In some examples, the status determination circuitry 2104 determines that the coolant level is critically low in response to determining that the measurement value does not satisfy the third threshold level. In some examples, the status determination circuitry 2104 provides the determined status to the reservoir database 2112 for storage therein. In some examples, the status determination circuitry 2104 is instantiated by programmable circuitry executing status determination circuitry instructions and/or configured to perform operations such as those represented by the flowchart(s) of FIG. 29.

The indicator control circuitry 2108 of FIG. 21 controls and/or adjusts the example indicator 1730 of FIGS. 17, 18A, and/or 18B based on the determined status. For example, in response to the status determination circuitry 2104 determining that the coolant level is satisfactory, the indicator control circuitry 2108 activates (e.g., turns on) the first light source 1732A, and deactivates (e.g., shuts off) and/or does not activate the second and third light sources 1732B, 1732C. In some examples, in response to the status determination circuitry 2104 determining that the coolant level is low, the indicator control circuitry 2108 activates the second light source 1732B, and deactivates and/or does not activate the first and third light sources 1732A, 1732C. In some examples, in response to the status determination circuitry 2104 determining that the coolant level is critically low, the indicator control circuitry 2108 activates the third light source 1732C, and deactivates and/or does not activate the first and second light sources 1732A, 1732B. In some examples, the indicator control circuitry 2108 can adjust a frequency at which light is emitted from the light sources 1732A, 1732B, 1732. For example, the indicator control circuitry 2108 can cause one(s) of the light sources 1732 to blink periodically (e.g., when the coolant level is below the second threshold and/or the third threshold).

In some examples, when the indicator 1730 includes a display, the indicator control circuitry 2108 can cause the indicator 1730 to present text on the display, where the text indicates the status, the coolant level, instructions to refill the second reservoir 1710, etc. In some examples, when the indicator 1730 includes a speaker, the indicator control circuitry 2108 can cause the indicator 1730 to emit an audio signal when the coolant level is low and/or critically low. In some examples, the indicator control circuitry 2108 is instantiated by programmable circuitry executing indicator control circuitry instructions and/or configured to perform operations such as those represented by the flowchart(s) of FIG. 29.

The alert generation circuitry 2106 of FIG. 21 generates and/or causes presentation of one or more example alerts 2116 based on the status of the coolant in the second reservoir 1710. In the illustrated example of FIG. 21, the alert(s) 2116 can inform an operator when refilling of the second reservoir 1710 should be performed and/or can provide information associated with the second reservoir 1710 (e.g., the status, the coolant level, etc.). In some examples, the alert(s) 2116 are output for presentation at the user device 1734 of FIG. 17. For example, the alert(s) 2116 can include an email and/or an SMS message to the user device 1734, and/or the alert(s) 2116 can be presented on a dashboard of the user device 1734. In some examples, the alert generation circuitry 2106 generates and/or outputs the alert(s) 2116 in response to the status determination circuitry 2104 determining that the coolant level in the second reservoir 1710 is low and/or critically low. In some examples, the alert generation circuitry 2106 generates and/or outputs the alert(s) 2116 periodically (e.g., hourly, daily, etc.) at a frequency selected by the operator.

In some examples, the alert(s) 2116 include the coolant level in the second reservoir 1710 and/or the status (e.g., satisfactory, low, critically low, etc.) of the coolant. In some examples, the alert(s) 2116 include a date and/or time at which the alert(s) 2116 were generated. In some examples, the alert(s) 2116 include identifying information corresponding to the second reservoir 1710 and/or the associated heat exchanger 1706. For example, the identifying information can include an identifier and/or a geographic location (e.g., grid coordinates, global positioning system (GPS) coordinates, etc.) corresponding to the second reservoir 1710 and/or the heat exchanger 1706. In some examples, the alert(s) 2116 include instructions on how to locate and/or service the second reservoir 1710 and/or the heat exchanger 1706. For example, the alert(s) 2116 can include a map to guide the operator to a location of the second reservoir 1710, an indication of how much coolant is to be added to the second reservoir 1710, etc. In some examples, the alert generation circuitry 2106 is instantiated by programmable circuitry executing alert generation circuitry instructions and/or configured to perform operations such as those represented by the flowchart(s) of FIG. 29.

The communication circuitry 2110 of FIG. 21 generates and/or provides example reservoir information 2118 to the example system monitoring circuitry 1704 of FIG. 17. For example, the communication circuitry 2110 is communicatively coupled to the system monitoring circuitry 1704 via the network 1736 of FIG. 17 for use in monitoring and/or predicting performance of an example liquid cooling system implementing the example heat exchanger 1706 of FIG. 17. In some examples, the reservoir information 2118 includes the coolant level and/or the status of the coolant in the second reservoir 1710, the date and/or time associated with the coolant level and/or the status, an identifier and/or a location associated with the second reservoir 1710 and/or the heat exchanger 1706, etc. In some examples, the communication circuitry 2110 provides the reservoir information 2118 periodically (e.g., daily, weekly, etc.) and/or in response to a request from the system monitoring circuitry 1704. In some examples, the communication circuitry 2110 provides the reservoir information 2118 to the reservoir database 2112 for storage therein. In some examples, the communication circuitry 2110 is instantiated by programmable circuitry executing communication circuitry instructions and/or configured to perform operations such as those represented by the flowchart(s) of FIG. 29.

FIG. 22 is a block diagram of an example implementation of the example system monitoring circuitry 1704 of FIG. 17 to monitor and/or predict performance of an example system of example heat exchangers (e.g., including the heat exchanger 1706 of FIG. 17). The system monitoring circuitry 1704 of FIG. 22 may be instantiated (e.g., creating an instance of, bring into being for any length of time, materialize, implement, etc.) by programmable circuitry such as a Central Processor Unit (CPU) executing first instructions. Additionally or alternatively, the system monitoring circuitry 1704 of FIG. 22 may be instantiated (e.g., creating an instance of, bring into being for any length of time, materialize, implement, etc.) by (i) an Application Specific Integrated Circuit (ASIC) and/or (ii) a Field Programmable Gate Array (FPGA) structured and/or configured in response to execution of second instructions to perform operations corresponding to the first instructions. It should be understood that some or all of the circuitry of FIG. 22 may, thus, be instantiated at the same or different times. Some or all of the circuitry of FIG. 22 may be instantiated, for example, in one or more threads executing concurrently on hardware and/or in series on hardware. Moreover, in some examples, some or all of the circuitry of FIG. 22 may be implemented by microprocessor circuitry executing instructions and/or FPGA circuitry performing operations to implement one or more virtual machines and/or containers.

In the illustrated example of FIG. 22, the example system monitoring circuitry 1704 includes example input interface circuitry 2202, example model training circuitry 2204, example coolant anomaly detection circuitry 2206, example hardware anomaly detection circuitry 2208, example RUL prediction circuitry 2210, example cluster analysis circuitry 2212, example output generation circuitry 2214, example control adjustment circuitry 2216, and an example system database 2218.

The example system database 2218 stores data utilized and/or obtained by the system monitoring circuitry 1704. The example system database 2218 of FIG. 22 is implemented by any memory, storage device and/or storage disc for storing data such as, for example, flash memory, magnetic media, optical media, solid state memory, hard drive(s), thumb drive(s), etc. Furthermore, the data stored in the example system database 2218 may be in any data format such as, for example, binary data, comma delimited data, tab delimited data, structured query language (SQL) structures, etc. While, in the illustrated example, the example system database 2218 is illustrated as a single device, the example system database 2218 and/or any other data storage devices described herein may be implemented by any number and/or type(s) of memories.

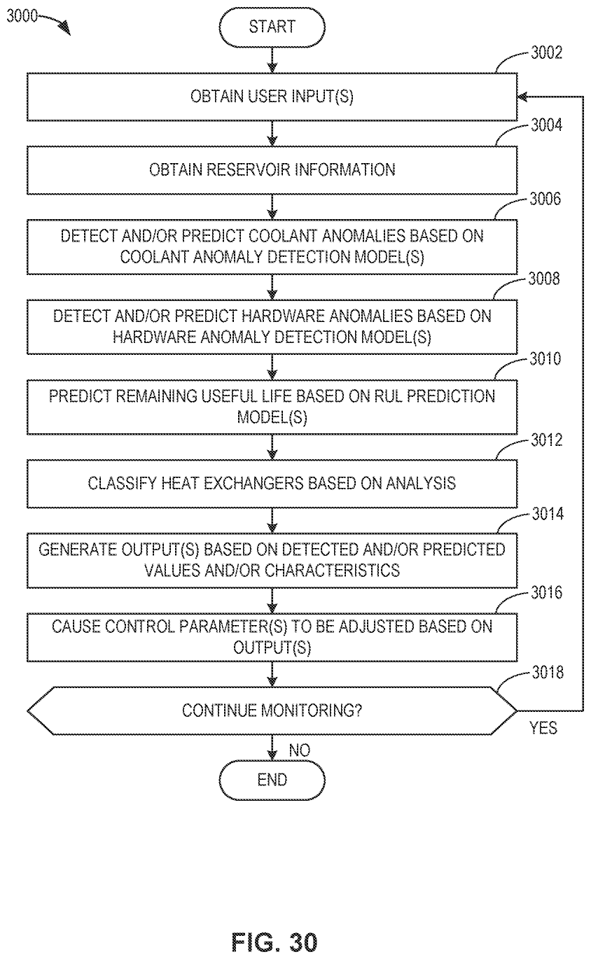

The example input interface circuitry 2202 obtains and/or accesses example data to be utilized by the system monitoring circuitry 1704 for monitoring and/or predicting performance of one or more heat exchangers 1706 in an example environment (e.g., a data center). In the illustrated example of FIG. 22, the input interface circuitry 2202 obtains and/or accesses the example reservoir information 2118 from the example reservoir monitoring circuitry 1702 of FIGS. 17 and/or 21. In some examples, the reservoir information 2118 includes coolant levels and/or statuses, timestamps associated with the coolant levels and/or the statuses, identifiers, and/or locations corresponding to one or more heat exchangers 1706 included in the example environment. In this example, the input interface circuitry 2202 obtains and/or accesses example user input(s) 2220 provided by an operator via the example user device 1734 of FIG. 17. In some examples, the operator can indicate, via the user input(s) 2220, information obtained based on manual and/or visual inspection of one(s) of the heat exchangers 1706. For example, the user input(s) 2220 can include observed coolant levels at the one(s) of the heat exchangers 1706, observed anomalies at the one(s) of the heat exchangers 1706, etc. In some examples, the input interface circuitry 2202 provides the reservoir information 2118 and/or the user input(s) 2220 to the system database 2218 for storage therein. In some examples, the input interface circuitry 2202 is instantiated by programmable circuitry executing input interface circuitry instructions and/or configured to perform operations such as those represented by the flowchart(s) of FIG. 30.

The example model training circuitry 2204 generates, trains, and/or re-trains one or more example machine learning models utilized by the system monitoring circuitry 1704. For example, the model training circuitry 2204 generates and/or trains at least one of an example coolant anomaly detection model, an example hardware anomaly detection model, or an example RUL prediction model. Although in the example of FIG. 22, the model training circuitry 2204 is shown as implemented by the system monitoring circuitry 1704, the model training circuitry 2204 can be implemented by circuitry different from the system monitoring circuitry 1704. In such examples, the model(s) generated and/or trained by the model training circuitry 2204 are accessible to the system monitoring circuitry 1704 via a database (e.g., the system database 2218).

In some examples, the model training circuitry 2204 performs training of the one or more machine learning models (e.g., neural networks, linear regression models, etc.) based on example training data. In the example of FIG. 22, the training data can be stored in the system database 2218 and can include labeled datasets based on historical data collected for one(s) of the heat exchangers 1706 and/or for one or more past heat exchangers. For example, the training data can include sensor data previously collected for one(s) of the heat exchangers 1706, where the sensor data can indicate coolant levels, coolant pressure, operating temperatures of the heat exchangers 1706, heat flux cooled by the heat exchangers 1706, and/or pump operating efficiency of the heat exchangers 1706 at corresponding points in time. Further, the training data includes labels indicating type(s) of anomalies (e.g., coolant anomalies and/or hardware anomalies) observed at the heat exchangers 1706 at the corresponding points in time. For example, when an operator performs manual and/or visual inspection of one(s) of the heat exchanger 1706, the operator can provide the user input(s) 2220 indicating the type(s) of anomalies observed at the one(s) of the heat exchangers 1706, and the user input(s) 2220 is used to generate the corresponding labels.

In some examples, the model training circuitry 2204 sub-divides the training data into a training data set and a validation data set. For example, a first portion (e.g., 80%) of the training data can be used as the training data set for training the machine learning model(s), and a second portion (e.g., 20%) of the training data can be used as the validation data set for validating the machine learning model(s). In some examples, the model training circuitry 2204 trains the machine learning model(s) by correlating the historical data (e.g., the coolant levels, the coolant pressures, the operating temperatures at the heat exchangers 1706, etc. at different points in time) with the corresponding type(s) of anomalies observed in the training data, and adjusting one or more parameters of the machine learning model(s) based on the correlation.

In some examples, during training of the coolant anomaly detection model, the model training circuitry 2204 determines correlations between the historical data and the type(s) of coolant anomalies observed at different points in time. For example, the coolant anomalies can include evaporation and/or overheating of the coolant, leakage of the coolant, reduced efficiency of the coolant, pressure drop of the coolant, corrosion of equipment associated with the coolant, etc. In some examples, the model training circuitry 2204 adjusts parameter(s) of the coolant anomaly detection model based on the correlations such that, when executed, the coolant anomaly detection model outputs possible coolant anomaly type(s) and/or coolant anomaly score(s) for one(s) of the heat exchangers 1706. For example, when the coolant anomaly detection model is executed based on the reservoir information 2118 corresponding to a particular one of the heat exchangers 1706, the coolant anomaly detection model outputs one or more coolant anomaly types that are possible and/or expected for the particular heat exchanger 1706. In some examples, when no coolant anomalies are expected for the heat exchanger 1706, the coolant anomaly detection model outputs an indication that operation of the heat exchanger 1706 is as expected or intended (e.g., not anomalous). Additionally or alternatively, as a result of the execution, the coolant anomaly detection model can output coolant anomaly scores for the corresponding heat exchangers 1706. For example, for corresponding one(s) of the coolant anomalies output for one(s) of the heat exchangers 1706, the coolant anomaly detection model outputs the coolant anomaly score(s) indicating a likelihood of the corresponding one(s) of the coolant anomalies occurring. In some examples, reduction in the coolant levels for one(s) of the heat exchangers 1706 results in an increase in the coolant anomaly score for the one(s) Of the heat exchangers 1706.

Similarly, during training of the hardware anomaly detection model, the model training circuitry 2204 determines correlations between the historical data and the type(s) of hardware anomalies observed at different points in time. For example, the hardware anomalies can include pump failures, fan failures, fin damage, blocked airflow, operating temperatures of the heat exchangers 1706 exceeding a threshold, etc. In some examples, the model training circuitry 2204 adjusts parameter(s) of the hardware anomaly detection model based on the correlations such that, when executed, the hardware anomaly detection model outputs possible hardware anomaly type(s) and/or hardware anomaly score(s) for one(s) of the heat exchangers 1706. In some examples, the hardware anomaly score(s) indicate likelihood of the hardware anomaly type(s) for the corresponding heat exchanger(s) 1706. In some examples, when no hardware anomalies are expected and/or detected for the heat exchanger 1706, the hardware anomaly detection model outputs an indication that operation of the heat exchanger 1706 is as expected or intended (e.g., not anomalous).

In some examples, the RUL prediction model is a predictive linear regression model trained to predict the RUL of corresponding heat exchangers 1706, where the RUL represents a duration (e.g., in days, weeks, etc.) for which the corresponding heat exchangers 1706 are expected to operate as expected or intended (e.g., without failure and/or anomalies) before repair and/or replacement is warranted. In some examples, a different type of model (e.g., instead of a linear regression model) can be used. In some examples, during training of the RUL prediction model, the model training circuitry 2204 determines correlations between heat exchanger parameters (e.g., coolant levels, operating time, pump operating efficiency, elapsed duration of use, heat flex being cooled, etc.) of past heat exchangers represented in the training data and the corresponding durations for which the past heat exchangers were operational before undergoing repair and/or replacement. In some examples, the model training circuitry 2204 adjusts parameter(s) of the RUL prediction model based on the correlations such that, when executed, the RUL prediction model outputs the predicted RUL for corresponding one(s) of the heat exchangers 1706.

In some examples, the model training circuitry 2204 validates the machine learning model(s) based on the second portion of the training data (e.g., the validation data set). For example, the model training circuitry 2204 evaluates the machine learning model(s) based on the validation data set. For example, the model training circuitry 2204 determines example coolant anomalies by providing the historical data from the validation data set as input to the trained coolant anomaly detection model(s). In some examples, the model training circuitry 2204 determines example hardware anomalies by providing the historical data from the validation data set as input to the trained hardware anomaly detection model(s). In some examples, the model training circuitry 2204 determines example RULs by providing the historical data from the validation data set as input to the trained RUL prediction model(s). In some examples, the model training circuitry 2204 compares the determined parameters (e.g., the determined coolant anomalies, the determined hardware anomalies, and/or the determined RULs) to corresponding reference parameters (e.g., reference coolant anomalies, reference hardware anomalies, and/or reference RULs) from the validation data set.

In some examples, the model training circuitry 2204 determines whether the determined parameters satisfy an accuracy threshold by comparing the determined parameters to the corresponding reference parameters from the validation data set. For example, the model training circuitry 2204 determines that the determined parameters do not satisfy the accuracy threshold when the determined parameters correctly predict less than a threshold percentage (e.g., less than 90%, less than 95%, etc.) of the corresponding reference parameters. Conversely, the model training circuitry 2204 determines that the determined parameters satisfy the accuracy threshold when the determined parameters correctly predict at least the threshold percentage (e.g., at least 90%, at least 95%, etc.) of the corresponding reference parameters. In some examples, the model training circuitry 2204 re-trains the machine learning model(s) when the determined parameters do not satisfy the accuracy threshold. In some examples, when the determined parameters satisfy the accuracy threshold, the model training circuitry 2204 stores the trained machine learning model(s) in the system database 2218 for use by the system monitoring circuitry 1704. In some examples, the model training circuitry 2204 is instantiated by programmable circuitry executing model training circuitry instructions and/or configured to perform operations such as those represented by the flowchart(s) of FIGS. 30 and/or 31.

Artificial intelligence (AI), including machine learning (ML), deep learning (DL), and/or other artificial machine-driven logic, enables machines (e.g., computers, logic circuits, etc.) to use a model to process input data to generate an output based on patterns and/or associations previously learned by the model via a training process. For instance, the model may be trained with data to recognize patterns and/or associations and follow such patterns and/or associations when processing input data such that other input(s) result in output(s) consistent with the recognized patterns and/or associations.

Many different types of machine learning models and/or machine learning architectures exist. In examples disclosed herein, machine learning models based on an Isolation Forest algorithm are used. However, other types of supervised and/or unsupervised machine learning models (e.g., convolutional neural networks (CNNs), linear regression, etc.) could additionally or alternatively be used.

In examples disclosed herein, the Isolation Forest algorithm is an unsupervised machine learning algorithm used for anomaly detection. In some examples, the Isolation Forest algorithm constructs binary trees based on randomly selected splits from data features provided as input. Anomalies can be identified based on a number of splits to isolate selected data points from remaining data points in a data set. For example, anomalies are identified as one(s) of the data points that require fewer splits (e.g., compared to remaining ones of the data point) to isolate the one(s) of the data points from the remaining ones of the data points and, thus, are dissimilar to the remaining ones of the data points. In some examples disclosed herein, a Random Forest algorithm can be used, where the Random Forest algorithm is a supervised machine learning algorithm. In some examples, the Random Forest algorithm generates decision trees based on random subsets of training data and/or random subsets of features, and outputs a prediction based on a combination of results from the decision trees. While Isolation Forest and/or Random Forest algorithms can be used for one(s) of the machine learning models disclosed herein, different types of machine learning models can be used instead.

In general, implementing a ML/AI system involves two phases, a learning/training phase and an inference phase. In the learning/training phase, a training algorithm is used to train a model to operate in accordance with patterns and/or associations based on, for example, training data. In general, the model includes internal parameters that guide how input data is transformed into output data, such as through a series of nodes and connections within the model to transform input data into output data. Additionally, hyperparameters are used as part of the training process to control how the learning is performed (e.g., a learning rate, a number of layers to be used in the machine learning model, etc.). Hyperparameters are defined to be training parameters that are determined prior to initiating the training process.

Different types of training may be performed based on the type of ML/AI model and/or the expected output. For example, supervised training uses inputs and corresponding expected (e.g., labeled) outputs to select parameters (e.g., by iterating over combinations of select parameters) for the ML/AI model that reduce model error. As used herein, labelling refers to an expected output of the machine learning model (e.g., a classification, an expected output value, etc.). Alternatively, unsupervised training (e.g., used in deep learning, a subset of machine learning, etc.) involves inferring patterns from inputs to select parameters for the ML/AI model (e.g., without the benefit of expected (e.g., labeled) outputs).

In some examples disclosed herein, ML/AI models are trained using unsupervised training. However, any other training algorithm may additionally or alternatively be used. In some examples disclosed herein, training is performed until a targeted accuracy level is reached (e.g., >95%). Training is performed using hyperparameters that control how the learning is performed (e.g., a learning rate, a number of layers to be used in the machine learning model, etc.). In some examples, pre-trained model(s) are used. In some examples re-training may be performed. Such re-training may be performed in response to, for example, poor crop residue detection due to, for instance, low ambient lighting.

Training is performed using training data. In some examples disclosed herein, the training data originates from a threshold number (e.g., hundreds, thousands) of historical data labeled with associated anomalies (e.g., coolant anomalies and/or hardware anomalies) and/or observed RULs. Labeling can be applied to the training data by the operator, where the labeling includes identifying one or more anomalies associated with one(s) of the heat exchangers represented in the training data.

Once training is complete, the model is deployed for use as an executable construct that processes an input and provides an output based on the network of nodes and connections defined in the model. In examples disclosed herein, the model(s) are stored in the system database 2218. The model(s) may then be executed by the system monitoring circuitry 1704 of FIG. 22.

Once trained, the deployed model may be operated in an inference phase to process data. In the inference phase, data to be analyzed (e.g., live data) is input to the model, and the model executes to create an output. This inference phase can be thought of as the AI “thinking” to generate the output based on what it learned from the training (e.g., by executing the model to apply the learned patterns and/or associations to the live data). In some examples, input data undergoes pre-processing before being used as an input to the machine learning model. Moreover, in some examples, the output data may undergo post-processing after it is generated by the AI model to transform the output into a useful result (e.g., a display of data, an instruction to be executed by a machine, etc.).

In some examples, output of the deployed model may be captured and provided as feedback. By analyzing the feedback, an accuracy of the deployed model can be determined. If the feedback indicates that the accuracy of the deployed model is less than a threshold or other criterion, training of an updated model can be triggered using the feedback and an updated training data set, hyperparameters, etc., to generate an updated, deployed model.

Referring to FIG. 22, the coolant anomaly detection circuitry 2206 detects and/or predicts coolant anomalies associated with one(s) of the heat exchangers 1706. For example, the coolant anomaly detection circuitry 2206 executes the trained coolant anomaly detection model based on the reservoir information 2118 for the heat exchangers 1706, where the reservoir information 2118 includes past and/or current coolant levels, coolant pressures, operating temperatures, etc. As a result of the execution, the coolant anomaly detection circuitry 2206 outputs coolant anomaly types (e.g., evaporation and/or overheating of the coolant, leakage of the coolant, reduced efficiency of the coolant, pressure drop of the coolant, corrosion of equipment associated with the coolant, etc.) detected for corresponding one(s) of the heat exchangers 1706. In some examples, based on the execution, the coolant anomaly detection circuitry 2206 outputs coolant anomaly scores for the corresponding heat exchangers 1706. In some examples, the coolant anomaly detection circuitry 2206 provides the output of the coolant anomaly detection model (e.g., the detected coolant anomalies and/or the coolant anomaly scores for corresponding ones of the heat exchangers 1706) to the system database 2218 for storage therein. In some examples, the coolant anomaly detection circuitry 2206 is instantiated by programmable circuitry executing coolant anomaly detection circuitry instructions and/or configured to perform operations such as those represented by the flowchart(s) of FIG. 30.

The hardware anomaly detection circuitry 2208 of FIG. 22 detects and/or predicts hardware anomalies associated with one(s) of the heat exchangers 1706. For example, the hardware anomaly detection circuitry 2208 executes the trained hardware anomaly detection model(s) based on the reservoir information 2118 for the heat exchangers 1706, where the reservoir information 2118 includes past and/or current coolant levels, coolant pressures, operating temperatures, etc. As a result of the execution, the hardware anomaly detection circuitry 2208 outputs example hardware anomaly types (e.g., pump failures, fan failures, fin damage, blocked airflow, operating temperatures above a threshold, etc.) detected for corresponding one(s) of the heat exchangers 1706. In some examples, based on the execution, the hardware anomaly detection circuitry 2208 outputs example hardware anomaly scores for the corresponding heat exchangers 1706. In some examples, the hardware anomaly detection circuitry 2208 provides the output of the hardware anomaly detection model (e.g., the detected hardware anomalies and/or the hardware anomaly scores for corresponding ones of the heat exchangers 1706) to the system database 2218 for storage therein. In some examples, the hardware anomaly detection circuitry 2208 is instantiated by programmable circuitry executing hardware anomaly detection circuitry instructions and/or configured to perform operations such as those represented by the flowchart(s) of FIG. 30.

The RUL prediction circuitry 2210 of FIG. 22 predicts the RUL for one(s) of the heat exchangers 1706. For example, the RUL prediction circuitry 2210 executes the trained RUL prediction model(s) based on the reservoir information 2118 for the heat exchangers 1706, where the reservoir information 2118 includes past and/or current coolant levels, coolant pressures, operating temperatures, pump operating efficiency, heat flux passing through the heat exchangers 1706, elapsed duration of use, etc. As a result of the execution, the RUL prediction circuitry 2210 outputs the predicted RUL (e.g., in hours, days, weeks, etc.) for corresponding one(s) of the heat exchangers 1706 (e.g., the predicted durations for which corresponding one(s) of the heat exchangers 1706 will be operational before repair and/or replacement is warranted). In some examples, the RUL prediction circuitry 2210 provides the output of the RUL prediction model (e.g., the predicted RUL of one(s) of the heat exchangers 1706) to the system database 2218 for storage therein. In some examples, the RUL prediction circuitry 2210 is instantiated by programmable circuitry executing RUL prediction circuitry instructions and/or configured to perform operations such as those represented by the flowchart(s) of FIG. 30.

The cluster analysis circuitry 2212 of FIG. 22 identifies and/or analyzes one or more clusters (e.g., groups) of the heat exchangers 1706 based on the reservoir information 2118 and/or based on the output of the machine learning model(s). For example, the cluster analysis circuitry 2212 analyzes coolant level patterns for the heat exchangers 1706 represented in the reservoir information 2118, and groups one(s) of the heat exchanger(s) 1706 based on similarity of the coolant level patterns. In some examples, the cluster analysis circuitry 2212 groups one(s) of the heat exchanger(s) 1706 corresponding to a particular coolant anomaly type, hardware anomaly type, and/or predicted RUL range. In some examples, the clusters of the heat exchangers 1706 can be identified and/or presented to an operator to facilitate maintenance of the heat exchangers 1706. For example, based on the cluster(s), the operator can identify one(s) of the heat exchangers 1706 having a similar anomaly and/or irregularity in the corresponding coolant level patterns, and the operator can proactively service the identified one(s) of the heat exchangers 1706 to reduce the anomaly and/or irregularity. Additionally or alternatively, the control adjustment circuitry 2216 of FIG. 22 can cause one or more control parameters for one(s) of the heat exchangers 1706 in an identified cluster to be adjusted based on the anomaly types and/or coolant level patterns observed for the identified cluster. In some examples, the cluster analysis circuitry 2212 is instantiated by programmable circuitry executing cluster analysis circuitry instructions and/or configured to perform operations such as those represented by the flowchart(s) of FIG. 30.

The control adjustment circuitry 2216 of FIG. 22 causes one or more example control parameters of the heat exchangers 1706 to be adjusted. For example, the control parameters can include fan speed, pump speed, and/or coolant flow rate of the heat exchangers 1706. In some examples, the control adjustment circuitry 2216 causes the control parameter(s) to be adjusted based on outputs from one or more machine learning models generated by the model training circuitry 2204. In some examples, the machine learning models are trained based on correlation(s) between the control parameters (e.g., the fan speed, the pump speed, etc.) and the cooling performance of the heat exchangers 1706. In some examples, the control adjustment circuitry 2216 executes the machine learning model(s) based on the reservoir information 2118 and/or the detected and/or predicted values (e.g., the anomaly types, the anomaly scores, etc.) to output one or more control parameter values. In some examples, the control adjustment circuitry 2216 transmits one or more control signals to the fan, the pump, and/or other components of the heat exchanger 1706 to adjust the control parameter(s) based on the control parameter value(s). In some examples, the control adjustment circuitry 2216 transmits the control signal(s) and the control parameter(s) are adjusted accordingly without user involvement. In some examples, the control adjustment circuitry 2216 output(s) alert(s) and/or recommendation(s) for presentation to prompt a user to provide input(s) to initiate or facilitate the adjustment(s) to the control parameter(s). In some examples, the control adjustment circuitry 2216 is instantiated by programmable circuitry executing control adjustment circuitry instructions and/or configured to perform operations such as those represented by the flowchart(s) of FIG. 30.

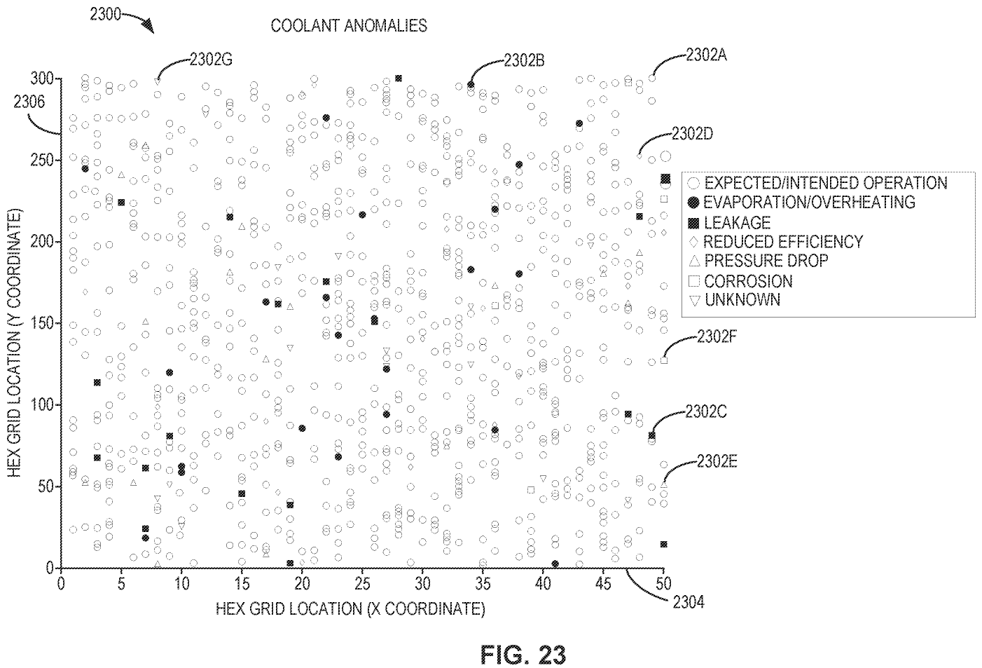

The output generation circuitry 2214 of FIG. 22 outputs example display information 2222 for presentation to an operator (e.g., at the example user device 1734 of FIG. 22). In the illustrated example of FIG. 22, the display information 2222 can include one or more example tables and/or example graphs to represent the reservoir information 2118 and/or one or more characteristics (e.g., the coolant anomalies, the hardware anomalies, the anomaly scores, the RUL, etc.) predicted and/or detected for the heat exchangers 1706. For example, the display information 2222 can include identifier(s), location(s), coolant level(s), coolant anomaly type(s), hardware anomaly type(s), and/or anomaly score(s) associated with one(s) of the heat exchangers 1706. In some examples, the display information 2222 is presented at the user device 1734 using at least one of an email, an SMS message, or a dashboard at the user device 1734. Example graphs and/or tables that can be generated and/or output by the output generation circuitry 2214 are further described in connection with FIGS. 23-26 below. In some examples, the output generation circuitry 2214 is instantiated by programmable circuitry executing output generation circuitry instructions and/or configured to perform operations such as those represented by the flowchart(s) of FIG. 30.

FIG. 23 illustrates a first example graph 2300 that can be generated and/or output by the example output generation circuitry 2214 of FIG. 22. In the illustrated example of FIG. 23, the first graph 2300 represents example coolant anomaly types detected and/or predicted at corresponding locations (e.g., grid locations) of the heat exchangers 1706 (e.g., in a data center). In this example, the first graph 2300 includes example markers 2302 representing locations of the heat exchangers 1706 with respect to a first example axis (e.g., an x coordinate axis, a horizontal axis) 2304 and a second example axis (e.g., a y coordinate axis, a vertical axis) 2306.

In the illustrated example of FIG. 23, different ones of the markers 2302 (e.g., having different sizes, shapes, colors, etc.) are used to represent corresponding coolant anomaly types detected and/or predicted for the heat exchangers 1706. For example, first example markers 2302A correspond to first one(s) of the heat exchangers 1706 that are operating as expected or intended (e.g., no coolant anomalies are detected), second example markers 2302B correspond to second one(s) of the heat exchangers 1706 at which evaporation and/or overheating of coolant is detected, third example markers 2302C correspond to third one(s) of the heat exchangers 1706 at which leakage of coolant is detected, fourth example markers 2302D correspond to fourth one(s) of the heat exchangers 1706 at which reduced efficiency (e.g., resulting from loss of coolant) is detected, fifth example markers 2302E correspond to fifth one(s) of the heat exchangers 1706 at which pressure drop of coolant is detected, sixth example markers 2302F correspond to sixth one(s) of the heat exchangers 1706 at which corrosion is detected, and seventh example markers 2302G correspond to seventh one(s) of the heat exchangers 1706 at which an unknown coolant anomaly is detected. In some examples, an unknown coolant anomaly is detected when the system monitoring circuitry 1704 of FIG. 17 detects low coolant levels, but the reservoir information 2118 associated with the seventh one(s) of the heat exchangers 1706 does not correspond to any of the known coolant anomalies (e.g., leakage, pressure drop, evaporation, etc.). In some examples, when an unknown coolant anomaly is detected, an operator can manually inspect the seventh one(s) of the heat exchangers 1706 to identify and/or classify the type (e.g., cause, source) of anomaly at the heat exchanger(s) 1706. In some examples, the operator can indicate the anomaly type via the user input(s) 2220 to the system monitoring circuitry 1704. In some such examples, the indicated anomaly type can be used to train and/or re-train one(s) of the machine learning models (e.g., the coolant anomaly detection model(s), the hardware anomaly detection model(s), etc.) to predict to indicated anomaly type for one(s) of the heat exchangers 1706 when the reservoir information 2118 for one(s) of the heat exchangers 1706 corresponds to the reservoir information 2118 for the seventh one(s) of the heat exchangers 1706.

In some examples, one or more additional markers can be included in the first graph 2300 to represent one or more additional coolant anomaly types. In some examples, one or more of the markers 2302 and/or the coolant anomaly types can be omitted from the first graph 2300. In some examples, the first graph 2300 can be output for presentation on the user device 1734 of FIG. 17 to facilitate monitoring and/or maintenance of one(s) of the heat exchangers 1706 by an operator.

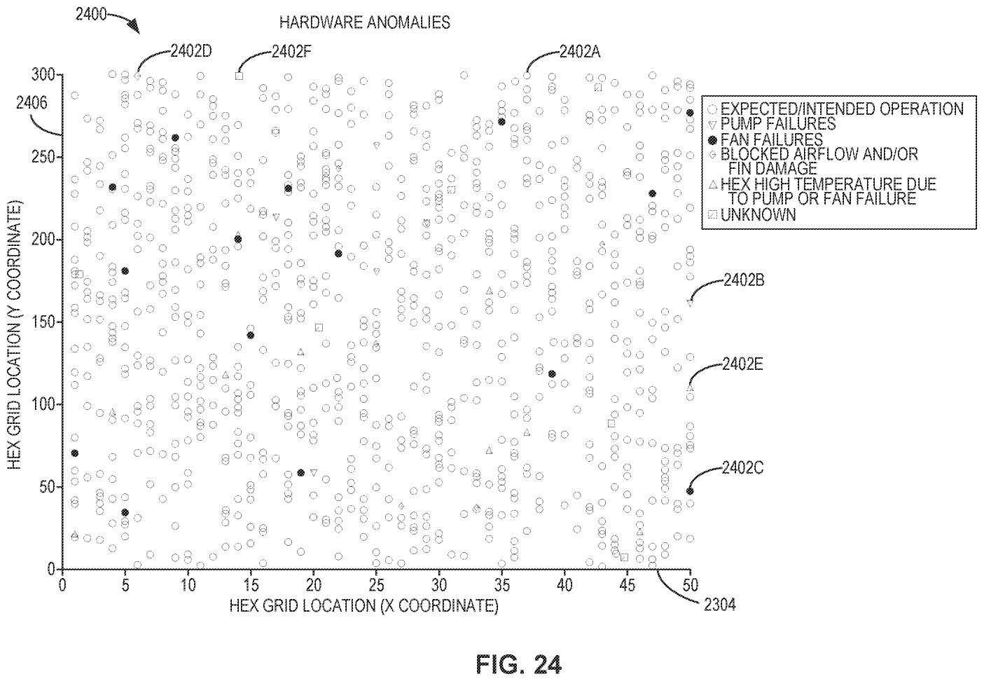

FIG. 24 illustrates a second example graph 2400 that can be generated and/or output by the example output generation circuitry 2214 of FIG. 22. In the illustrated example of FIG. 24, the second graph 2400 represents example hardware anomaly types detected and/or predicted at corresponding locations (e.g., grid locations) of the heat exchangers 1706. In this example, the second graph 2400 includes example markers 2402 representing locations of the heat exchangers 1706 with respect to a first example axis (e.g., an x coordinate axis, a horizontal axis) 2404 and a second example axis (e.g., a y coordinate axis, a vertical axis) 2406.

In the illustrated example of FIG. 24, different ones of the markers 2402 (e.g., having different sizes, shapes, colors, etc.) are used to represent corresponding hardware anomaly types detected and/or predicted for the heat exchangers 1706. For example, first example markers 2402A correspond to first one(s) of the heat exchangers 1706 that are operating as expected or intended (e.g., no hardware anomalies are detected), second example markers 2402B correspond to second one(s) of the heat exchangers 1706 at which a pump failure is detected, third example markers 2402C correspond to third one(s) of the heat exchangers 1706 at a fan failure is detected, fourth example markers 2402D correspond to fourth one(s) of the heat exchangers 1706 at which blocked airflow and/or fin damage is detected, fifth example markers 2402E correspond to fifth one(s) of the heat exchangers 1706 at which high operating temperatures resulting from pump failure and/or fan failure is detected, and sixth example markers 2402F correspond to sixth one(s) of the heat exchangers 1706 at which an unknown hardware anomaly is detected.

In some examples, one or more additional markers can be included in the second graph 2400 to represent one or more additional hardware anomaly types. In some examples, one or more of the markers 2402 and/or the hardware anomaly types can be omitted from the second graph 2400. In some examples, the second graph 2400 can be output for presentation on the user device 1734 of FIG. 17 to facilitate monitoring and/or maintenance of one(s) of the heat exchangers 1706 by an operator.

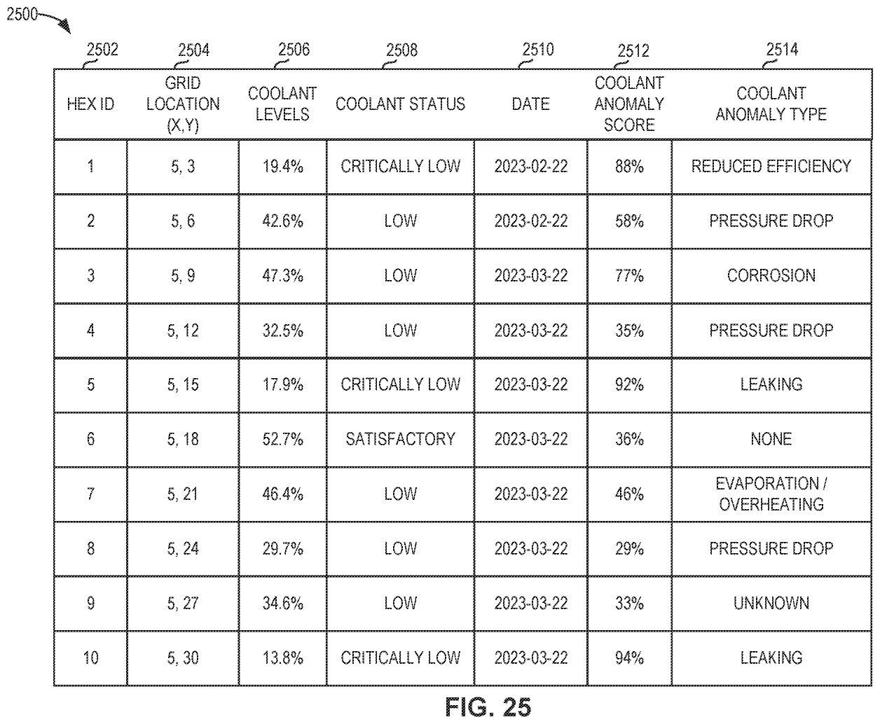

FIG. 25 illustrates a first example table 2500 that can be generated and/or output by the example output generation circuitry 2214 of FIG. 22. In the illustrated example of FIG. 25, the first table 2500 represents the reservoir information 2118 and/or other coolant anomaly information (e.g., coolant anomaly types, coolant anomaly scores, etc.) associated with corresponding ones of the heat exchangers 1706. In the illustrated example of FIG. 25, the first table 2500 includes a first example column 2502 representing example identifiers associated with ones of the heat exchangers 1706, a second example column 2504 representing example locations (e.g., grid locations) of the corresponding heat exchangers 1706, a third example column 2506 representing example coolant levels (e.g., represented as a percentage of coolant capacity) of the corresponding heat exchangers 1706, a fourth example column 2508 representing example coolant statuses (e.g., satisfactory, low, or critically low) of the corresponding heat exchangers 1706, a fifth example column 2510 representing example dates at which the reservoir information 2118 for the corresponding heat exchangers 1706 was determined and/or obtained, a sixth example column 2512 representing example coolant anomaly scores of the corresponding heat exchangers 1706, and a seventh example column 2514 representing example coolant anomaly types of the corresponding heat exchangers 1706.

In some examples, the first table 2500 can include one or more additional columns representing, for example, example hardware anomaly scores and/or example hardware anomaly types of the corresponding heat exchangers 1706. In some examples, one or more of the columns 2502, 2504, 2506, 2508, 2510, 2512, 2514 can be omitted. In some examples, the first table 2500 can be output for presentation on the user device 1734 of FIG. 17 to facilitate monitoring and/or maintenance of one(s) of the heat exchangers 1706 by an operator.

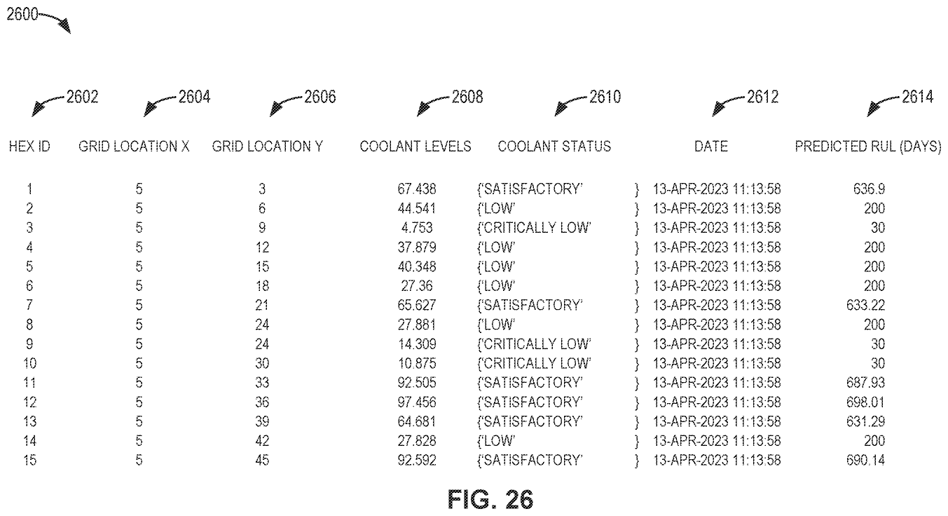

FIG. 26 illustrates a second example table 2600 that can be generated and/or output by the example output generation circuitry 2214 of FIG. 22. In the illustrated example of FIG. 26, the second table 2600 represents the reservoir information 2118 and/or predicted RUL for corresponding ones of the heat exchangers 1706. In this example, the second table 2600 includes a first example column 2602 representing example identifiers associated with ones of the heat exchangers 1706, a second example column 2604 representing first example grid locations (e.g., x coordinates) of the corresponding heat exchangers 1706, a third example column 2606 representing second example grid locations (e.g., y coordinates) of the corresponding heat exchangers 1706, a fourth example column 2608 representing example coolant levels (e.g., represented as a proportion of coolant capacity) of the corresponding heat exchangers 1706, a first example column 2610 representing example coolant statuses (e.g., satisfactory, low, or critically low) of the corresponding heat exchangers 1706, a sixth example column 2612 representing example dates and/or times at which the reservoir information 2118 for the corresponding heat exchangers 1706 was determined and/or obtained, and a seventh example column 2614 representing predicted RUL (e.g., in days) of the corresponding heat exchangers 1706.

In some examples, the second table 2600 can include one or more additional columns representing, for example, example coolant anomaly scores, example hardware anomaly scores, example coolant anomaly types, and/or example hardware anomaly types of the corresponding heat exchangers 1706. In some examples, one or more of the columns 2602, 2604, 2606, 2608, 2610, 2612, 2614 can be omitted. In some examples, the second table 2600 can be output for presentation on the user device 1734 of FIG. 17 to facilitate monitoring and/or maintenance of one(s) of the heat exchangers 1706 by an operator.

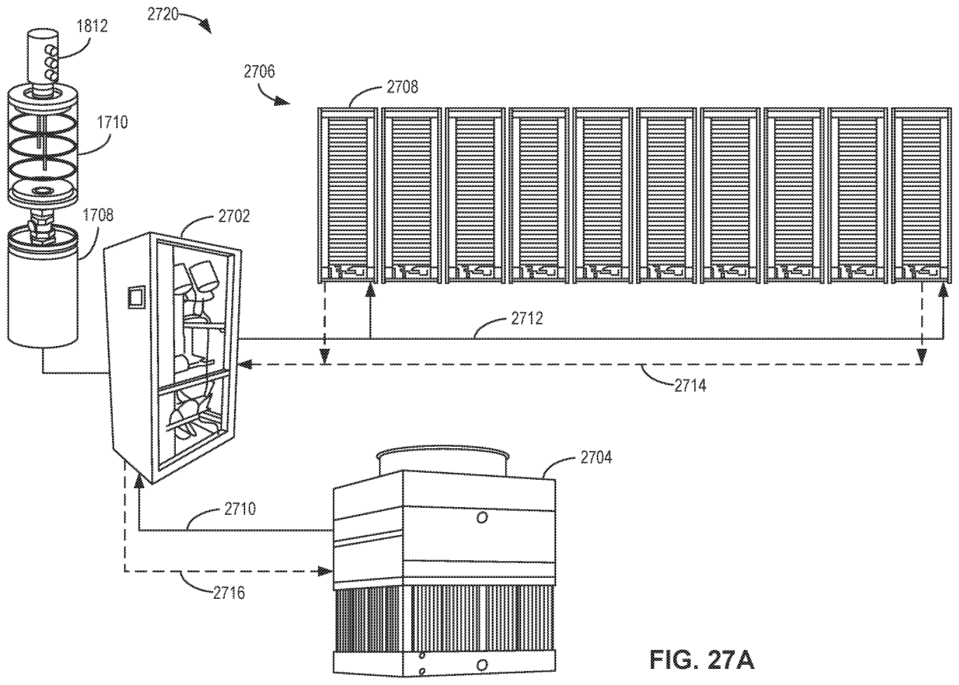

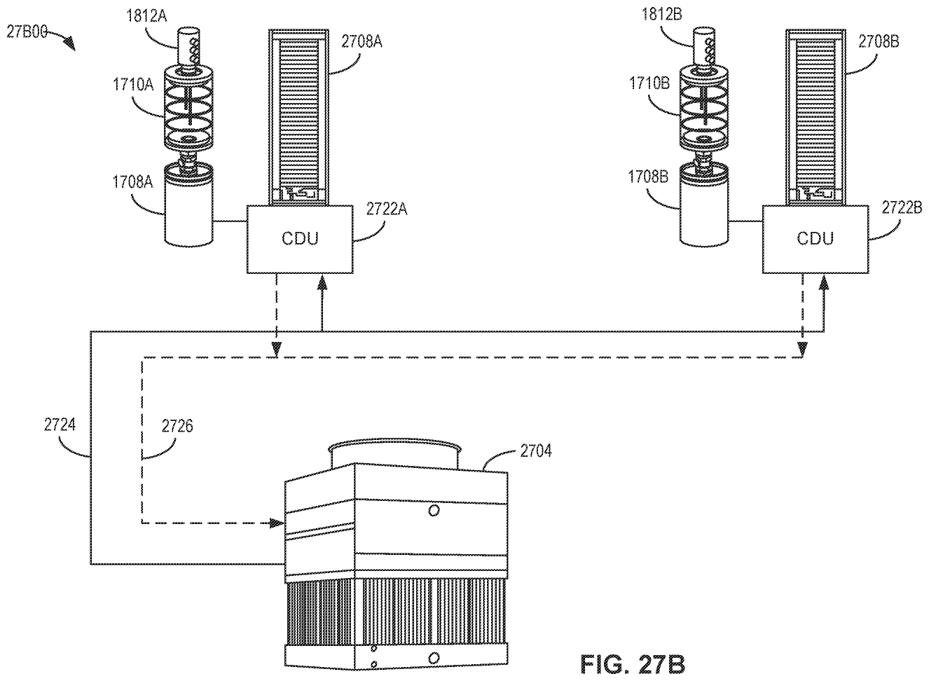

FIG. 27A is a schematic illustration of a first example liquid cooling system 2700 of an example data center environment in which examples disclosed herein can be implemented. In the illustrated example of FIG. 27A, the first liquid cooling system 2700 includes an example cooling distribution unit (CDU) 2702 fluidly coupled to an example cooling tower 2704. In this example, the CDU 2702 is an in-row CDU that is fluidly and/or operatively coupled to an example row 2706 including multiple example racks (e.g., server racks, liquid cooled racks) 2708 to be cooled using fluid (e.g., coolant) from the CDU 2702. In the example of FIG. 27A, the row 2706 includes ten of the racks 2708. In some examples, a different number of racks (e.g., less than ten, greater than ten) can be used instead. While one row 2706 is shown in FIG. 27A, the CDU 2702 can be fluidly coupled to multiple rows of the racks 2708 in some examples.

In operation, the cooling tower 2704 provides fluid to the CDU 2702 along a first example supply line 2710, where the fluid is provided at a first temperature. In some examples, the CDU 2702 directs the fluid along a second example supply line 2712 to one(s) of the racks 2708. In such examples, as the fluid passes through and/or across one or more electronic devices included in the racks 2708, the fluid cools (e.g., draws heat away from) the electronic device(s). In some examples, heated fluid from the racks 2708 returns to the CDU 2702 along a first example return line 2714, where the heated fluid is at a second temperature greater than the first temperature. In some examples, the CDU 2702 provides the heated fluid to the cooling tower via a second example return line 2716, and the heated fluid can be cooled (e.g., back to the first temperature) at the cooling tower 2704 before returning to the CDU 2702.

In the illustrated example of FIG. 27A, the first reservoir 1708 is fluidly coupled to the CDU 2702 to provide and/or store fluid to be utilized by the CDU 2702. Further, the example second reservoir 1710 is fluidly coupled to the first reservoir 1710 to provide fluid in the event that loss of coolant occurs in the first reservoir 1710 (e.g., due to evaporation, leakage, etc.). As described above, the example coolant monitoring device 1812 can be operatively coupled to the second reservoir 1710 to detect and/or indicate a coolant level in the second reservoir 1710. Additionally or alternatively, the coolant monitoring device 1812 can provide the detected coolant levels to the reservoir monitoring circuitry 1702 of FIG. 21 and/or the system monitoring circuitry 1704 of FIG. 22 for use in monitoring and/or predicting anomalies (e.g., coolant anomalies and/or hardware anomalies) associated with the CDU 2702.

FIG. 27B illustrates a second example liquid cooling system 2720 of an example data center environment in which examples disclosed herein can be implemented. In contrast to the first liquid cooling system 2700 of FIG. 27A, the second liquid cooling system 2720 of FIG. 27B includes multiple example CDUs (e.g., in-rack CDUs) 2722A, 2722B fluidly and/or operatively coupled to respective ones of the racks 2708A, 2708B. In this example, the cooling tower 2704 provides fluid to the CDUs 2722A, 2722B via an example supply line 2724, and the CDUs 2722A, 2722B cause circulation of the fluid through the respective racks 2708A, 2708B to cool one or more electronic components therein. In some examples, heated fluid from the racks 2708A, 2808B returns to the cooling tower 2704 via an example return line 2726.

In the example of FIG. 27B, first example reservoirs 1708A, 1708B are fluidly coupled to respective ones of the CDUs 2722A, 2722B to store fluid from and/or supply fluid to the CDUs 2722A, 2722B. In this example, second example reservoirs 1710A, 1710B are fluidly coupled to respective ones of the first reservoirs 1708A, 1708B, and example coolant monitoring devices 1812A, 1812B are operatively coupled to respective ones of the second reservoirs 1710A, 1710B to detect and/or indicate the coolant levels therein. In the example of FIG. 27B, one of the CDUs 2722, one of the first reservoirs 1708, one of the second reservoirs 1710, and one of the coolant monitoring devices 1812 are implemented on a respective one of the racks 2708. In some examples, one or more of the CDUs 2722, one or more of the first reservoirs 1708, one or more of the second reservoirs 1710, and/or one or more of the coolant monitoring devices 1812 can be used for multiple ones of the racks 2708.

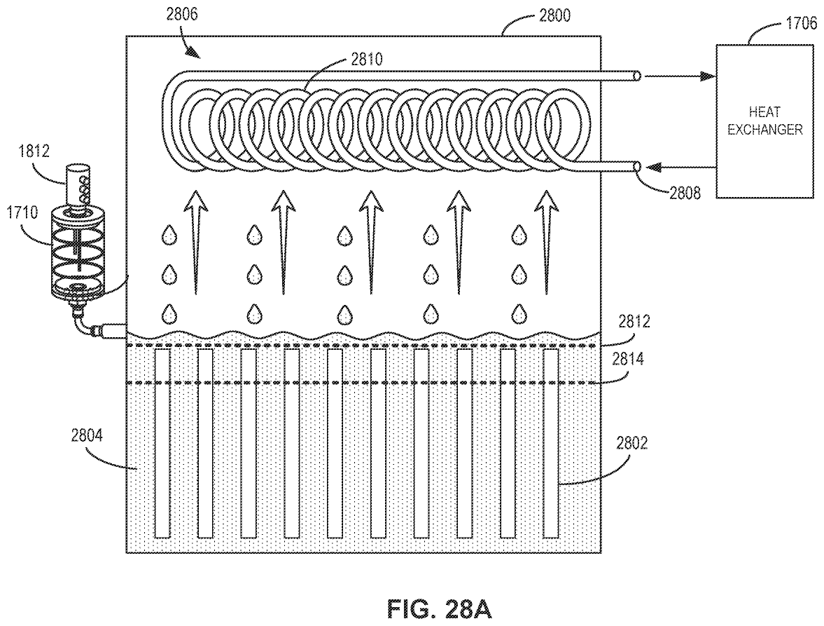

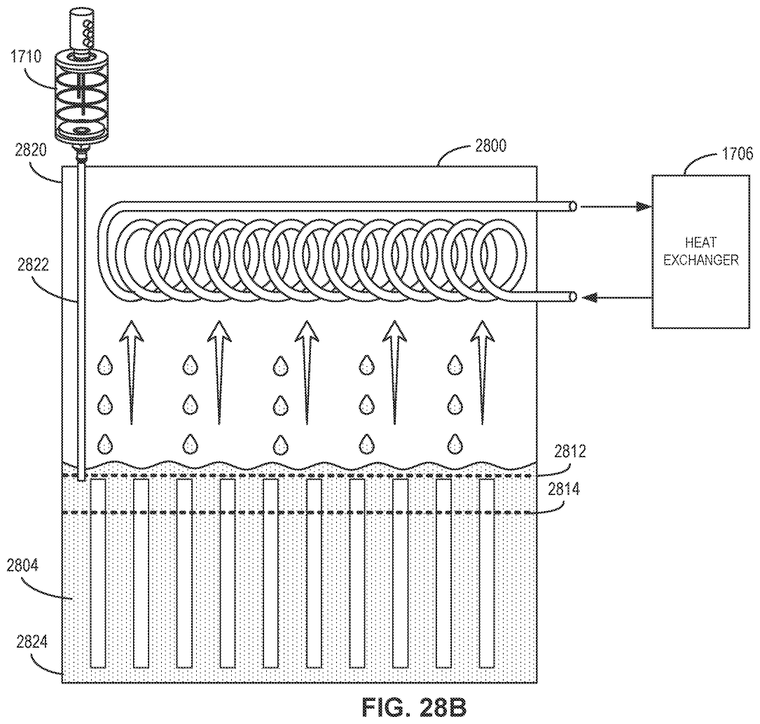

FIG. 28A illustrates an example immersion tank (e.g., an immersion cooling tank) 2800 in which examples disclosed herein can be implemented. In some examples, the immersion tank 2800 can be used to cool one or more devices (e.g., electronic devices and/or components) 2802 that are submerged in fluid (e.g., water, coolant, etc.) 2804 contained in the immersion tank 2800. In some examples, single-phase cooling can be used in which the fluid 2804 does not change phase (e.g., remains in a liquid phase) when drawing heat away from the devices 2802. Conversely, two-phase cooling can be used in some examples, where the heat generated by the devices 2802 causes the fluid 2804 to change from a liquid phase to a vapor phase. In the example of FIG. 28A, an example condenser (e.g., a condenser coil) 2806 is positioned in the immersion tank 2800 to enable cooling and/or condensation of the vaporized fluid 2804. For example, example coolant is provided to the condenser 2806 at an example inlet 2808, and the coolant flows through example coils 2810 of the condenser 2806 before exiting the immersion tank 2800 and flowing to an example heat exchanger (e.g., the heat exchanger 1706) operatively coupled to the condenser 2806. As the coolant flows through the coils 2810, the coolant draws heat away from the vaporized fluid 2804 to enable the fluid 2804 to return to a liquid phase.

In some examples, as a result of vaporization and/or evaporation of the fluid, a level of the fluid 2804 in the immersion tank 2800 reduces over time. In the illustrated example of FIG. 28A, the second reservoir 1710 and the associated coolant monitoring device 1812 is implemented on the immersion tank 2800 to supply additional fluid thereto. In some examples, the immersion tank 2800 includes a first fluid level sensor 2812 to detect whether the fluid in the immersion tank 2800 is below a first example fluid level (e.g., a low fluid level) and a second fluid level sensor 2814 to detect whether the fluid in the immersion tank 2800 is below a second example fluid level (e.g., a critically low fluid level). In some examples, the second reservoir 1710 supplies the additional fluid to the immersion tank 2800 when the fluid level is below the low fluid level and/or the critically low fluid level. For example, one(s) of the fluid level sensors 2812, 2814 can be operatively and/or communicatively coupled to an example valve 2816 implemented between the second reservoir 1710 and the immersion tank 2800. In some examples, the valve 2816 can be opened (e.g., based on example signal(s) from the one(s) of the fluid level sensors 2812, 2814) to enable fluid flow from the second reservoir 1710 to the immersion tank 2800 when the fluid level is below the low fluid level and/or the critically low fluid level. Conversely, the valve 2816 can be closed to restrict and/or prevent the fluid flow from the second reservoir 1718 to the immersion tank 2800 when the fluid level is at or above the low fluid level and/or the critically low fluid level.

FIG. 28B illustrates the example immersion tank 2800 of FIG. 28A, where the second reservoir 1710 is coupled to a different (e.g., top) portion 2820 of the immersion tank 2800 from the location of the second reservoir 1710 in the example of FIG. 28A. In this example, the second reservoir 1710 is fluidly coupled to the fluid 2804 in the immersion tank 2800 via an example pipe (e.g., a tube) 2822. In this example, the pipe 2822 extends from the top portion 2820 of the immersion tank 2800 to a location of the immersion tank 2800 at or below the first fluid level sensor 2812. In some examples, a length and/or a position of the pipe 2822 can be different. For example, the pipe 2822 can extend to a location of the immersion tank 2800 at or below the second fluid level sensor 2812, at a bottom portion 2824 of the immersion tank 2800, etc.

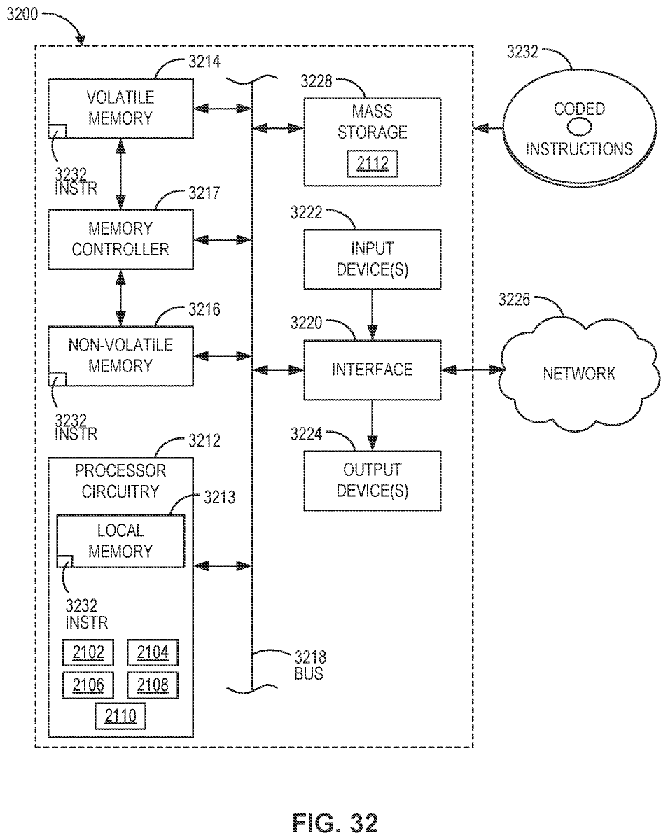

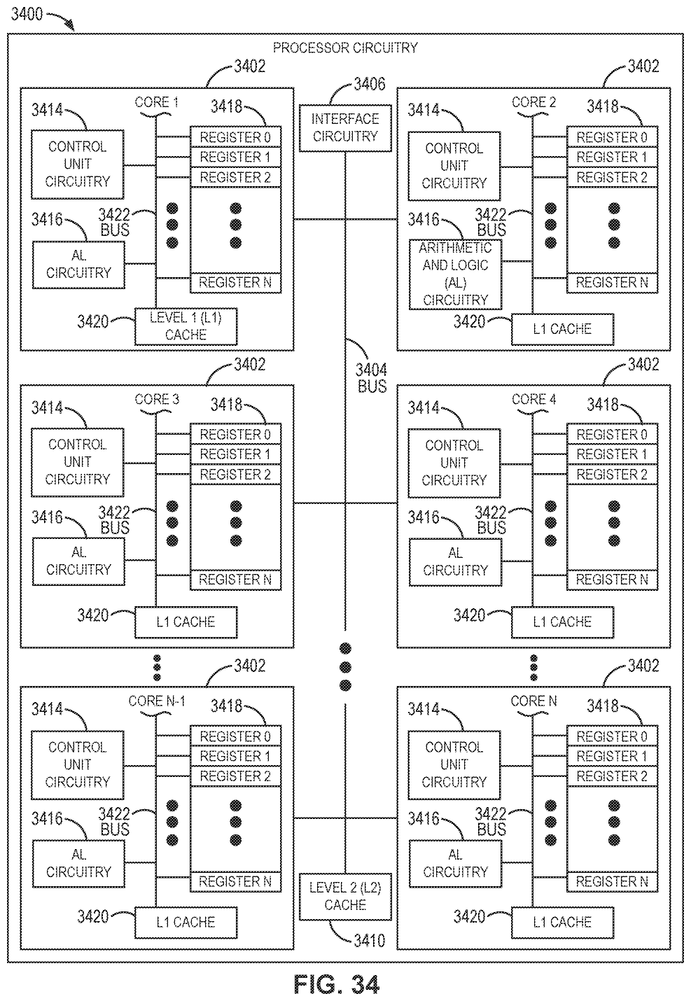

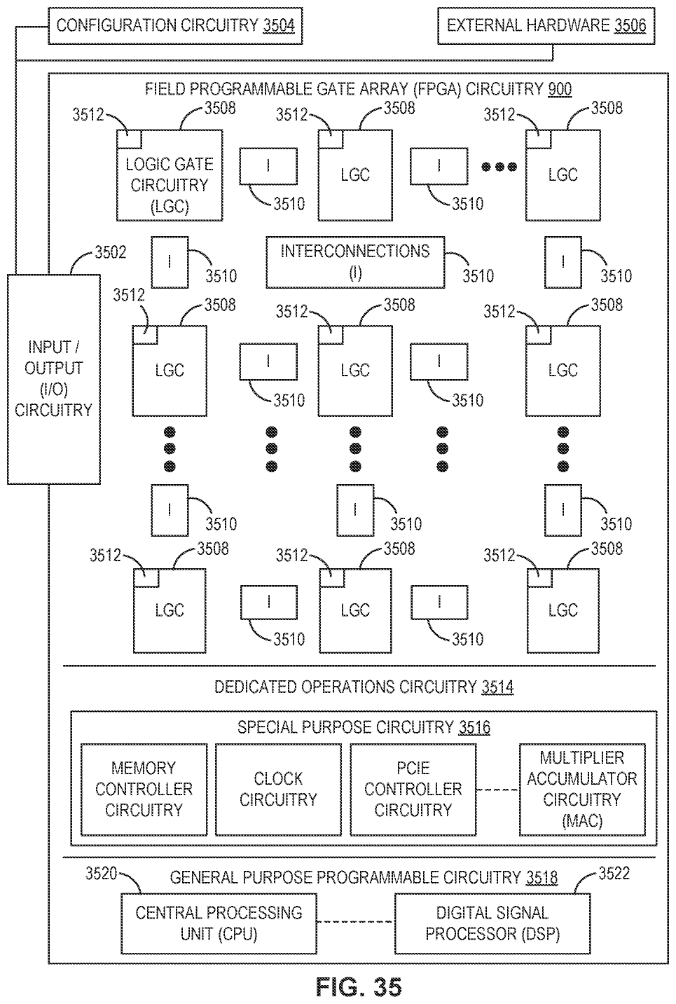

In some examples, the reservoir monitoring circuitry 1702 includes means for obtaining sensor data. For example, the means for obtaining sensor data may be implemented by the sensor interface circuitry 2102. In some examples, the sensor interface circuitry 2102 may be instantiated by programmable circuitry such as the example programmable circuitry 3212 of FIG. 32. For instance, the sensor interface circuitry 2102 may be instantiated by the example microprocessor 3400 of FIG. 34 executing machine executable instructions such as those implemented by at least blocks 2902, 2920 of FIG. 29. In some examples, sensor interface circuitry 2102 may be instantiated by hardware logic circuitry, which may be implemented by an ASIC, XPU, or the FPGA circuitry 3500 of FIG. 35 configured and/or structured to perform operations corresponding to the machine readable instructions. Additionally or alternatively, the sensor interface circuitry 2102 may be instantiated by any other combination of hardware, software, and/or firmware. For example, the sensor interface circuitry 2102 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the reservoir monitoring circuitry 1702 includes means for determining a status. For example, the means for determining a status may be implemented by the status determination circuitry 2104. In some examples, the status determination circuitry 2104 may be instantiated by programmable circuitry such as the example programmable circuitry 3212 of FIG. 32. For instance, the status determination circuitry 2104 may be instantiated by the example microprocessor 3400 of FIG. 34 executing machine executable instructions such as those implemented by at least blocks 2904, 2906, 2908, 2910, 2914 of FIG. 29. In some examples, status determination circuitry 2104 may be instantiated by hardware logic circuitry, which may be implemented by an ASIC, XPU, or the FPGA circuitry 3500 of FIG. 35 configured and/or structured to perform operations corresponding to the machine readable instructions. Additionally or alternatively, the status determination circuitry 2104 may be instantiated by any other combination of hardware, software, and/or firmware. For example, the status determination circuitry 2104 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the reservoir monitoring circuitry 1702 includes means for generating an alert. For example, the means for generating an alert may be implemented by the alert generation circuitry 2106. In some examples, the alert generation circuitry 2106 may be instantiated by programmable circuitry such as the example programmable circuitry 3212 of FIG. 32. For instance, the alert generation circuitry 2106 may be instantiated by the example microprocessor 3400 of FIG. 34 executing machine executable instructions such as those implemented by at least block 2916 of FIG. 29. In some examples, alert generation circuitry 2106 may be instantiated by hardware logic circuitry, which may be implemented by an ASIC, XPU, or the FPGA circuitry 3500 of FIG. 35 configured and/or structured to perform operations corresponding to the machine readable instructions. Additionally or alternatively, the alert generation circuitry 2106 may be instantiated by any other combination of hardware, software, and/or firmware. For example, the alert generation circuitry 2106 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the reservoir monitoring circuitry 1702 includes means for controlling an indicator. For example, the means for controlling an indicator may be implemented by the indicator control circuitry 2108. In some examples, the indicator control circuitry 2108 may be instantiated by programmable circuitry such as the example programmable circuitry 3212 of FIG. 32. For instance, the indicator control circuitry 2108 may be instantiated by the example microprocessor 3400 of FIG. 34 executing machine executable instructions such as those implemented by at least block 2912 of FIG. 29. In some examples, indicator control circuitry 2108 may be instantiated by hardware logic circuitry, which may be implemented by an ASIC, XPU, or the FPGA circuitry 3500 of FIG. 35 configured and/or structured to perform operations corresponding to the machine readable instructions. Additionally or alternatively, the indicator control circuitry 2108 may be instantiated by any other combination of hardware, software, and/or firmware. For example, the indicator control circuitry 2108 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the reservoir monitoring circuitry 1702 includes means for communicating. For example, the means for communicating may be implemented by the communication circuitry 2110. In some examples, the communication circuitry 2110 may be instantiated by programmable circuitry such as the example programmable circuitry 3212 of FIG. 32. For instance, the communication circuitry 2110 may be instantiated by the example microprocessor 3400 of FIG. 34 executing machine executable instructions such as those implemented by at least block 2918 of FIG. 29. In some examples, communication circuitry 2110 may be instantiated by hardware logic circuitry, which may be implemented by an ASIC, XPU, or the FPGA circuitry 3500 of FIG. 35 configured and/or structured to perform operations corresponding to the machine readable instructions. Additionally or alternatively, the communication circuitry 2110 may be instantiated by any other combination of hardware, software, and/or firmware. For example, the communication circuitry 2110 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

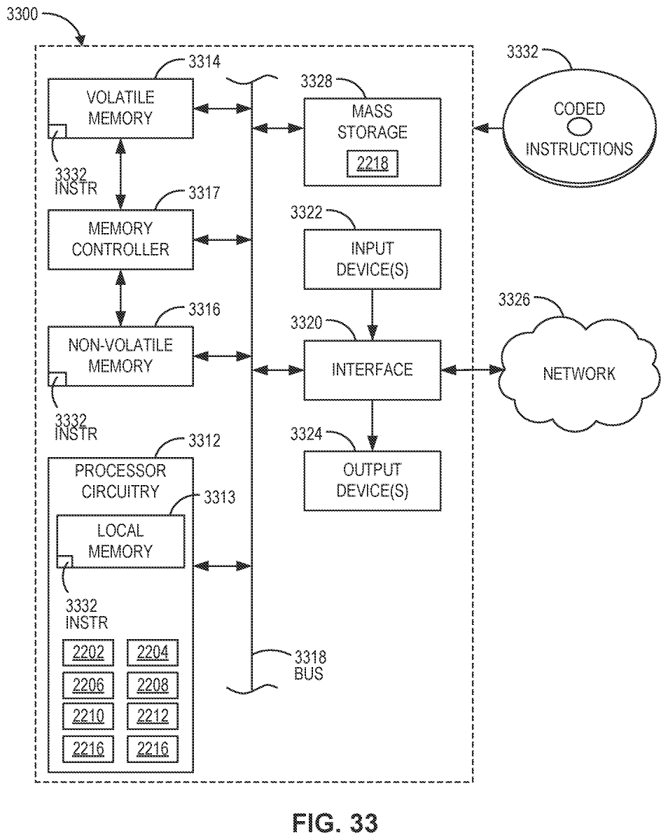

In some examples, the system monitoring circuitry 1704 includes means for obtaining input. For example, the means for obtaining input may be implemented by the input interface circuitry 2202. In some examples, the input interface circuitry 2202 may be instantiated by programmable circuitry such as the example programmable circuitry 3312 of FIG. 33. For instance, the input interface circuitry 2202 may be instantiated by the example microprocessor 3400 of FIG. 34 executing machine executable instructions such as those implemented by at least blocks 3002, 3004, 3018 of FIG. 30. In some examples, input interface circuitry 2202 may be instantiated by hardware logic circuitry, which may be implemented by an ASIC, XPU, or the FPGA circuitry 3500 of FIG. 35 configured and/or structured to perform operations corresponding to the machine readable instructions. Additionally or alternatively, the input interface circuitry 2202 may be instantiated by any other combination of hardware, software, and/or firmware. For example, the input interface circuitry 2202 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

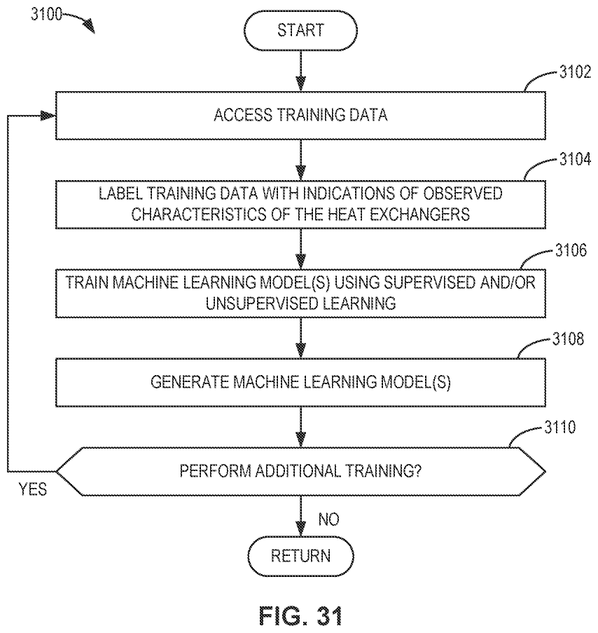

In some examples, the system monitoring circuitry 1704 includes means for training. For example, the means for training may be implemented by the model training circuitry 2204. In some examples, the model training circuitry 2204 may be instantiated by programmable circuitry such as the example programmable circuitry 3312 of FIG. 33. For instance, the model training circuitry 2204 may be instantiated by the example microprocessor 3400 of FIG. 34 executing machine executable instructions such as those implemented by at least blocks 3102, 3104, 3106, 3108, 3110 of FIG. 31. In some examples, the model training circuitry 2204 may be instantiated by hardware logic circuitry, which may be implemented by an ASIC, XPU, or the FPGA circuitry 3500 of FIG. 35 configured and/or structured to perform operations corresponding to the machine readable instructions. Additionally or alternatively, the model training circuitry 2204 may be instantiated by any other combination of hardware, software, and/or firmware. For example, the model training circuitry 2204 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the system monitoring circuitry 1704 includes means for detecting coolant anomalies. For example, the means for detecting coolant anomalies may be implemented by the coolant anomaly detection circuitry 2206. In some examples, the coolant anomaly detection circuitry 2206 may be instantiated by programmable circuitry such as the example programmable circuitry 3312 of FIG. 33. For instance, the coolant anomaly detection circuitry 2206 may be instantiated by the example microprocessor 3400 of FIG. 34 executing machine executable instructions such as those implemented by at least block 3006 of FIG. 30. In some examples, the coolant anomaly detection circuitry 2206 may be instantiated by hardware logic circuitry, which may be implemented by an ASIC, XPU, or the FPGA circuitry 3500 of FIG. 35 configured and/or structured to perform operations corresponding to the machine readable instructions. Additionally or alternatively, the coolant anomaly detection circuitry 2206 may be instantiated by any other combination of hardware, software, and/or firmware. For example, the coolant anomaly detection circuitry 2206 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the system monitoring circuitry 1704 includes means for detecting hardware anomalies. For example, the means for detecting hardware anomalies may be implemented by the hardware anomaly detection circuitry 2208. In some examples, the hardware anomaly detection circuitry 2208 may be instantiated by programmable circuitry such as the example programmable circuitry 3312 of FIG. 33. For instance, the hardware anomaly detection circuitry 2208 may be instantiated by the example microprocessor 3400 of FIG. 34 executing machine executable instructions such as those implemented by at least block 3008 of FIG. 30. In some examples, the hardware anomaly detection circuitry 2208 may be instantiated by hardware logic circuitry, which may be implemented by an ASIC, XPU, or the FPGA circuitry 3500 of FIG. 35 configured and/or structured to perform operations corresponding to the machine readable instructions. Additionally or alternatively, the hardware anomaly detection circuitry 2208 may be instantiated by any other combination of hardware, software, and/or firmware. For example, the hardware anomaly detection circuitry 2208 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the system monitoring circuitry 1704 includes means for predicting. For example, the means for predicting may be implemented by the RUL prediction circuitry 2210. In some examples, the RUL prediction circuitry 2210 may be instantiated by programmable circuitry such as the example programmable circuitry 3312 of FIG. 33. For instance, the RUL prediction circuitry 2210 may be instantiated by the example microprocessor 3400 of FIG. 34 executing machine executable instructions such as those implemented by at least block 3010 of FIG. 30. In some examples, the RUL prediction circuitry 2210 may be instantiated by hardware logic circuitry, which may be implemented by an ASIC, XPU, or the FPGA circuitry 3500 of FIG. 35 configured and/or structured to perform operations corresponding to the machine readable instructions. Additionally or alternatively, the RUL prediction circuitry 2210 may be instantiated by any other combination of hardware, software, and/or firmware. For example, the RUL prediction circuitry 2210 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the system monitoring circuitry 1704 includes means for analyzing. For example, the means for analyzing may be implemented by the cluster analysis circuitry 2212. In some examples, the cluster analysis circuitry 2212 may be instantiated by programmable circuitry such as the example programmable circuitry 3312 of FIG. 33. For instance, the cluster analysis circuitry 2212 may be instantiated by the example microprocessor 3400 of FIG. 34 executing machine executable instructions such as those implemented by at least block 3012 of FIG. 30. In some examples, the cluster analysis circuitry 2212 may be instantiated by hardware logic circuitry, which may be implemented by an ASIC, XPU, or the FPGA circuitry 3500 of FIG. 35 configured and/or structured to perform operations corresponding to the machine readable instructions. Additionally or alternatively, the cluster analysis circuitry 2212 may be instantiated by any other combination of hardware, software, and/or firmware. For example, the cluster analysis circuitry 2212 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the system monitoring circuitry 1704 includes means for generating output. For example, the means for generating output may be implemented by the output generation circuitry 2214. In some examples, the output generation circuitry 2214 may be instantiated by programmable circuitry such as the example programmable circuitry 3312 of FIG. 33. For instance, the output generation circuitry 2214 may be instantiated by the example microprocessor 3400 of FIG. 34 executing machine executable instructions such as those implemented by at least block 3014 of FIG. 30. In some examples, the output generation circuitry 2214 may be instantiated by hardware logic circuitry, which may be implemented by an ASIC, XPU, or the FPGA circuitry 3500 of FIG. 35 configured and/or structured to perform operations corresponding to the machine readable instructions. Additionally or alternatively, the output generation circuitry 2214 may be instantiated by any other combination of hardware, software, and/or firmware. For example, the output generation circuitry 2214 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In some examples, the system monitoring circuitry 1704 includes means for adjusting. For example, the means for adjusting may be implemented by the control adjustment circuitry 2216. In some examples, the control adjustment circuitry 2216 may be instantiated by programmable circuitry such as the example programmable circuitry 3312 of FIG. 33. For instance, the control adjustment circuitry 2216 may be instantiated by the example microprocessor 3400 of FIG. 34 executing machine executable instructions such as those implemented by at least block 3016 of FIG. 30. In some examples, the control adjustment circuitry 2216 may be instantiated by hardware logic circuitry, which may be implemented by an ASIC, XPU, or the FPGA circuitry 3500 of FIG. 35 configured and/or structured to perform operations corresponding to the machine readable instructions. Additionally or alternatively, the control adjustment circuitry 2216 may be instantiated by any other combination of hardware, software, and/or firmware. For example, the control adjustment circuitry 2216 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

While an example manner of implementing the reservoir monitoring circuitry 1702 of FIG. 17 is illustrated in FIG. 21, one or more of the elements, processes, and/or devices illustrated in FIG. 21 may be combined, divided, re-arranged, omitted, eliminated, and/or implemented in any other way. Further, the example sensor interface circuitry 2102, the example status determination circuitry 2104, the example alert generation circuitry 2106, the example indicator control circuitry 2108, the example communication circuitry 2110, the example reservoir database 2112, and/or, more generally, the example reservoir monitoring circuitry 1702 of FIG. 21, may be implemented by hardware alone or by hardware in combination with software and/or firmware. Thus, for example, any of the example sensor interface circuitry 2102, the example status determination circuitry 2104, the example alert generation circuitry 2106, the example indicator control circuitry 2108, the example communication circuitry 2110, the example reservoir database 2112, and/or, more generally, the example reservoir monitoring circuitry 1702, could be implemented by programmable circuitry in combination with machine readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), and/or field programmable logic device(s) (FPLD(s)) such as FPGAs. Further still, the example reservoir monitoring circuitry 1702 of FIG. 21 may include one or more elements, processes, and/or devices in addition to, or instead of, those illustrated in FIG. 21, and/or may include more than one of any or all of the illustrated elements, processes and devices.

While an example manner of implementing the system monitoring circuitry 1704 of FIG. 17 is illustrated in FIG. 22, one or more of the elements, processes, and/or devices illustrated in FIG. 22 may be combined, divided, re-arranged, omitted, eliminated, and/or implemented in any other way. Further, the example input interface circuitry 2202, the example model training circuitry 2204, the example coolant anomaly detection circuitry 2206, the example hardware anomaly detection circuitry 2208, the example RUL prediction circuitry 2210, the example cluster analysis circuitry 2212, the example output generation circuitry 2214, the example control adjustment circuitry 2216, the example system database 2218, and/or, more generally, the example system monitoring circuitry 1704 of FIG. 22, may be implemented by hardware alone or by hardware in combination with software and/or firmware. Thus, for example, any of the example input interface circuitry 2202, the example model training circuitry 2204, the example coolant anomaly detection circuitry 2206, the example hardware anomaly detection circuitry 2208, the example RUL prediction circuitry 2210, the example cluster analysis circuitry 2212, the example output generation circuitry 2214, the example control adjustment circuitry 2216, the example system database 2218, and/or, more generally, the example system monitoring circuitry 1704, could be implemented by programmable circuitry in combination with machine readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), and/or field programmable logic device(s) (FPLD(s)) such as FPGAs. Further still, the example system monitoring circuitry 1704 of FIG. 22 may include one or more elements, processes, and/or devices in addition to, or instead of, those illustrated in FIG. 22, and/or may include more than one of any or all of the illustrated elements, processes and devices.

Flowchart(s) representative of example machine readable instructions, which may be executed by programmable circuitry to implement and/or instantiate the reservoir monitoring circuitry 1702 of FIG. 21 and/or the system monitoring circuitry 1704 of FIG. 22 and/or representative of example operations which may be performed by programmable circuitry to implement and/or instantiate the reservoir monitoring circuitry 1702 of FIG. 21 and/or the system monitoring circuitry 1704 of FIG. 22, are shown in FIGS. 29, 30, and/or 31. The machine readable instructions may be one or more executable programs or portion(s) of one or more executable programs for execution by programmable circuitry such as the programmable circuitry 3212 shown in the example processor platform 3200 discussed below in connection with FIG. 32 and/or the programmable circuitry 3312 shown in the example processor platform 3300 discussed below in connection with FIG. 33 and/or may be one or more function(s) or portion(s) of functions to be performed by the example programmable circuitry (e.g., an FPGA) discussed below in connection with FIGS. 34 and/or 35. In some examples, the machine readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIGS. 29, 30, and/or 31, many other methods of implementing the example reservoir monitoring circuitry 1702 and/or the system monitoring circuitry 1704 may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). For example, the programmable circuitry may be a CPU and/or an FPGA located in the same package (e.g., the same integrated circuit (IC) package or in two or more separate housings), one or more processors in a single machine, multiple processors distributed across multiple servers of a server rack, multiple processors distributed across one or more server racks, etc., and/or any combination(s) thereof.

The machine readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine readable instructions may be fragmented and stored on one or more storage devices, disks and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable, computer readable and/or machine readable media, as used herein, may include instructions and/or program(s) regardless of the particular format or state of the machine readable instructions and/or program(s).

The machine readable instructions described herein can be represented by any past, present, or future instruction language, scripting language, programming language, etc. For example, the machine readable instructions may be represented using any of the following languages: C, C++, Java, C#, Perl, Python, JavaScript, HyperText Markup Language (HTML), Structured Query Language (SQL), Swift, etc.

As mentioned above, the example operations of FIGS. 29, 30, and/or 31 may be implemented using executable instructions (e.g., computer readable and/or machine readable instructions) stored on one or more non-transitory computer readable and/or machine readable media. As used herein, the terms non-transitory computer readable medium, non-transitory computer readable storage medium, non-transitory machine readable medium, and/or non-transitory machine readable storage medium are expressly defined to include any type of computer readable storage device and/or storage disk and to exclude propagating signals and to exclude transmission media. Examples of such non-transitory computer readable medium, non-transitory computer readable storage medium, non-transitory machine readable medium, and/or non-transitory machine readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

FIG. 29 is a flowchart representative of example machine readable instructions and/or example operations 2900 that may be executed, instantiated, and/or performed by programmable circuitry to implement the example reservoir monitoring circuitry 1702 of FIG. 21. The example machine-readable instructions and/or the example operations 2900 of FIG. 29 begin at block 2902, at which the example reservoir monitoring circuitry 1702 obtains the example sensor data 2114 associated with one or more second reservoirs 1710 of FIGS. 17, 18A, 18B, 19, 20, 27A, 27B, 28A, and/or 28B. For example, the example sensor interface circuitry 2102 of FIG. 21 obtains the sensor data 2114 corresponding to outputs of one or more of the example sensors 1728 implemented in the second reservoir(s) 1710. In some examples, the sensor data 2114 represents coolant levels at the corresponding second reservoir(s) 1710.

At block 2904, the example reservoir monitoring circuitry 1702 determines example location(s) and/or example identifier(s) corresponding to the second reservoir(s) 1710. For example, the sensor interface circuitry 2102 determines the location(s) (e.g., grid locations, grid coordinates) and/or the identifier(s) corresponding to one(s) of the heat exchangers 1706 associated with the second reservoir(s) 1710. In some examples, the sensor interface circuitry 2102 causes storage of the location(s) and/or the identifier(s) in association with the sensor data 2114 obtained for the second reservoir(s) 1710.

At block 2906, the example reservoir monitoring circuitry 1702 selects and/or adjusts one or more example thresholds (e.g., coolant level threshold(s)) for evaluation of coolant levels at the second reservoir(s) 1710. For example, the example status determination circuitry 2104 selects and/or adjusts the threshold(s) based on user input(s). In some examples, the thresholds are percentages of coolant capacity of the second reservoir(s) 1710. In some examples, the thresholds are used to determine whether the coolant levels in the second reservoir(s) 1710 are satisfactory, low, or critically low. In some examples, the threshold(s) are based on expected heat dissipation at the heat exchanger(s) 1706, expected evaporation rate of the coolant, a number of the heat exchangers 1706 implemented in an example system, an expected lifetime of the heat exchanger(s) 1706, etc.

At block 2908, the example reservoir monitoring circuitry 1702 determines the coolant level(s) at the second reservoir(s) 1710 based on the sensor data 2114. For example, the status determination circuitry 2104 determines the coolant level(s) based on one or more signals from the sensors 1728, where the signal(s) indicate a measured value of the coolant level(s) (e.g., a percentage of coolant capacity, a height) at the second reservoir(s) 1710. Additionally or alternatively, the signal(s) indicate whether the coolant level(s) at the second reservoir(s) 1710 satisfy the threshold(s) for corresponding one(s) of the sensor(s) 1728. In some examples, the status determination circuitry 2104 determines that the coolant level(s) are at or above one(s) of the thresholds when the sensor data 2114 includes the signal(s) from one(s) of the sensors 1728, and the status determination circuitry 2104 determines that the coolant level(s) are below one(s) of the thresholds when the sensor data 2114 does not include the signal(s) from one(s) of the sensors 1728.

At block 2910, the example reservoir monitoring circuitry 1702 determines the status(es) of the second reservoir(s) 1710 by comparing the coolant level(s) to the threshold(s). For example, the status determination circuitry 2104 determines whether the coolant level(s) at the second reservoir(s) 1710 are satisfactory, low, or critically low based on the comparison. In some examples, the status determination circuitry 2104 determines the coolant level(s) are satisfactory when the coolant level(s) satisfy (e.g., are at or above) a first example threshold. In some examples, the status determination circuitry 2104 determines the coolant level(s) are low when the coolant level(s) satisfy (e.g., are at or above) a second example threshold, but do not satisfy (e.g., are below) the first threshold. In some examples, the status determination circuitry 2104 determines the coolant level(s) are critically low when the coolant level(s) do not satisfy (e.g., are below) the second threshold and/or a third example threshold.

At block 2912, the example reservoir monitoring circuitry 1702 activates one or more of the example light sources (e.g., indicators) 1732 based on the determined status(es). For example, when the status(es) indicate the coolant level(s) are satisfactory, the example indicator control circuitry 2108 activates the first light source 1732A and does not activate (e.g., and/or deactivates) the second and third light sources 1732B, 1732C. In some examples, when the status(es) indicate the coolant level(s) are low, the indicator control circuitry 2108 activates the second light source 1732B and does not activate (e.g., and/or deactivates) the first and third light sources 1732A, 1732C. In some examples, when the status(es) indicate the coolant level(s) are critically low, the indicator control circuitry 2108 activates the third light source 1732C and does not activate (e.g., and/or deactivates) the first and second light sources 1732A, 1732B.

At block 2914, the example reservoir monitoring circuitry 1702 determines whether the coolant level(s) are low and/or critically low. For example, in response to the status determination circuitry 2104 determining that the coolant level(s) are low and/or critically low (e.g., block 2914 returns a result of YES), control proceeds to block 2916. Alternatively, in response to the status determination circuitry 2104 determining that the coolant level(s) are not low and/or not critically low (e.g., block 2914 returns a result of NO), control proceeds to block 2918.

At block 2916, the example reservoir monitoring circuitry 1702 generates and/or outputs one or more example alerts 2116. For example, the example alert generation circuitry 2106 generates the alert(s) 2116 including the coolant level(s), the status(es), the date(s) and/or time(s) at which the alert(s) were generated, the identifier(s) and/or location(s) associated with the second reservoir(s) 1710, etc. In some examples, the alert generation circuitry 2106 outputs the alert(s) 2116 for presentation on the example user device 1734 (e.g., as an email, an SMS message, and/or a dashboard on the user device 1734).

At block 2918, the example reservoir monitoring circuitry 1702 transmits and/or causes storage of the example reservoir information 2118 of FIG. 21. For example, the example communication circuitry 2110 causes storage of the reservoir information 2118 in the example reservoir database 2112, where the reservoir information 2118 includes the coolant level(s) and/or the status(es) of the coolant in the second reservoir 1710, the date(s) and/or time(s) associated with the coolant level(s), the identifier(s) and/or the location(s) associated with the second reservoir 1710, etc. Additionally or alternatively, the communication circuitry 2110 transmits the reservoir information 2118 to the example system monitoring circuitry 1704 of FIG. 22 for use in detecting and/or predicting anomalies and/or performance associated with the heat exchanger(s) 1706.

At block 2920, the example reservoir monitoring circuitry 1702 determines whether to continue monitoring. For example, the sensor interface circuitry 2102 determines to continue monitoring when additional sensor data is obtained from the example sensor(s) 1728. In response to the sensor interface circuitry 2102 determining to continue monitoring (e.g., block 2920 returns a result of YES), control returns to block 2902. Alternatively, in response to the sensor interface circuitry 2102 determining not to continue monitoring (e.g., block 2920 returns a result of NO), control ends.

FIG. 30 is a flowchart representative of example machine readable instructions and/or example operations 3000 that may be executed, instantiated, and/or performed by programmable circuitry to implement the example system monitoring circuitry 1704 of FIG. 22. The example machine-readable instructions and/or the example operations 3000 of FIG. 30 begin at block 3002, at which the example system monitoring circuitry 1704 obtains the example user input(s) 2220 of FIG. 22. For example, the example input interface circuitry 2202 of FIG. 22 obtains the user input(s) 2220 provided by an operator via the example user device 1734 of FIG. 17. In some examples, the user input(s) 2220 can include observed coolant levels at the one(s) of the heat exchangers 1706, observed anomalies at the one(s) of the heat exchangers 1706, etc.

At block 3004, the example system monitoring circuitry 1704 obtains the example reservoir information 2118 associated with one or more of the example second reservoirs 1710 of FIGS. 17, 18A, 18B, 19, 20, 27A, 27B, 28A, and/or 28B. For example, the input interface circuitry 2202 obtains the reservoir information 2118 from the example reservoir monitoring circuitry 1702 of FIG. 21, where the reservoir information 2118 includes coolant level(s) and/or status(es) of coolant in the second reservoir(s) 1710, date(s) and/or time(s) associated with the coolant level(s), identifier(s) and/or location(s) associated with the second reservoir(s) 1710, etc.

At block 3006, the example system monitoring circuitry 1704 detects and/or predicts example coolant anomalies based on the coolant anomaly detection model(s) (e.g., machine learning model(s) trained by the model training circuitry 2204 as discussed in connection with the flowchart of FIG. 31). For example, the example coolant anomaly detection circuitry 2206 executes the coolant anomaly detection model(s) based on the reservoir information 2118 and, based on the execution, outputs one or more coolant anomalies detected and/or predicted for corresponding one(s) of the heat exchangers 1706. In some examples, the coolant anomalies include evaporation and/or overheating of coolant, leakage of the coolant, reduced efficiency of the coolant, pressure drop of the coolant, corrosion of equipment associated with the coolant, etc. Additionally or alternatively, as a result of the execution of the coolant anomaly detection model(s), the coolant anomaly detection circuitry 2206 can output coolant anomaly score(s) corresponding to one(s) of the heat exchangers 1706. In some examples, the coolant anomaly scores indicate likelihoods of the coolant anomalies occurring for the corresponding one(s) of the heat exchangers 1706.

At block 3008, the example system monitoring circuitry 1704 detects and/or predicts example hardware anomalies based on the hardware anomaly detection model(s). For example, the example hardware anomaly detection circuitry 2208 executes the hardware anomaly detection model(s) based on the reservoir information 2118 and, based on the execution, outputs one or more hardware anomalies detected and/or predicted for corresponding one(s) of the heat exchangers 1706. In some examples, the hardware anomalies include pump failures, fan failures, fin damage, blocked airflow, operating temperatures of the heat exchangers 1706 above a threshold, etc. Additionally or alternatively, as a result of the execution of the hardware anomaly detection model(s), the hardware anomaly detection circuitry 2208 can output hardware anomaly score(s) corresponding to one(s) of the heat exchangers 1706. In some examples, the hardware anomaly scores indicate likelihoods of the hardware anomalies occurring for the corresponding one(s) of the heat exchangers 1706.

At block 3010, the example system monitoring circuitry 1704 detects and/or predicts example RUL of the heat exchanger(s) 1706 based on the RUL prediction model(s). For example, the example RUL prediction circuitry 2210 executes the RUL prediction model(s) based on the reservoir information 2118 and, based on the execution, outputs RULs for corresponding one(s) of the heat exchangers 1706. In some examples, the RUL(s) represent duration(s) for which one(s) of heat exchangers 1706 can operate until repair and/or replacement of the one(s) of the heat exchangers 1706 is expected.

At block 3012, the example system monitoring circuitry 1704 classifies the heat exchangers 1706 in view of, for example, anomalies, behaviors, etc. For example, the example cluster analysis circuitry 2212 identifies the cluster(s) by analyzing coolant level patterns for the heat exchangers 1706 represented in the reservoir information 2118, and groups one(s) of the heat exchanger(s) 1706 based on similarity of the coolant level patterns. In some examples, the cluster analysis circuitry 2212 identifies the cluster(s) of the heat exchanger(s) 1706 corresponding to a particular coolant anomaly type, hardware anomaly type, and/or predicted RUL range.

At block 3014, the example system monitoring circuitry 1704 generates example output(s) based on one or more detected and/or predicted values and/or characteristics. For example, the example output generation circuitry 2214 generates and/or outputs the example display information 2222 including one or more example tables and/or example graphs to represent the reservoir information 2118 and/or one or more characteristics (e.g., the coolant anomalies, the hardware anomalies, the anomaly scores, the RUL, etc.) predicted and/or detected for the heat exchangers 1706. In some examples, the display information 2222 can include identifier(s), location(s), coolant level(s), coolant anomaly type(s), hardware anomaly type(s), and/or anomaly score(s) associated with one(s) of the heat exchangers 1706. In some examples, the output generation circuitry 2214 outputs the display information 2222 for presentation by the user device 1734.

At block 3016, the example system monitoring circuitry 1704 causes one or more control parameters to be adjusted based on the output(s). For example, the example control adjustment circuitry 2216 causes the control parameter(s) (e.g., including fan speed, pump speed, and/or coolant flow rate of the heat exchangers 1706) to be adjusted based on control signal(s) sent to the corresponding one(s) of the heat exchangers 1706, the fans 1722, the pump 1720, etc. In some examples, the control adjustment circuitry 2216 adjusts and/or selects the control parameters based on the reservoir information 2118 and/or the detected and/or predicted characteristics (e.g., the coolant anomalies, the hardware anomalies, the anomaly scores, etc.) for one(s) of the heat exchangers 1706.

At block 3018, the example system monitoring circuitry 1704 determines whether to continue monitoring. For example, the input interface circuitry 2202 determines to continue monitoring when additional user input(s) and/or additional reservoir information is obtained from the example reservoir monitoring circuitry 1702. In response to the input interface circuitry 2202 determining to continue monitoring (e.g., block 3018 returns a result of YES), control returns to block 3002. Alternatively, in response to the input interface circuitry 2202 determining not to continue monitoring (e.g., block 3018 returns a result of NO), control ends.

FIG. 31 is a flowchart representative of example machine readable instructions and/or example operations 3100 that may be executed, instantiated, and/or performed by programmable circuitry to train and/or re-train one or more example machine learning models to be utilized by the system monitoring circuitry 1704 of FIG. 22. The example instructions 3100 of FIG. 31, when executed by the model training circuitry 2204 of FIG. 22, result in one or more machine learning models (e.g., the coolant anomaly detection model(s), the hardware anomaly detection model(s), the RUL prediction model(s), etc.) that can be distributed to other computing systems, such as the coolant anomaly detection circuitry 2206, the hardware anomaly detection circuitry 2208, and/or the RUL prediction circuitry 2210 of the example system monitoring circuitry 1704.

The example machine-readable instructions and/or the example operations 3100 of FIG. 31 begin at block 3102, at which the example system monitoring circuitry 1704 of FIG. 22 accesses example training data. For example, the model training circuitry 2204 of FIG. 22 can access the training data stored in the example reservoir database 2112 of FIG. 21 and/or the example system database 2218 of FIG. 22. In some examples, the training data can include historical data indicating coolant levels, coolant pressures, operating temperatures of the heat exchangers 1706, heat flux cooled by the heat exchangers 1706, pump operating efficiency of the heat exchangers 1706, etc. at corresponding points in time.

At block 3104, the example system monitoring circuitry 1704 labels the training data with indications of anomalies and/or other characteristics observed for the heat exchangers 1706. For example, the model training circuitry 2204 labels the training data with labels indicating type(s) of anomalies (e.g., coolant anomalies and/or hardware anomalies) observed at the heat exchangers 1706 at the corresponding points in time. In some examples, the labels are generated based on user input from an operator performing manual and/or visual inspection of the heat exchangers 1706.

At block 3106, the example system monitoring circuitry 1704 trains the machine learning model(s) using supervised and/or unsupervised learning. For example, the model training circuitry 2204 trains the machine learning model(s) based on the labeled training data. As a result of the training, at least one of the coolant anomaly detection model(s), the hardware anomaly detection model(s), or the RUL prediction model(s) are generated at block 3108. In some examples, the coolant anomaly detection model(s) are trained to output coolant anomalies (e.g., evaporation and/or overheating of the coolant, leakage of the coolant, reduced efficiency of the coolant, pressure drop of the coolant, corrosion of equipment associated with the coolant, etc.) and/or coolant anomaly scores for the heat exchangers 1706. In some examples, the hardware anomaly detection model(s) are trained to output hardware anomalies (e.g., pump failures, fan failures, blocked air flow, fin damage, operating temperatures exceeding a threshold, etc.) and/or hardware anomaly scores for the heat exchangers 1706. In some examples, the RUL prediction model(s) are trained to output predicted RUL (e.g., in days, weeks, months, etc.) for the heat exchangers 1706.

In some examples, the coolant anomaly detection model(s), the hardware anomaly detection model(s), and/or the RUL prediction model(s) can be stored in the system database 2218 of FIG. 22 for access by the coolant anomaly detection circuitry 2206, the hardware anomaly detection circuitry 2208, and/or the RUL prediction circuitry 2210 of FIG. 22. The example instructions 3100 of FIG. 31 end when no additional training (e.g., re-training) is to be performed (block 3110).

FIG. 32 is a block diagram of an example programmable circuitry platform 3200 structured to execute and/or instantiate the example machine-readable instructions and/or the example operations of FIG. 29 to implement the reservoir monitoring circuitry 1702 of FIG. 21. The programmable circuitry platform 3200 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing and/or electronic device.

The programmable circuitry platform 3200 of the illustrated example includes programmable circuitry 3212. The programmable circuitry 3212 of the illustrated example is hardware. For example, the programmable circuitry 3212 can be implemented by one or more integrated circuits, logic circuits, FPGAs, microprocessors, CPUs, GPUs, DSPs, and/or microcontrollers from any desired family or manufacturer. The programmable circuitry 3212 may be implemented by one or more semiconductor based (e.g., silicon based) devices. In this example, the programmable circuitry 3212 implements the example sensor interface circuitry 2102, the example status determination circuitry 2104, the example alert generation circuitry 2106, the example indicator control circuitry 2108, the example communication circuitry 2110, and the example reservoir database 2112.

The programmable circuitry 3212 of the illustrated example includes a local memory 3213 (e.g., a cache, registers, etc.). The programmable circuitry 3212 of the illustrated example is in communication with main memory 3214, 3216, which includes a volatile memory 3214 and a non-volatile memory 3216, by a bus 3218. The volatile memory 3214 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 3216 may be implemented by flash memory and/or any other desired type of memory device. Access to the main memory 3214, 3216 of the illustrated example is controlled by a memory controller 3217. In some examples, the memory controller 3217 may be implemented by one or more integrated circuits, logic circuits, microcontrollers from any desired family or manufacturer, or any other type of circuitry to manage the flow of data going to and from the main memory 3214, 3216.

The programmable circuitry platform 3200 of the illustrated example also includes interface circuitry 3220. The interface circuitry 3220 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 3222 are connected to the interface circuitry 3220. The input device(s) 3222 permit(s) a user (e.g., a human user, a machine user, etc.) to enter data and/or commands into the programmable circuitry 3212. The input device(s) 3222 can be implemented by, for example, an audio sensor, a microphone, a camera (still or video), a keyboard, a button, a mouse, a touchscreen, a trackpad, a trackball, an isopoint device, and/or a voice recognition system.

One or more output devices 3224 are also connected to the interface circuitry 3220 of the illustrated example. The output device(s) 3224 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 3220 of the illustrated example, thus, typically includes a graphics driver card, a graphics driver chip, and/or graphics processor circuitry such as a GPU.

The interface circuitry 3220 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 3226. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 3200 of the illustrated example also includes one or more mass storage discs or devices 3228 to store firmware, software, and/or data. Examples of such mass storage discs or devices 3228 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine readable instructions 3232, which may be implemented by the machine readable instructions of FIG. 29, may be stored in the mass storage device 3228, in the volatile memory 3214, in the non-volatile memory 3216, and/or on at least one non-transitory computer readable storage medium such as a CD or DVD which may be removable.

FIG. 33 is a block diagram of an example programmable circuitry platform 3300 structured to execute and/or instantiate the example machine-readable instructions and/or the example operations of FIGS. 30 and/or 31 to implement the system monitoring circuitry 1704 of FIG. 22. The programmable circuitry platform 3300 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing and/or electronic device.

The programmable circuitry platform 3300 of the illustrated example includes programmable circuitry 3312. The programmable circuitry 3312 of the illustrated example is hardware. For example, the programmable circuitry 3312 can be implemented by one or more integrated circuits, logic circuits, FPGAs, microprocessors, CPUs, GPUs, DSPs, and/or microcontrollers from any desired family or manufacturer. The programmable circuitry 3312 may be implemented by one or more semiconductor based (e.g., silicon based) devices. In this example, the programmable circuitry 3312 implements the example input interface circuitry 2202, the example model training circuitry 2204, the example coolant anomaly detection circuitry 2206, the example hardware anomaly detection circuitry 2208, the example RUL prediction circuitry 2210, the example cluster analysis circuitry 2212, the example output generation circuitry 2214, the example control adjustment circuitry 2216, and the example system database 2218.

The programmable circuitry 3312 of the illustrated example includes a local memory 3313 (e.g., a cache, registers, etc.). The programmable circuitry 3312 of the illustrated example is in communication with main memory 3314, 3316, which includes a volatile memory 3314 and a non-volatile memory 3316, by a bus 3318. The volatile memory 3314 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 3316 may be implemented by flash memory and/or any other desired type of memory device. Access to the main memory 3314, 3316 of the illustrated example is controlled by a memory controller 3317. In some examples, the memory controller 3317 may be implemented by one or more integrated circuits, logic circuits, microcontrollers from any desired family or manufacturer, or any other type of circuitry to manage the flow of data going to and from the main memory 3314, 3316.

The programmable circuitry platform 3300 of the illustrated example also includes interface circuitry 3320. The interface circuitry 3320 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 3322 are connected to the interface circuitry 3320. The input device(s) 3322 permit(s) a user (e.g., a human user, a machine user, etc.) to enter data and/or commands into the programmable circuitry 3312. The input device(s) 3322 can be implemented by, for example, an audio sensor, a microphone, a camera (still or video), a keyboard, a button, a mouse, a touchscreen, a trackpad, a trackball, an isopoint device, and/or a voice recognition system.

One or more output devices 3324 are also connected to the interface circuitry 3320 of the illustrated example. The output device(s) 3324 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 3320 of the illustrated example, thus, typically includes a graphics driver card, a graphics driver chip, and/or graphics processor circuitry such as a GPU.

The interface circuitry 3320 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 3326. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 3300 of the illustrated example also includes one or more mass storage discs or devices 3328 to store firmware, software, and/or data. Examples of such mass storage discs or devices 3328 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine readable instructions 3332, which may be implemented by the machine readable instructions of FIGS. 30 and/or 31, may be stored in the mass storage device 3328, in the volatile memory 3314, in the non-volatile memory 3316, and/or on at least one non-transitory computer readable storage medium such as a CD or DVD which may be removable.

FIG. 34 is a block diagram of an example implementation of the programmable circuitry 3212 of FIG. 32 and/or the example programmable circuitry 3312 of FIG. 33. In this example, the programmable circuitry 3212 of FIG. 32 and/or the programmable circuitry 3312 of FIG. 33 is implemented by a microprocessor 3400. For example, the microprocessor 3400 may be a general-purpose microprocessor (e.g., general-purpose microprocessor circuitry). The microprocessor 3400 executes some or all of the machine-readable instructions of the flowcharts of FIGS. 29, 30, and/or 31 to effectively instantiate the circuitry of FIGS. 21 and/or 22 as logic circuits to perform operations corresponding to those machine readable instructions. In some such examples, the circuitry of FIGS. 21 and/or 22 is instantiated by the hardware circuits of the microprocessor 3400 in combination with the machine-readable instructions. For example, the microprocessor 3400 may be implemented by multi-core hardware circuitry such as a CPU, a DSP, a GPU, an XPU, etc. Although it may include any number of example cores 3402 (e.g., 1 core), the microprocessor 3400 of this example is a multi-core semiconductor device including N cores. The cores 3402 of the microprocessor 3400 may operate independently or may cooperate to execute machine readable instructions. For example, machine code corresponding to a firmware program, an embedded software program, or a software program may be executed by one of the cores 3402 or may be executed by multiple ones of the cores 3402 at the same or different times. In some examples, the machine code corresponding to the firmware program, the embedded software program, or the software program is split into threads and executed in parallel by two or more of the cores 3402. The software program may correspond to a portion or all of the machine readable instructions and/or operations represented by the flowcharts of FIGS. 29, 30, and/or 31.

The cores 3402 may communicate by a first example bus 3404. In some examples, the first bus 3404 may be implemented by a communication bus to effectuate communication associated with one(s) of the cores 3402. For example, the first bus 3404 may be implemented by at least one of an Inter-Integrated Circuit (I2C) bus, a Serial Peripheral Interface (SPI) bus, a PCI bus, or a PCIe bus. Additionally or alternatively, the first bus 3404 may be implemented by any other type of computing or electrical bus. The cores 3402 may obtain data, instructions, and/or signals from one or more external devices by example interface circuitry 3406. The cores 3402 may output data, instructions, and/or signals to the one or more external devices by the interface circuitry 3406. Although the cores 3402 of this example include example local memory 3420 (e.g., Level 1 (L1) cache that may be split into an L1 data cache and an L1 instruction cache), the microprocessor 3400 also includes example shared memory 3410 that may be shared by the cores (e.g., Level 2 (L2 cache)) for high-speed access to data and/or instructions. Data and/or instructions may be transferred (e.g., shared) by writing to and/or reading from the shared memory 3410. The local memory 3420 of each of the cores 3402 and the shared memory 3410 may be part of a hierarchy of storage devices including multiple levels of cache memory and the main memory (e.g., the main memory 3214, 3216 of FIG. 32 and/or the main memory 3314, 3316 of FIG. 33). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 3402 may be referred to as a CPU, DSP, GPU, etc., or any other type of hardware circuitry. Each core 3402 includes control unit circuitry 3414, arithmetic and logic (AL) circuitry (sometimes referred to as an ALU) 3416, a plurality of registers 3418, the local memory 3420, and a second example bus 3422. Other structures may be present. For example, each core 3402 may include vector unit circuitry, single instruction multiple data (SIMD) unit circuitry, load/store unit (LSU) circuitry, branch/jump unit circuitry, floating-point unit (FPU) circuitry, etc. The control unit circuitry 3414 includes semiconductor-based circuits structured to control (e.g., coordinate) data movement within the corresponding core 3402. The AL circuitry 3416 includes semiconductor-based circuits structured to perform one or more mathematic and/or logic operations on the data within the corresponding core 3402. The AL circuitry 3416 of some examples performs integer based operations. In other examples, the AL circuitry 3416 also performs floating-point operations. In yet other examples, the AL circuitry 3416 may include first AL circuitry that performs integer-based operations and second AL circuitry that performs floating-point operations. In some examples, the AL circuitry 3416 may be referred to as an Arithmetic Logic Unit (ALU).

The registers 3418 are semiconductor-based structures to store data and/or instructions such as results of one or more of the operations performed by the AL circuitry 3416 of the corresponding core 3402. For example, the registers 3418 may include vector register(s), SIMD register(s), general-purpose register(s), flag register(s), segment register(s), machine-specific register(s), instruction pointer register(s), control register(s), debug register(s), memory management register(s), machine check register(s), etc. The registers 3418 may be arranged in a bank as shown in FIG. 34. Alternatively, the registers 3418 may be organized in any other arrangement, format, or structure, such as by being distributed throughout the core 3402 to shorten access time. The second bus 3422 may be implemented by at least one of an I2C bus, a SPI bus, a PCI bus, or a PCIe bus.

Each core 3402 and/or, more generally, the microprocessor 3400 may include additional and/or alternate structures to those shown and described above. For example, one or more clock circuits, one or more power supplies, one or more power gates, one or more cache home agents (CHAs), one or more converged/common mesh stops (CMS s), one or more shifters (e.g., barrel shifter(s)) and/or other circuitry may be present. The microprocessor 3400 is a semiconductor device fabricated to include many transistors interconnected to implement the structures described above in one or more integrated circuits (ICs) contained in one or more packages.

The microprocessor 3400 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those discussed herein. A GPU, DSP and/or other programmable device can also be an accelerator. Accelerators may be on-board the microprocessor 3400, in the same chip package as the microprocessor 3400 and/or in one or more separate packages from the microprocessor 3400.

FIG. 35 is a block diagram of another example implementation of the programmable circuitry 3212 of FIG. 32 and/or the programmable circuitry 3312 of FIG. 33. In this example, the programmable circuitry 3212, 3312 is implemented by FPGA circuitry 3500. For example, the FPGA circuitry 3500 may be implemented by an FPGA. The FPGA circuitry 3500 can be used, for example, to perform operations that could otherwise be performed by the example microprocessor 3400 of FIG. 34 executing corresponding machine readable instructions. However, once configured, the FPGA circuitry 3500 instantiates the operations and/or functions corresponding to the machine readable instructions in hardware and, thus, can often execute the operations/functions faster than they could be performed by a general-purpose microprocessor executing the corresponding software.

More specifically, in contrast to the microprocessor 3400 of FIG. 34 described above (which is a general purpose device that may be programmed to execute some or all of the machine readable instructions represented by the flowchart(s) of FIGS. 29, 30, and/or 31 but whose interconnections and logic circuitry are fixed once fabricated), the FPGA circuitry 3500 of the example of FIG. 35 includes interconnections and logic circuitry that may be configured, structured, programmed, and/or interconnected in different ways after fabrication to instantiate, for example, some or all of the operations/functions corresponding to the machine readable instructions represented by the flowchart(s) of FIGS. 29, 30, and/or 31. In particular, the FPGA circuitry 3500 may be thought of as an array of logic gates, interconnections, and switches. The switches can be programmed to change how the logic gates are interconnected by the interconnections, effectively forming one or more dedicated logic circuits (unless and until the FPGA circuitry 3500 is reprogrammed). The configured logic circuits enable the logic gates to cooperate in different ways to perform different operations on data received by input circuitry. Those operations may correspond to some or all of the instructions (e.g., the software and/or firmware) represented by the flowchart(s) of FIGS. 29, 30, and/or 31. As such, the FPGA circuitry 3500 may be configured and/or structured to effectively instantiate some or all of the operations/functions corresponding to the machine readable instructions of the flowchart(s) of FIGS. 29, 30, and/or 31 as dedicated logic circuits to perform the operations/functions corresponding to those software instructions in a dedicated manner analogous to an ASIC. Therefore, the FPGA circuitry 3500 may perform the operations/functions corresponding to the some or all of the machine readable instructions of FIGS. 29, 30, and/or 31 faster than the general-purpose microprocessor can execute the same.

In the example of FIG. 35, the FPGA circuitry 3500 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 3500 of FIG. 35 may access and/or load the binary file to cause the FPGA circuitry 3500 of FIG. 35 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 3500 of FIG. 35 to cause configuration and/or structuring of the FPGA circuitry 3500 of FIG. 35, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 3500 of FIG. 35 may access and/or load the binary file to cause the FPGA circuitry 3500 of FIG. 35 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 3500 of FIG. 35 to cause configuration and/or structuring of the FPGA circuitry 3500 of FIG. 35, or portion(s) thereof.

The FPGA circuitry 3500 of FIG. 35, includes example input/output (I/O) circuitry 3502 to obtain and/or output data to/from example configuration circuitry 3504 and/or external hardware 3506. For example, the configuration circuitry 3504 may be implemented by interface circuitry that may obtain a binary file, which may be implemented by a bit stream, data, and/or machine-readable instructions, to configure the FPGA circuitry 3500, or portion(s) thereof. In some such examples, the configuration circuitry 3504 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 3506 may be implemented by external hardware circuitry. For example, the external hardware 3506 may be implemented by the microprocessor 3400 of FIG. 34.

The FPGA circuitry 3500 also includes an array of example logic gate circuitry 3508, a plurality of example configurable interconnections 3510, and example storage circuitry 3512. The logic gate circuitry 3508 and the configurable interconnections 3510 are configurable to instantiate one or more operations/functions that may correspond to at least some of the machine readable instructions of FIGS. 29, 30, and/or 31 and/or other desired operations. The logic gate circuitry 3508 shown in FIG. 35 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 3508 to enable configuration of the electrical structures and/or the logic gates to form circuits to perform desired operations/functions. The logic gate circuitry 3508 may include other electrical structures such as look-up tables (LUTs), registers (e.g., flip-flops or latches), multiplexers, etc.

The configurable interconnections 3510 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 3508 to program desired logic circuits.

The storage circuitry 3512 of the illustrated example is structured to store result(s) of the one or more of the operations performed by corresponding logic gates. The storage circuitry 3512 may be implemented by registers or the like. In the illustrated example, the storage circuitry 3512 is distributed amongst the logic gate circuitry 3508 to facilitate access and increase execution speed.

The example FPGA circuitry 3500 of FIG. 35 also includes example dedicated operations circuitry 3514. In this example, the dedicated operations circuitry 3514 includes special purpose circuitry 3516 that may be invoked to implement commonly used functions to avoid the need to program those functions in the field. Examples of such special purpose circuitry 3516 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 3500 may also include example general purpose programmable circuitry 3518 such as an example CPU 3520 and/or an example DSP 3522. Other general purpose programmable circuitry 3518 may additionally or alternatively be present such as a GPU, an XPU, etc., that can be programmed to perform other operations.

Although FIGS. 34 and 35 illustrate two example implementations of the programmable circuitry 3212 of FIG. 32 and/or the programmable circuitry 3312 of FIG. 33, many other approaches are contemplated. For example, FPGA circuitry may include an on-board CPU, such as one or more of the example CPU 3520 of FIG. 34. Therefore, the programmable circuitry 3212 of FIG. 32 may additionally be implemented by combining at least the example microprocessor 3400 of FIG. 34 and the example FPGA circuitry 3500 of FIG. 35. In some such hybrid examples, one or more cores 3402 of FIG. 34 may execute a first portion of the machine readable instructions represented by the flowchart(s) of FIGS. 29, and/or 31 to perform first operation(s)/function(s), the FPGA circuitry 3500 of FIG. 35 may be configured and/or structured to perform second operation(s)/function(s) corresponding to a second portion of the machine readable instructions represented by the flowcharts of FIGS. 29, 30, and/or 31, and/or an ASIC may be configured and/or structured to perform third operation(s)/function(s) corresponding to a third portion of the machine readable instructions represented by the flowcharts of FIGS. 29, 30, and/or 31.

It should be understood that some or all of the circuitry of FIGS. 21 and/or 22 may, thus, be instantiated at the same or different times. For example, same and/or different portion(s) of the microprocessor 3400 of FIG. 34 may be programmed to execute portion(s) of machine-readable instructions at the same and/or different times. In some examples, same and/or different portion(s) of the FPGA circuitry 3500 of FIG. 35 may be configured and/or structured to perform operations/functions corresponding to portion(s) of machine-readable instructions at the same and/or different times.

In some examples, some or all of the circuitry of FIGS. 21 and/or 22 may be instantiated, for example, in one or more threads executing concurrently and/or in series. For example, the microprocessor 3400 of FIG. 34 may execute machine readable instructions in one or more threads executing concurrently and/or in series. In some examples, the FPGA circuitry 3500 of FIG. 35 may be configured and/or structured to carry out operations/functions concurrently and/or in series. Moreover, in some examples, some or all of the circuitry of FIGS. 21 and/or 22 may be implemented within one or more virtual machines and/or containers executing on the microprocessor 3400 of FIG. 34.

In some examples, the programmable circuitry 3212, 3312 may be in one or more packages. For example, the microprocessor 3400 of FIG. 34 and/or the FPGA circuitry 3500 of FIG. 35 may be in one or more packages. In some examples, an XPU may be implemented by the programmable circuitry 3212, 3312, which may be in one or more packages. For example, the XPU may include a CPU (e.g., the microprocessor 3400 of FIG. 34, the CPU 3520 of FIG. 35, etc.) in one package, a DSP (e.g., the DSP 3522 of FIG. 35) in another package, a GPU in yet another package, and an FPGA (e.g., the FPGA circuitry 3500 of FIG. 35) in still yet another package.

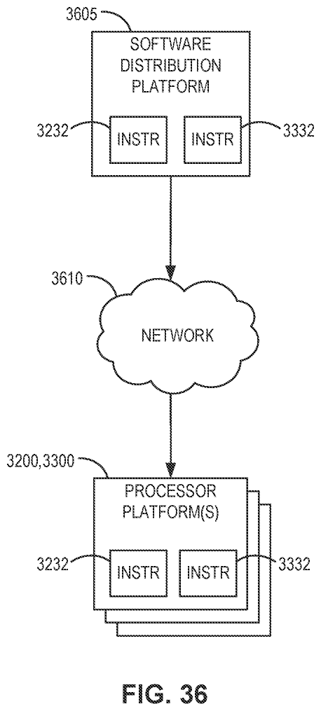

A block diagram illustrating an example software distribution platform 3605 to distribute software such as the example machine readable instructions 3232 of FIG. 32 and/or the example machine readable instructions 3332 of FIG. 33 to other hardware devices (e.g., hardware devices owned and/or operated by third parties from the owner and/or operator of the software distribution platform) is illustrated in FIG. 36. The example software distribution platform 3605 may be implemented by any computer server, data facility, cloud service, etc., capable of storing and transmitting software to other computing devices. The third parties may be customers of the entity owning and/or operating the software distribution platform 3605. For example, the entity that owns and/or operates the software distribution platform 3605 may be a developer, a seller, and/or a licensor of software such as the example machine readable instructions 3232 of FIG. 32 and/or the example machine readable instructions 3332 of FIG. 33. The third parties may be consumers, users, retailers, OEMs, etc., who purchase and/or license the software for use and/or re-sale and/or sub-licensing. In the illustrated example, the software distribution platform 3605 includes one or more servers and one or more storage devices. The storage devices store the machine readable instructions 3232, 3332, which may correspond to the example machine readable instructions of FIGS. 29, 30, and/or 31, as described above. The one or more servers of the example software distribution platform 3605 are in communication with an example network 3610, which may correspond to any one or more of the Internet and/or any of the example networks described above. In some examples, the one or more servers are responsive to requests to transmit the software to a requesting party as part of a commercial transaction. Payment for the delivery, sale, and/or license of the software may be handled by the one or more servers of the software distribution platform and/or by a third party payment entity. The servers enable purchasers and/or licensors to download the machine readable instructions 3232, 3332 from the software distribution platform 3605. For example, the software, which may correspond to the example machine readable instructions of FIGS. 29, 30, and/or 31, may be downloaded to the example programmable circuitry platform 3200, which is to execute the machine readable instructions 3232, 3332 to implement the reservoir monitoring circuitry 1702 and/or the system monitoring circuitry 1704. In some examples, one or more servers of the software distribution platform 3605 periodically offer, transmit, and/or force updates to the software (e.g., the example machine readable instructions 3232 of FIG. 32 and/or the example machine readable instructions 3332 of FIG. 33) to ensure improvements, patches, updates, etc., are distributed and applied to the software at the end user devices. Although referred to as software above, the distributed “software” could alternatively be firmware.

From the foregoing, it will be appreciated that example systems, apparatus, articles of manufacture, and methods have been disclosed that monitor and/or predict performance of example heat exchangers and/or one or more example reservoirs associated therewith. In examples disclosed herein, a first example reservoir is fluidly and/or operatively coupled to an example heat exchanger, and a second example reservoir is fluidly coupled to the first reservoir to supply coolant thereto without user involvement. As a result, examples disclosed herein maintain sufficient levels of coolant at the heat exchanger to reduce a risk of damage to the heat exchanger resulting from insufficient coolant levels. In further examples disclosed herein, example programmable circuitry detects a coolant level in the second reservoir based on outputs of sensors, and alerts an operator when the coolant level does not satisfy one or more example thresholds. Additionally or alternatively, the programmable circuitry can detect and/or predict, based on execution of one or more machine learning model(s), anomalies (e.g., coolant anomalies and/or hardware anomalies) associated with the heat exchanger(s). Advantageously, by dynamically supplying coolant to one or more heat exchangers and/or alerting an operator when low coolant levels and/or other anomalies are detected for the heat exchanger(s), disclosed systems, apparatus, articles of manufacture, and methods improve efficiency of cooling compute device(s) and, as a result, preventing overheating of the computing device, reduce maintenance issues at heat exchanger(s), etc. Disclosed systems, apparatus, articles of manufacture, and methods are accordingly directed to one or more improvement(s) in the operation of a machine such as a computer or other electronic and/or mechanical device.

Example methods, apparatus, systems, and articles of manufacture to monitor heat exchangers and associated reservoirs are disclosed herein. Further examples and combinations thereof include the following:

Example 1 includes an apparatus comprising memory, instructions, and programmable circuitry to execute the instructions to detect, based on outputs of a sensor associated with a first reservoir, a coolant level of the first reservoir, the first reservoir removably coupled to a second reservoir, the first reservoir to supply coolant to the second reservoir, predict, based on the coolant level, a characteristic associated with operation of a cooling device fluidly coupled to the second reservoir, and cause an output to be presented at a user device based on the predicted characteristic.

Example 2 includes the apparatus of example 1, wherein the programmable circuitry is to execute a machine learning model to predict the characteristic, the coolant level defining an input to the machine learning model.

Example 3 includes the apparatus of example 1, wherein the cooling device includes a liquid assisted air cooling (LAAC) heat exchanger, an in-row cooling distribution unit (CDU), an in-rack CDU, or an immersion tank.

Example 4 includes the apparatus of example 1, wherein the predicted characteristic corresponds to at least one of a coolant anomaly associated with the coolant, a hardware anomaly associated with the cooling device, or a remaining useful life of the cooling device.

Example 5 includes the apparatus of example 4, wherein the coolant anomaly includes at least one of evaporation of the coolant, overheating of the coolant, leakage of the coolant, or a pressure drop of the coolant.

Example 6 includes the apparatus of example 4, wherein the hardware anomaly includes at least one of a pump failure, a fan failure, blocked air flow, fin damage, or operating temperatures associated with the cooling device being above a threshold.

Example 7 includes the apparatus of example 6, wherein the programmable circuitry is to cause one or more of fan speed, pump speed, or coolant flow rate to be adjusted responsive to the hardware anomaly.

Example 8 includes the apparatus of example 1, wherein the programmable circuitry is to cause the output to be displayed at the user device, the output including at least one of an identifier associated with the cooling device, a location of the cooling device, the coolant level, or the predicted characteristic.

Example 9 includes a non-transitory computer readable medium comprising instructions that, when executed, cause programmable circuitry to at least detect, based on outputs of a sensor associated with a first reservoir, a property of coolant in the first reservoir, the first reservoir removably coupled to a second reservoir, the first reservoir to provide coolant to the second reservoir, detect, based on the coolant property, an anomaly associated with a cooling device fluidly coupled to the second reservoir, and cause a control parameter of the cooling device to be adjusted responsive to the detection of the anomaly.

Example 10 includes the non-transitory computer readable medium of example 9, wherein the cooling device corresponds to at least one of a liquid assisted air cooling (LAAC) heat exchanger, an in-row cooling distribution unit (CDU), an in-rack CDU, or an immersion tank.

Example 11 includes the non-transitory computer readable medium of example 9, wherein the instructions cause the programmable circuitry to predict a remaining useful life of the cooling device.

Example 12 includes the non-transitory computer readable medium of example 11, wherein the anomaly is associated with one or more of (a) coolant provided to the cooling device via the first reservoir or (b) hardware associated with the cooling device.

Example 13 includes the non-transitory computer readable medium of example 12, wherein the anomaly is indicative of one or more of evaporation of the coolant, overheating of the coolant, leakage of the coolant, or a pressure associated with the coolant.

Example 14 includes the non-transitory computer readable medium of example 12, wherein the anomaly includes at least one of a pump failure, a fan failure, blocked air flow, fin damage, or operating temperatures associated with the cooling device exceeding a threshold.

Example 15 includes the non-transitory computer readable medium of example 9, wherein the instructions cause the programmable circuitry to cause one or more of fan speed, pump speed, or coolant flow rate associated with the cooling device to be adjusted.

Example 16 includes the non-transitory computer readable medium of example 9, wherein the instructions cause the programmable circuitry to output display information for presentation at a user device, the display information including at least one of an identifier associated with the cooling device, a location of the cooling device, the coolant property, or the anomaly.

Example 17 includes the non-transitory computer readable medium of example 9, wherein the cooling device is a first cooling device in a data center, the anomaly is a first anomaly, the control parameter is a first control parameter, and the instructions cause the programmable circuitry to detect a second anomaly associated with a second cooling device in the data center, define a cluster including the first cooling device and the second cooling device based on the first and second anomalies, and cause a second control parameter of the second cooling device to be adjusted based on the clustering.

Example 18 includes a system comprising a first reservoir fluidly coupled to a heat exchanger, a second reservoir removably coupled to the first reservoir, the second reservoir to supply fluid to the first reservoir, a sensor operatively coupled to the second reservoir, the sensor to generate outputs indicative of a fluid level of the fluid in the second reservoir, and programmable circuitry to determine a status of the second reservoir based on the outputs, and cause an indicator to emit light based on the status.

Example 19 includes the system of example 18, wherein the first reservoir is to supply the fluid to the second reservoir based on the outputs during operation of the heat exchanger.

Example 20 includes the system of example 18, wherein the indicator includes a first light source and a second light source, the programmable circuitry to in response to determining that the fluid level satisfies a threshold, activate the first light source but not the second light source, and in response to determining that the fluid level does not satisfy the threshold, activate the second light source but not the first light source.

Example 21 includes the system of example 20, wherein the programmable circuitry is to generate an alert in response to determining that the fluid level does not satisfy the threshold, and cause the alert to be presented at one or more of the second reservoir or a user device.

Example 22 includes the system of example 21, wherein the alert includes the status and at least one of a location of the heat exchanger or an identifier associated with the heat exchanger.

Example 23 includes the system of example 18, wherein the sensor is carried by a cap removably coupled to the second reservoir.

Example 24 includes the system of example 23, wherein the cap includes the indicator.

Example 25 includes the system of example 18, wherein the sensor is a first sensor at least partially disposed in the second reservoir and further including a second sensor at least partially disposed in the second reservoir, the first sensor associated with a first fluid level threshold and the second sensor associated with a second fluid level threshold.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

1. An apparatus comprising:
memory;
instructions; and
programmable circuitry to execute the instructions to:
detect, based on outputs of a sensor associated with a first reservoir, a coolant level of the first reservoir, the first reservoir removably coupled to a second reservoir, the first reservoir to supply coolant to the second reservoir;
predict, based on the coolant level, a characteristic associated with operation of a cooling device fluidly coupled to the second reservoir; and
cause an output to be presented at a user device based on the predicted characteristic.

2. The apparatus of claim 1, wherein the programmable circuitry is to execute a machine learning model to predict the characteristic, the coolant level defining an input to the machine learning model.

3. The apparatus of claim 1, wherein the cooling device includes a liquid assisted air cooling (LAAC) heat exchanger, an in-row cooling distribution unit (CDU), an in-rack CDU, or an immersion tank.

4. The apparatus of claim 1, wherein the predicted characteristic corresponds to at least one of a coolant anomaly associated with the coolant, a hardware anomaly associated with the cooling device, or a remaining useful life of the cooling device.

5. The apparatus of claim 4, wherein the coolant anomaly includes at least one of evaporation of the coolant, overheating of the coolant, leakage of the coolant, or a pressure drop of the coolant.

6. The apparatus of claim 4, wherein the hardware anomaly includes at least one of a pump failure, a fan failure, blocked air flow, fin damage, or operating temperatures associated with the cooling device being above a threshold.

7. The apparatus of claim 6, wherein the programmable circuitry is to cause one or more of fan speed, pump speed, or coolant flow rate to be adjusted responsive to the hardware anomaly.

8. The apparatus of claim 1, wherein the programmable circuitry is to cause the output to be displayed at the user device, the output including at least one of an identifier associated with the cooling device, a location of the cooling device, the coolant level, or the predicted characteristic.

9. A non-transitory computer readable medium comprising instructions that, when executed, cause programmable circuitry to at least:
detect, based on outputs of a sensor associated with a first reservoir, a property of coolant in the first reservoir, the first reservoir removably coupled to a second reservoir, the first reservoir to provide coolant to the second reservoir;
detect, based on the coolant property, an anomaly associated with a cooling device fluidly coupled to the second reservoir; and
cause a control parameter of the cooling device to be adjusted responsive to the detection of the anomaly.

10. The non-transitory computer readable medium of claim 9, wherein the cooling device corresponds to at least one of a liquid assisted air cooling (LAAC) heat exchanger, an in-row cooling distribution unit (CDU), an in-rack CDU, or an immersion tank.

11. The non-transitory computer readable medium of claim 9, wherein the instructions cause the programmable circuitry to predict a remaining useful life of the cooling device.

12. The non-transitory computer readable medium of claim 11, wherein the anomaly is associated with one or more of (a) coolant provided to the cooling device via the first reservoir or (b) hardware associated with the cooling device.

13. The non-transitory computer readable medium of claim 12, wherein the anomaly is indicative of one or more of evaporation of the coolant, overheating of the coolant, leakage of the coolant, or a pressure associated with the coolant.

14. The non-transitory computer readable medium of claim 12, wherein the anomaly includes at least one of a pump failure, a fan failure, blocked air flow, fin damage, or operating temperatures associated with the cooling device exceeding a threshold.

15. The non-transitory computer readable medium of claim 9, wherein the instructions cause the programmable circuitry to cause one or more of fan speed, pump speed, or coolant flow rate associated with the cooling device to be adjusted.

16. The non-transitory computer readable medium of claim 9, wherein the instructions cause the programmable circuitry to output display information for presentation at a user device, the display information including at least one of an identifier associated with the cooling device, a location of the cooling device, the coolant property, or the anomaly.

17. The non-transitory computer readable medium of claim 9, wherein the cooling device is a first cooling device in a data center, the anomaly is a first anomaly, the control parameter is a first control parameter, and the instructions cause the programmable circuitry to:
detect a second anomaly associated with a second cooling device in the data center;
define a cluster including the first cooling device and the second cooling device based on the first and second anomalies; and
cause a second control parameter of the second cooling device to be adjusted based on the clustering.

18. A system comprising:
a first reservoir fluidly coupled to a heat exchanger;
a second reservoir removably coupled to the first reservoir, the second reservoir to supply fluid to the first reservoir;
a sensor operatively coupled to the second reservoir, the sensor to generate outputs indicative of a fluid level of the fluid in the second reservoir; and
programmable circuitry to:
determine a status of the second reservoir based on the outputs; and
cause an indicator to emit light based on the status.

19. The system of claim 18, wherein the first reservoir is to supply the fluid to the second reservoir based on the outputs during operation of the heat exchanger.

20. The system of claim 18, wherein the indicator includes a first light source and a second light source, the programmable circuitry to:
in response to determining that the fluid level satisfies a threshold, activate the first light source but not the second light source; and
in response to determining that the fluid level does not satisfy the threshold, activate the second light source but not the first light source.

21-25. (canceled)
